(19) United States
(12) Patent Application Publication
(10) Pub. No.: US 2010/0176377 A1
(43) Pub. Date: Jul. 15, 2010

(54) Polymeric compound and polymeric electroluminescence element using the same

(75) Inventors: Daisuke Fukushima, Ibaraki (JP); Yoshiaki Tsubata, Ibaraki (JP); Makoto Anryu, Ibaraki (JP)

Correspondence Address: SUGHRUE MION, PLLC, 2100 PENNSYLVANIA AVENUE, N.W., SUITE 800, WASHINGTON, DC, 20037, US

(73) Assignee: Sumitomo Chemical Company, Limited, Chuo-ku, Tokyo (JP)

(21) Appl. No.: 12/091,977

(22) PCT Filed: Nov. 15, 2006
(86) PCT No.: PCT/JP06/23257

§ 371 Date: Jun. 4, 2008

(30) Foreign Application Priority Data
Nov. 18, 2005 (JP) 2005-333759

(51) Int. Cl. H01L 51/54; C08G 79/08; C08L 85/04; H01B 1/12; B05D 5/00; H01L 51/30

(52) U.S. Cl. 257/40; 528/8; 524/610; 252/500; 427/256; 257/E51.001; 257/E51.027

(57) ABSTRACT

A polymer compound comprising at least one of repeating units of the following formula (1) and at least one of repeating units selected from the following formulae (2) and (3).

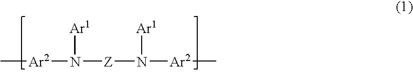

(Ar¹ represents an aryl group or monovalent aromatic heterocyclic group, Ar² represents an arylene group or divalent aromatic heterocyclic group, and Z represents a divalent aromatic group having a condensed ring structure.)

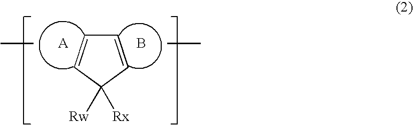

(a ring A and a ring B represent an aromatic hydrocarbon ring, at least one of the ring A and the ring B is an aromatic hydrocarbon ring having two or more benzene rings condensed, and Rw and Rx represent each independently a hydrogen atom, alkyl group or the like.)

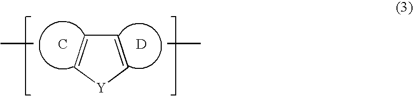

(a ring C and a ring D represent an aromatic ring, Y represents an oxygen atom, sulfur atom or —O—C(R^{K})₂—, and R^{K} represents a hydrogen atom, alkyl group or the like.).

### TECHNICAL FIELD

The present invention relates to a polymer compound and a polymer light emitting device using the same.

### BACKGROUND ART

Light emitting material and charge transporting material of high molecular weight which are soluble in solvent are capable of forming an organic layer in a light emitting device by an application method, thus, various investigations have been undergone, and polymer compounds containing a diphenylaminoanthracenediyl group and a fluorenediyl group are known as examples thereof (International Publication WO 2005/49546 pamphlet).

The above-described polymer compound, however, has not necessarily sufficient heat resistance and fluorescence intensity, and light emitting devices using the above-described polymer compounds have not necessarily sufficient device properties thereof such as life of a device, light emission efficiency and the like.

### DISCLOSURE OF THE INVENTION

An object of the present invention is to provide a polymer compound which is useful as a light emitting material and a charge transporting material and excellent in heat resistance, fluorescence intensity and the like, and a polymer light emitting device using the same which is excellent in device properties such as life of a device, light emission efficiency and the like.

That is, the present invention provides a polymer compound comprising at least one of repeating units of the following formula (1) and at least one of repeating units selected from the following formulae (2) and (3).

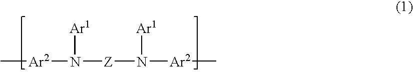

(wherein, Ar¹ represents an aryl group or monovalent aromatic heterocyclic group optionally having a substituent, and Ar² represents an arylene group or divalent aromatic heterocyclic group optionally having a substituent. Z represents a divalent aromatic group having a condensed ring structure, and this group optionally has a substituent. Two Ar¹s may be the same or different, and two Ar²s may be the same or different.)

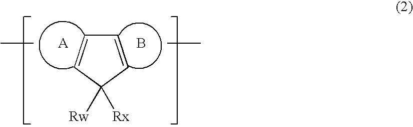

(wherein, a ring A and a ring B represent each independently an aromatic hydrocarbon ring optionally having a substituent, and at least one of the ring A and the ring B is an aromatic hydrocarbon ring having two or more benzene rings condensed, two bonds are present on the ring A or the ring B, and Rw and Rx represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group, and Rw and Rx may be mutually connected with each other to form a ring.)

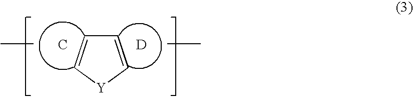

(wherein, a ring C and a ring D represent each independently an aromatic ring optionally having a substituent, and two bonds are present on the ring C or the ring D. Y represents an oxygen atom, sulfur atom or —O—C(R^{K})₂—. R^{K} represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, nitro group or cyano group. Two R^{K}s may be the same or different.).

### MODE FOR CARRYING OUT THE INVENTION

The polymer compound of the present invention contains one or more repeating units of the above-described formula (1).

In the formula (1), Ar¹ represents an aryl group or monovalent aromatic heterocyclic group optionally having a substituent. Two Ar¹s may be the same or different. Ar¹ preferably represent an aryl group.

Here, the aryl group is an atomic group obtained by removing one hydrogen atom from an aromatic hydrocarbon, and includes those having an independent benzene ring or condensed ring. The aryl group has a carbon number of usually about from 6 to 60, preferably 6 to 48, more preferably 6 to 30, even preferably 6 to 18, further preferably 6 to 10, and particularly preferably 6. This carbon number does not include the carbon number of substituents. Examples of the aryl group include a phenyl group, 1-naphthyl group, 2-naphthyl group, 1-anthracenyl group, 2-anthracenyl group, 9-anthracenyl group, 1-phenanthryl group, 9-phenanthryl group, 1-naphthacenyl group, 2-naphthacenyl group and the like, preferably a phenyl group, 1-naphthyl group, 2-naphthyl group, 1-anthracenyl group, 2-anthracenyl group and 9-anthracenyl group, more preferably a phenyl group, 1-naphthyl group and 2-naphthyl group, and further preferably a phenyl group.

The monovalent aromatic heterocyclic group is an atomic group remaining after removing one hydrogen atom from an aromatic heterocyclic compound, and the carbon is usually about from 4 to 60, preferably 4 to 20, more preferably 4 to 9, and further preferably 4 to 5. The carbon number of the monovalent aromatic heterocyclic group does not include the carbon number of substituents. Here, the heterocyclic compound refers to organic compounds having a cyclic structure in which elements constituting the ring include not only a carbon atom, but also a heteroatom such as oxygen, sulfur, nitrogen, phosphorus, boron and the like contained in the ring. Examples of the monovalent aromatic heterocyclic group include a 2-thienyl group, 3-thienyl group, 2-pyrrolyl group, 3-pyrrolyl group, 2-furyl group, 3-furyl group, 2-pyridyl group, 3-pyridyl group, 4-pyridyl group, 2-quinolyl group, 4-quinolyl group, 5-quinolyl group, 1-isoquinolyl group, 3-isoquinolyl group, 6-isoquinolyl group and the like, and preferable are a 2-thienyl group, 3-thienyl group, 2-pyridyl group, 3-pyridyl group, 4-pyridyl group, 2-quinolyl group, 4-quinolyl group, 5-quinolyl group, 1-isoquinolyl group, 3-isoquinolyl group and 6-isoquinolyl group, more preferable are a 2-thienyl group, 3-thienyl group, 2-pyridyl group, 3-pyridyl group and 4-pyridyl group, further preferable are a 2-pyridyl group, 3-pyridyl group and 4-pyridyl group.

When Ar¹ has a substituent, it is preferable from the standpoints of solubility in organic solvents, device properties, easiness of synthesis and the like that the substituent is selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group. The substituent is more preferably selected from an alkyl group, alkoxy group, aryl group, aryloxy group, arylalkyl group, arylalkoxy group, substituted amino group, substituted silyl group, acyl group, substituted carboxyl group and cyano group, even preferably selected from an alkyl group, alkoxy group, aryl group, aryloxy group, arylalkyl group, arylalkoxy group and substituted carboxyl group, further preferably selected from an alkyl group, alkoxy group and aryl group, and the substituent is particularly preferably an alkyl group.

Here, the alkyl group may be linear, branched or cyclic, the carbon number thereof is usually about from 1 to 20, preferably 1 to 15, more preferably 1 to 10, and examples thereof include a methyl group, ethyl group, propyl group, i-propyl group, butyl group, i-butyl group, t-butyl group, pentyl group, isoamyl group, hexyl group, cyclohexyl group, heptyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group and the like, and mentioned from the standpoints of device properties, easiness of synthesis and the like and for balance with heat resistance are a methyl group, ethyl group, propyl group, i-propyl group, butyl group, i-butyl group, t-butyl group, pentyl group, isoamyl group, hexyl group, octyl group, 2-ethylhexyl group, decyl group and 3,7-dimethyloctyl group.

The alkoxy group may be linear, branched or cyclic, the carbon number thereof is usually about from 1 to 20, preferably 1 to 15, and examples thereof include a methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group, lauryloxy group, trifluoromethoxy group, pentafluoroethoxy group, perfluorobutoxy group, perfluorohexyl group, perfluorooctyl group, methoxymethyloxy group, 2-methoxyethyloxy group, 2-ethoxyethyloxy group and the like, and mentioned from the standpoints of solubility in organic solvents, device properties, easiness of synthesis and the like and for balance with heat resistance are a pentyloxy group, hexyloxy group, octyloxy group, 2-ethylhexyloxy group, decyloxy group and 3,7-dimethyloctyloxy group.

The alkylthio group may be linear, branched or cyclic, the carbon number thereof is usually about from 1 to 20, preferably 3 to 20, and examples thereof include a methylthio group, ethylthio group, propylthio group, i-propylthio group, butylthio group, i-butylthio group, t-butylthio group, pentylthio group, hexylthio group, cyclohexylthio group, heptylthio group, octylthio group, 2-ethylhexylthio group, nonylthio group, decylthio group, 3,7-dimethyloctylthio group, laurylthio group, trifluoromethylthio group and the like, and mentioned from the standpoints of solubility in organic solvents, device properties, easiness of synthesis and the like and for balance with heat resistance are a pentylthio group, hexylthio group, octylthio group, 2-ethylhexylthio group, decylthio group and 3,7-dimethyloctylthio group.

The aryl group is an atomic group obtained by removing one hydrogen atom from an aromatic hydrocarbon, and includes also those having a condensed ring, and those in which independent two or more benzene rings or condensed rings are connected directly or via a group such as vinylene and the like. The aryl group has a total carbon number of usually about from 6 to 60, preferably 7 to 48. Examples thereof include a phenyl group, 1-naphthyl group, 2-naphthyl group, 1-anthracenyl group, 2-anthracenyl group, 9-anthracenyl group, pentafluorophenyl group and the like, these may further have a substituent such as an alkyl group, alkoxy group, alkyloxycarbonyl group and the like. Preferable from the standpoints of solubility in these organic solvents, device properties, easiness of synthesis and the like are phenyl groups having as a substituent at least one of alkyl groups having 1 to 12 carbon atoms and/or alkoxy groups having 1 to 12 carbon atoms and/or alkyloxycarbonyl groups, and examples thereof include a 3-methylphenyl group, 4-methylphenyl group, 3,5-dimethylphenyl group, 4-propylphenyl group, mesityl group, 4-i-propylphenyl group, 4-butylphenyl group, 4-1-butylphenyl group, 4-t-butylphenyl group, 4-pentylphenyl group, 4-isoamylphenyl group, 4-hexylphenyl group, 2,6-dimethyl-4-t-butylphenyl group, 4-heptylphenyl group, 4-octylphenyl group, 4-nonylphenyl group, 4-decylphenyl group, 4-dodecylphenyl group, 3-methyloxyphenyl group, 4-methyloxyphenyl group, 3,5-dimethyloxyphenyl group, 4-propyloxyphenyl group, 4-i-propyloxyphenyl group, 4-butyloxyphenyl group, 4-i-butyloxyphenyl group, 4-t-butyloxyphenyl group, 4-hexyloxyphenyl group, 3,5-dihexyloxyphenyl group, 4-heptyloxyphenyl group, 4-octyloxyphenyl group, 4-nonyloxyphenyl group, 4-(methoxymethoxy)phenyl group, 3-(methoxymethoxy)phenyl group, 4-(2-ethoxy-ethoxy)phenyl group, 3-(2-ethoxy-ethoxy)phenyl group, 3,5-bis(2-ethoxy-ethoxy)phenyl group, 3-methoxycarbonylphenyl group, 4-methoxycarbonylphenyl group, 3,5-dimethoxycarbonylphenyl group, 3-ethoxycarbonylphenyl group, 4-ethoxycarbonylphenyl group, 3-ethyloxycarbonyl-4-methoxyphenyl group, 3-ethyloxycarbonyl-4-ethoxyphenyl group, 3-ethyloxycarbonyl-4-hexyloxyphenyl group and the like.

The aryloxy group has a carbon number of usually about from 6 to 60, preferably 7 to 48, and examples thereof include a phenoxy group, C₁ to C₁₂ alkoxyphenoxy groups (C₁ to C₁₂ means a carbon number of 1 to 12, being applicable also in the following descriptions), C₁ to C₁₂ alkylphenoxy groups, 1-naphthyloxy group, 2-naphthyloxy group, pentafluorophenyloxy group and the like, and preferable from the standpoints of solubility in organic solvents, device properties, easiness of synthesis and the like are C₁ to C₁₂ alkoxyphenoxy groups and C₁ to C₁₂ alkylphenoxy groups.

Examples of the C₁ to C₁₂ alkoxy include methoxy, ethoxy, propyloxy, i-propyloxy, butoxy, i-butoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, lauryloxy and the like.

Examples of the C₁ to C₁₂ alkylphenoxy group include a methylphenoxy group, ethylphenoxy group, dimethylphenoxy group, propylphenoxy group, 1,3,5-trimethylphenoxy group, methylethylphenoxy group, i-propylphenoxy group, butylphenoxy group, i-butylphenoxy group, t-butylphenoxy group, pentylphenoxy group, isoamylphenoxy group, hexylphenoxy group, heptylphenoxy group, octylphenoxy group, nonylphenoxy group, decylphenoxy group, dodecylphenoxy group and the like.

The arylthio group has a carbon number of usually about from 3 to 60, and examples thereof include a phenylthio group, C₁ to C₁₂ alkoxyphenylthio groups, C₁ to C₁₂ alkylphenylthio groups, 1-naphthylthio group, 2-naphthylthio group, pentafluorophenylthio group and the like, and mentioned from the standpoints of solubility in organic solvents, device properties, easiness of synthesis and the like are C₁ to C₁₂ alkoxyphenylthio groups and C₁ to C₁₂ alkylphenylthio groups.

The arylalkyl group has a carbon number of usually about from 7 to 60, preferably 7 to 48, and examples thereof include phenyl C₁ to C₁₂ alkyl groups, C₁ to C₁₂ alkoxyphenyl-C₁ to C₁₂ alkyl groups, C₁ to C₁₂ alkylphenyl-C₁ to C₁₂ alkyl groups, 1-naphthyl-C₁ to C₁₂ alkyl groups, 2-naphthyl-C₁ to C₁₂ alkyl groups and the like, and preferable from the standpoints of solubility in organic solvents, device properties, easiness of synthesis and the like are C₁ to C₁₂ alkoxyphenyl-C₁ to C₁₂ alkyl groups and C₁ to C₁₂ alkylphenyl-C₁ to C₁₂ alkyl groups.

The arylalkoxy group has a carbon number of usually about from 7 to 60, preferably a carbon number of 7 to 48, and examples thereof include phenyl-C₁ to C₁₂ alkoxy groups such as a phenylmethoxy group, phenylethoxy group, phenylbutoxy group, phenylpentyloxy group, phenylhexyloxy group, phenylheptyloxy group, phenyloctyloxy group and the like, C₁ to C₁₂ alkoxyphenyl-C₁ to C₁₂ alkoxy groups, C₁ to C₁₂ alkylphenyl-C₁ to C₁₂ alkoxy groups, 1-naphthyl-C₁ to C₁₂ alkoxy groups, 2-naphthyl-C₁ to C₁₂ alkoxy groups and the like, and mentioned from the standpoints of solubility in organic solvents, device properties, easiness of synthesis and the like are C₁ to C₁₂ alkoxyphenyl-C₁ to C₁₂ alkoxy groups and C₁ to C₁₂ alkylphenyl-C₁ to C₁₂ alkoxy groups.

The arylalkylthio group has a carbon number of usually about from 7 to 60, preferably a carbon number of 7 to 48, and examples thereof include phenyl-C₁ to C₁₂ alkylthio groups, C₁ to C₁₂ alkoxyphenyl-C₁ to C₁₂ alkylthio groups, C₁ to C₁₂ alkylphenyl-C₁ to C₁₂ alkylthio groups, 1-naphthyl-C₁ to C₁₂ alkylthio groups, 2-naphthyl-C₁ to C₁₂ alkylthio groups and the like, and mentioned from the standpoints of solubility in organic solvents, device properties, easiness of synthesis and the like are C₁ to C₁₂ alkoxyphenyl-C₁ to C₁₋₂ alkylthio groups and C₁ to C₁₂ alkylphenyl-C₁ to C₁₋₂ alkylthio groups.

The arylalkenyl group has a carbon number of usually about from 8 to 60, and as examples thereof include phenyl-C₂ to C₁₂ alkenyl groups, C₁ to C₁₂ alkoxyphenyl-C₂ to C₁₂ alkenyl groups, C₁ to C₁₂ alkylphenyl-C₂ to C₁₂ alkenyl groups, 1-naphthyl-C₂ to C₁₂ alkenyl groups, 2-naphthyl-C₂ to C₁₂ alkenyl groups and the like, and mentioned from the standpoints of solubility in organic solvents, device properties, easiness of synthesis and the like are C₁ to C₁₋₂ alkoxyphenyl-C₂ to C₁₂ alkenyl groups and C₂ to C₁₂ alkylphenyl-C₁ to C₁₋₂ alkenyl groups.

The arylalkynyl group has a carbon number of usually about from 8 to 60, and examples thereof include phenyl-C₂ to C₁₂ alkynyl groups, C₁ to C₁₂ alkoxyphenyl-C₂ to C₁₂ alkynyl groups, C₁ to C₁₂ alkylphenyl-C₂ to C₁₂ alkynyl groups, 1-naphthyl-C₂ to C₁₂ alkynyl groups, 2-naphthyl-C₂ to C₁₂ alkynyl groups and the like, and mentioned from the standpoints of solubility in organic solvents, device properties, easiness of synthesis and the like are C₁ to C₁₂ alkoxyphenyl-C₂ to C₁₂ alkynyl groups and C₁ to C₁₂ alkylphenyl-C₂ to C₁₂ alkynyl groups.

The substituted amino group includes amino groups substituted by one or two groups selected from alkyl groups, aryl groups, arylalkyl groups or monovalent heterocyclic groups, and the alkyl group, aryl group, arylalkyl group or monovalent heterocyclic group optionally has a substituent. The carbon number of the substituted amino group is usually about from 1 to 60, preferably 2 to 48 not including the carbon number of the substituent.

Examples include a methylamino group, dimethylamino group, ethylamino group, diethylamino group, propylamino group, dipropylamino group, i-propylamino group, diisopropylamino group, butylamino group, i-butylamino group, t-butylamino group, pentylamino group, hexylamino group, cyclohexylamino group, heptylamino group, octylamino group, 2-ethylhexylamino group, nonylamino group, decylamino group, 3,7-dimethyloctylamino group, laurylamino group, cyclopentylamino group, dicyclopentylamino group, cyclohexylamino group, dicyclohexylamino group, pyrrolidyl group, piperidyl group, ditrifluoromethylamino group, phenylamino group, diphenylamino group, C₁ to C₁₂ alkoxyphenylamino groups, di(C₁ to C₁₂ alkoxyphenyl)amino groups, di(C₁ to C₁₂ alkylphenyl)amino groups, 1-naphthylamino group, 2-naphthylamino group, pentafluorophenylamino group, pyridylamino group, pyridazinylamino group, pyrimidylamino group, pyrazylamino group, triazylamino group, phenyl C₁ to C₁₂ alkylamino groups, C₁ to C₁₂ alkoxyphenyl-C₁ to C₁₂ alkylamino groups, C₁ to C₁₂ alkylphenyl-C₁ to C₁₂ alkylamino groups, di(C₁ to C₁₂ alkoxyphenyl-C₁ to C₁₂ alkyl)amino groups, di(C₁ to C₁₂ alkylphenyl-C₁ to C₁₂ alkyl)amino groups, 1-naphthyl-C₁ to C₁₂ alkylamino groups, 2-naphthyl-C₁ to C₁₂ alkylamino groups and the like.

The substituted silyl group includes silyl groups substituted by one, two or three groups selected from alkyl groups, aryl groups, arylalkyl groups or monovalent heterocyclic groups. The carbon number of the substituted silyl group is usually about from 1 to 60, preferably 3 to 48. The alkyl group, aryl group, arylalkyl group or monovalent heterocyclic group optionally has a substituent.

Examples include a trimethylsilyl group, triethylsilyl group, tripropylsilyl group, tri-i-propylsilyl group, dimethyl-i-propylsilyl group, diethyl-i-propylsilyl group, t-butylsilyldimethylsilyl group, pentyldimethylsilyl group, hexyldimethylsilyl group, heptyldimethylsilyl group, octyldimethylsilyl group, 2-ethylhexyl-dimethylsilyl group, nonyldimethylsilyl group, decyldimethylsilyl group, 3,7-dimethyloctyl-dimethylsilyl group, lauryldimethylsilyl group, phenyl-C₁ to C₁₂ alkylsilyl groups, C₁ to C₁₂ alkoxyphenyl-C₁ to C₁₂ alkylsilyl groups, C₁ to C₁₂ alkylphenyl-C₁ to C₁₂ alkylsilyl groups, 1-naphthyl-C₁ to C₁₂ alkylsilyl groups, 2-naphthyl-C₁ to C₁₂ alkylsilyl groups, phenyl-C₁ to C₁₂ alkyldimethylsilyl groups, triphenylsilyl group, tri-p-xylylsilyl group, tribenzylsilyl group, diphenylmethylsilyl group, t-butyldiphenylsilyl group, dimethylphenylsilyl group and the like.

Examples of the halogen atom include a fluorine atom, chlorine atom, bromine atom and iodine atom are exemplified.

The acyl group has a carbon number of usually about from 2 to 20, preferably a carbon number of 2 to 18, and examples thereof include an acetyl group, propionyl group, butyryl group, isobutyryl group, pivaloyl group, benzoyl group, trifluoroacetyl group, pentafluorobenzoyl group and the like.

The acyloxy group has a carbon number of usually about from 2 to 20, preferably a carbon number of 2 to 18, and examples thereof include an acetoxy group, propionyloxy group, butyryloxy group, isobutyryloxy group, pivaloyloxy group, benzoyloxy group, trifluoroacetyloxy group, pentafluorobenzoyloxy group and the like.

The imine residue has a carbon number of about from 2 to 20, preferably a carbon number of 2 to 18, and examples thereof include groups of the following structural formulae and the like.

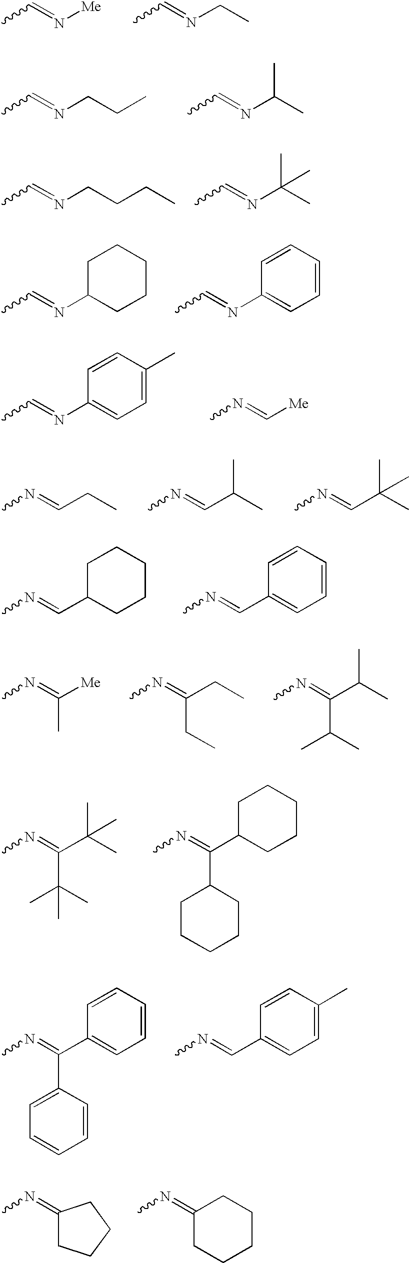

The amide group has a carbon number of usually about from 2 to 20, preferably a carbon number of 2 to 18, and examples thereof include a formamide group, acetamide group, propioamide group, butyroamide group, benzamide group, trifluoroacetamide group, pentafluorobenzamide group, diformamide group, diacetamide group, dipropioamide group, dibutyroamide group, dibenzamide group, ditrifluoroacetamide group, dipentafluorobenzamide group and the like.

The acid imide group includes residues obtained by removing from an acid imide a hydrogen atom connected to its nitrogen atom, and the carbon number thereof is about from 4 to 20, and the following groups and the like are illustrated.

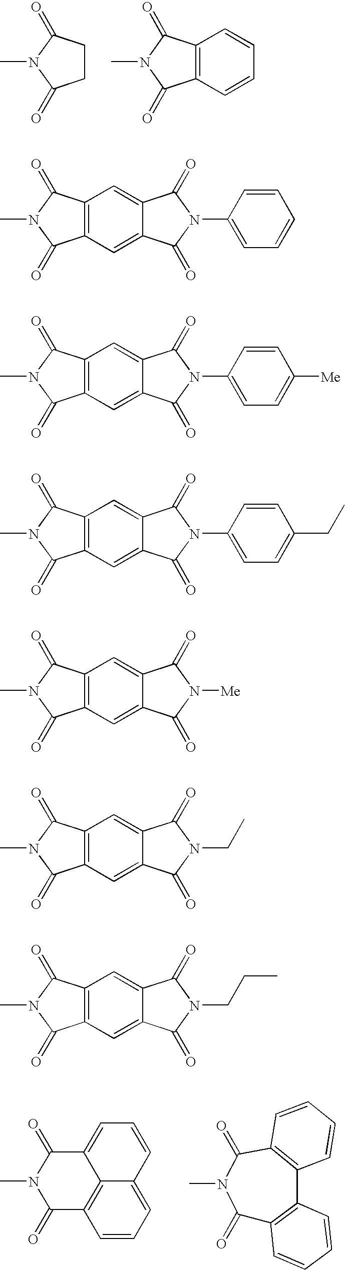

The monovalent heterocyclic group is an atomic group remaining after removing one hydrogen atom from a heterocyclic compound, and the carbon is usually about from 4 to 60, preferably 4 to 20. The carbon number of the heterocyclic group does not include the carbon number of substituents. Here, the heterocyclic compound refers to organic compounds having a cyclic structure in which elements constituting the cyclic structure include not only a carbon atom, but also a heteroatom such as oxygen, sulfur, nitrogen, phosphorus, boron and the like contained in the ring. Examples include a thienyl group, C₁ to C₁₂ alkylthienyl groups, pyrrolyl group, furyl group, pyridyl group, C₁ to C₁₂ alkylpyridyl groups, piperidyl, quinolyl group, isoquinolyl group and the like, and preferable are a thienyl group, C₁ to C₁₂ alkylthienyl groups, pyridyl group and C₁ to C₁₂ alkylpyridyl groups.

The substituted carboxyl group includes carboxyl groups substituted by an alkyl group, aryl group, arylalkyl group or monovalent heterocyclic group, and the carbon number thereof is usually about from 2 to 60, preferably 2 to 48, and examples thereof include a methoxycarbonyl group, ethoxycarbonyl group, propoxycarbonyl group, i-propoxycarbonyl group, butoxycarbonyl group, i-butoxycarbonyl group, t-butoxycarbonyl group, pentyloxycarbonyl group, hexyloxycarbonyl group, cyclohexyloxycarbonyl group, heptyloxycarbonyl group, octyloxycarbonyl group, 2-ethylhexyloxycarbonyl group, nonyloxycarbonyl group, decyloxycarbonyl group, 3,7-dimethyloctyloxycarbonyl group, dodecyloxycarbonyl group, trifluoromethoxycarbonyl group, pentafluoroethoxycarbonyl group, perfluorobutoxycarbonyl group, perfluorohexyloxycarbonyl group, perfluorooctyloxycarbonyl group, phenoxycarbonyl group, naphthoxycarbonyl group, pyridyloxycarbonyl group and the like. The alkyl group, aryl group, arylalkyl group or monovalent heterocyclic group optionally has a substituent. The carbon number of the substituted carboxyl group does not include the carbon number of the substituent.

In the formula (1), Ar² represents an arylene group or divalent aromatic heterocyclic group optionally having a substituent. Two Ar²s may be the same or different. Ar² preferably represent an arylene group.

Here, the arylene group is an atomic group obtained by removing two hydrogen atoms from an aromatic hydrocarbon, and includes those having an independent benzene ring or condensed ring. The arylene group has a carbon number of usually about from 6 to 60, preferably 6 to 48, more preferably 6 to 30, even preferably 6 to 18, further preferably 6 to 10, and particularly preferably 6. This carbon number does not include the carbon number of substituents. Examples of the arylene group include a 1,4-phenylene group, 1,3-phenylene group, 1,2-phenylene group, 1,4-naphthylene group, 1,5-naphthylene group, 2,6-naphthylene group, 1,4-anthracenylene group, 1,5-anthracenylene group, 2,6-anthracenylene group, 9,10-anthracenylene group, 2,7-phenanthrylene group, 1,7-naphthacenylene group, 2,8-naphthacenylene group and the like, preferably a 1,4-phenylene group, 1,3-phenylene group, 1,2-phenylene group, 1,5-naphthylene group, 2,6-naphthylene group, 1,4-anthracenylene group, 1,5-anthracenylene group, 2,6-anthracenylene group and 9,10-anthracenylene group, more preferably a 1,4-phenylene group, 1,3-phenylene group, 1,2-phenylene group, 1,5-naphthylene group and 2,6-naphthylene group, further preferably a 1,4-phenylene group, 1,3-phenylene group and 1,2-phenylene group, and particularly preferably a 1,4-phenylene group.

The divalent aromatic heterocyclic group is an atomic group remaining after removing two hydrogen atoms from an aromatic heterocyclic group, and the carbon number thereof is usually about from 4 to 60, preferably 4 to 20, more preferably 4 to 9, and further preferably 4 to 5. Examples of the divalent aromatic heterocyclic group include a 2,5-thienyl group, 2,5-pyrrolyl group, 2,5-furyl group, 2,4-pyridyl group, 2,6-pyridyl group, 2,4-quinolyl group, 2,6-quinolyl group, 1,4-isoquinolyl group, 1,5-isoquinolyl group and the like, preferable are a 2,5-thienyl group, 2,4-pyridyl group, 2,6-pyridyl group, 2,4-quinolyl group, 2,6-quinolyl group, 1,4-isoquinolyl group and 1,5-isoquinolyl group, more preferable are a 2,5-thienyl group, 2,4-pyridyl group and 2,6-pyridyl group, and further preferable are a 2,4-pyridyl group and 2,6-pyridyl group.

When Ar² has a substituent, it is preferable from the standpoints of solubility in organic solvents, device properties, easiness of synthesis and the like that the substituent is selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group. The substituent is more preferably selected from an alkyl group, alkoxy group, aryl group, aryloxy group, arylalkyl group, arylalkoxy group, substituted amino group, substituted silyl group, acyl group, substituted carboxyl group and cyano group, even preferably selected from an alkyl group, alkoxy group, aryl group, aryloxy group, arylalkyl group, arylalkoxy group and substituted carboxyl group, further preferably selected from an alkyl group, alkoxy group and aryl group, and the substituent is particularly preferably an alkyl group.

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group are the same as the definitions and examples for a substituent when Ar¹ in the above-described formula (1) has a substituent.

Z in the formula (1) represents a divalent aromatic group having a condensed ring structure. This group optionally has a substituent. Here, the divalent aromatic group having a condensed ring structure is an atomic group obtained by removing two hydrogen atoms from an aromatic hydrocarbon compound or aromatic heterocyclic compound having a condensed ring. The divalent aromatic group has a carbon number of usually about from 6 to 60, preferably 6 to 48, more preferably 10 to 30, even preferably 10 to 22, further preferably 10 to 18, above all preferably 12 to 16, and particularly preferably 14. This carbon number does not include the carbon number of substituents. Examples of the divalent aromatic group include a 1,4-naphthylene group, 1,5-naphthylene group, 2,6-naphthylene group, 1,4-anthracenediyl group, 1,5-anthracenediyl group, 2,6-anthracenediyl group, 9,10-anthracenediyl group, 2,7-phenanthrylene group, 1,7-naphthacenylene group, 2,8-naphthacenylene group, 2,7-fluorenediyl group, 2,7-pyrenediyl group, 4,10-pyrenediyl group, 2,6-quinolinediyl group, 1,5-isoquinolinediyl group, 5,8-quinoxalinediyl group, 4,7-benzo[1,2,5]thiadiazolediyl group, 4,7-benzothiazolediyl group, 2,7-carbazolediyl group, 3,7-dibenzofurandiyl group, 3,7-dibenzothiophenediyl group, 3,7-phenoxazinediyl group and the like, preferably a 1,4-naphthylene group, 1,5-naphthylene group, 2,6-naphthylene group, 1,4-anthracenediyl group, 1,5-anthracenediyl group, 2,6-anthracenediyl group, 9,10-anthracenediyl group, 2,7-fluorenediyl group, 5,8-quinoxalinediyl group, 4,7-benzo[1,2,5]thiadiazolediyl group, 4,7-benzothiazolediyl group, 2,7-carbazolediyl group, 3,7-dibenzofurandiyl group, 3,7-dibenzothiophenediyl group and 3,7-phenoxazinediyl group, more preferably a 1,4-naphthylene group, 1,5-naphthylene group, 2,6-naphthylene group, 1,4-anthracenediyl group, 1,5-anthracenediyl group, 2,6-anthracenediyl group, 9,10-anthracenediyl group, 2,7-fluorenediyl group, 4,7-benzo[1,2,5]thiadiazolediyl group, even preferably a 1,4-naphthylene group, 1,5-naphthylene group, 2,6-naphthylene group, 1,4-anthracenediyl group, 1,5-anthracenediyl group, 2,6-anthracenediyl group, 9,10-anthracenediyl group and 2,7-fluorenediyl group, further preferably a 1,4-anthracenediyl group, 1,5-anthracenediyl group, 2,6-anthracenediyl group, 9,10-anthracenediyl group and 2,7-fluorenediyl group, above all preferably a 9,10-anthracenediyl group and 2,7-fluorenediyl group, and particularly preferably a 9,10-anthracenediyl group.

When Z has a substituent, it is preferable from the standpoints of solubility in organic solvents, device properties, easiness of synthesis and the like that the substituent is selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group. The substituent is more preferably selected from an alkyl group, alkoxy group, aryl group, aryloxy group, arylalkyl group, arylalkoxy group, substituted amino group, substituted silyl group, acyl group, substituted carboxyl group and cyano group, even preferably selected from an alkyl group, alkoxy group, aryl group, aryloxy group, arylalkyl group, arylalkoxy group and substituted carboxyl group, further preferably selected from an alkyl group, alkoxy group and aryl group, and the substituent is particularly preferably an alkyl group.

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group are the same as the definitions and examples for a substituent when Ar¹ in the above-described formula (1) has a substituent.

The repeating unit of the formula (1) includes the following repeating units (S-1 to S-51), and these repeating units having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like.

In the following formulae, bonds in aromatic hydrocarbon rings can take any position.

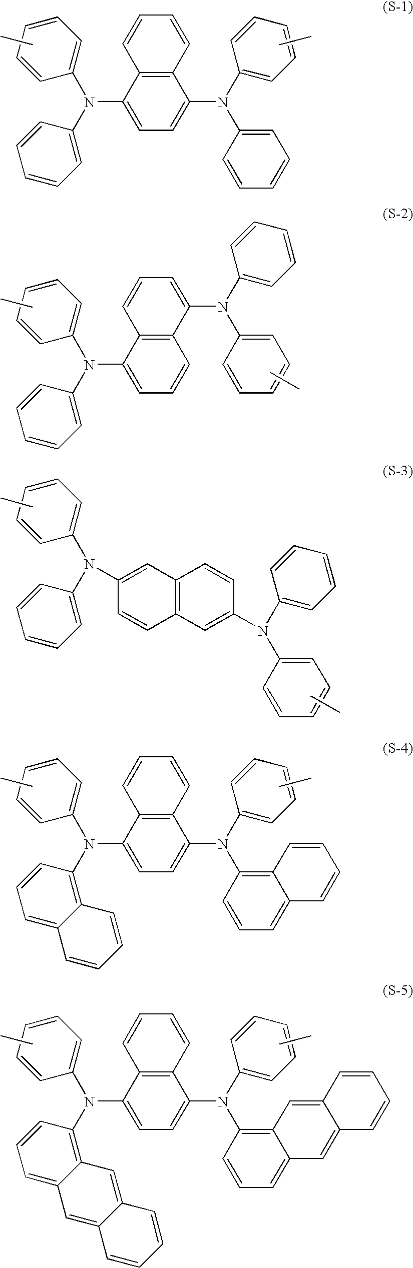

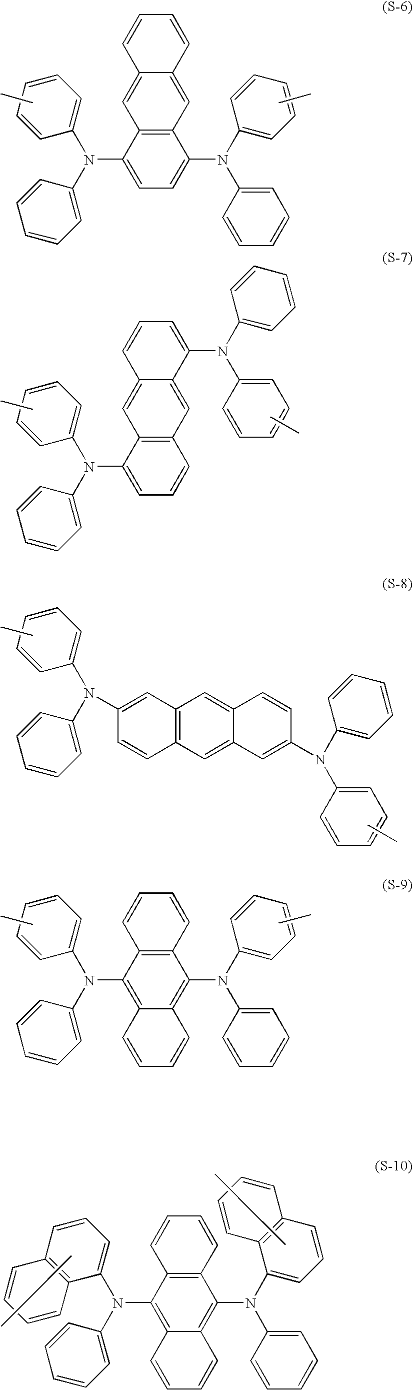

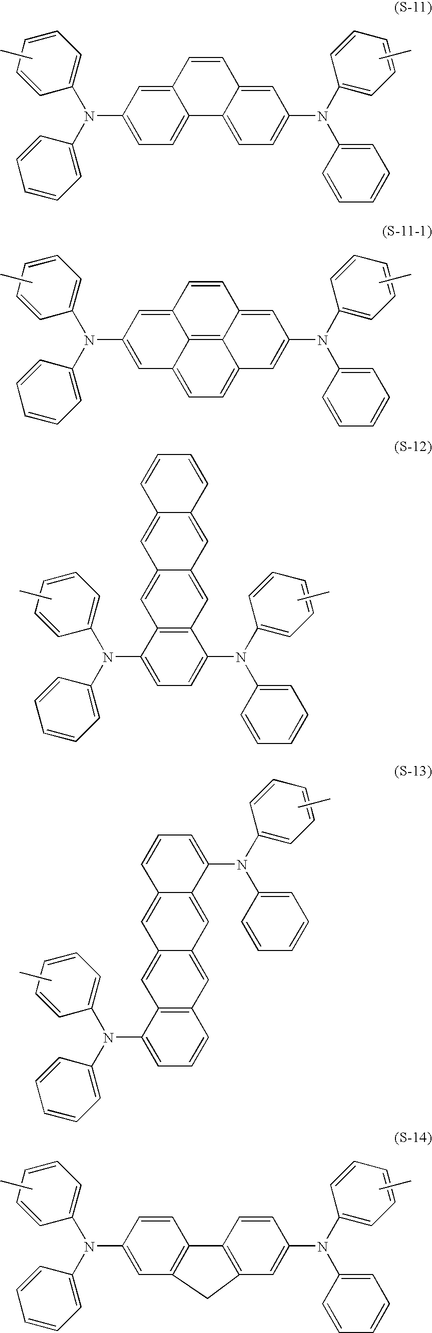

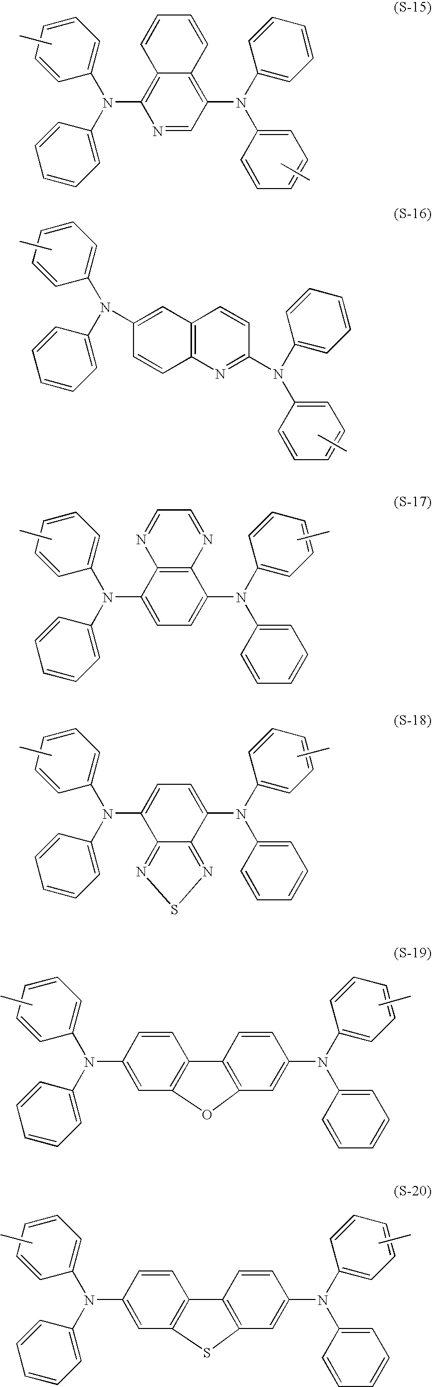

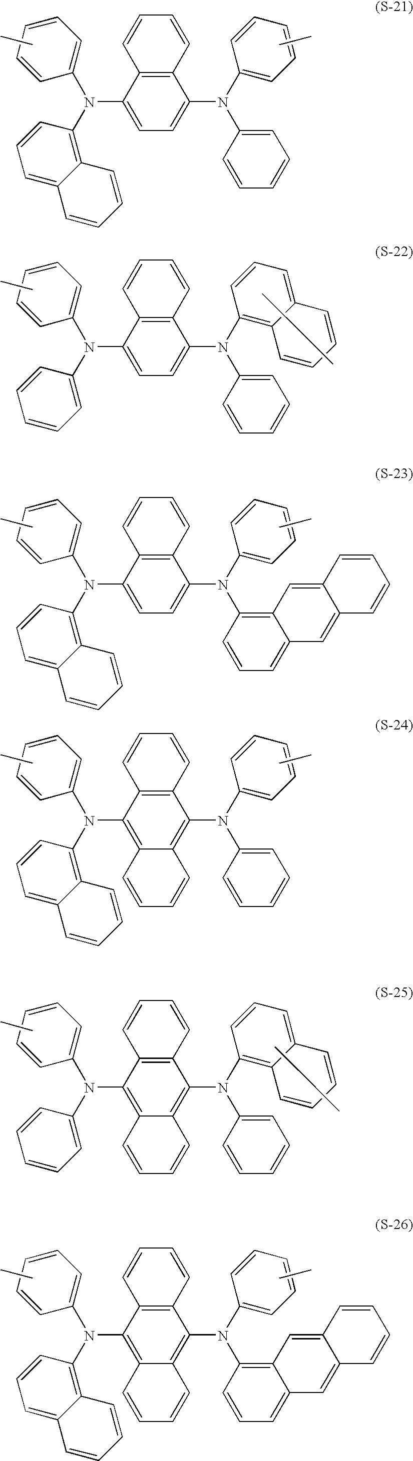

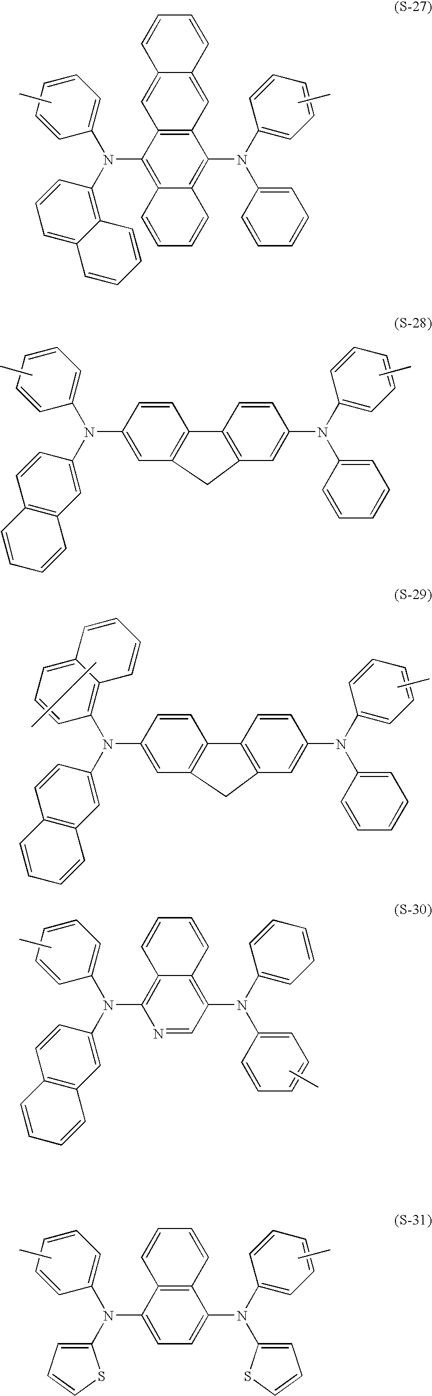

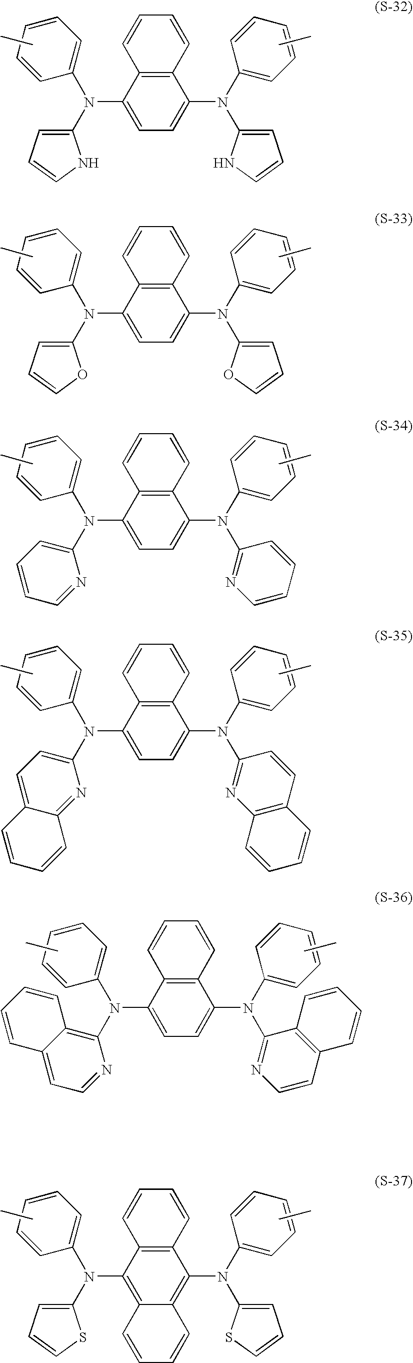

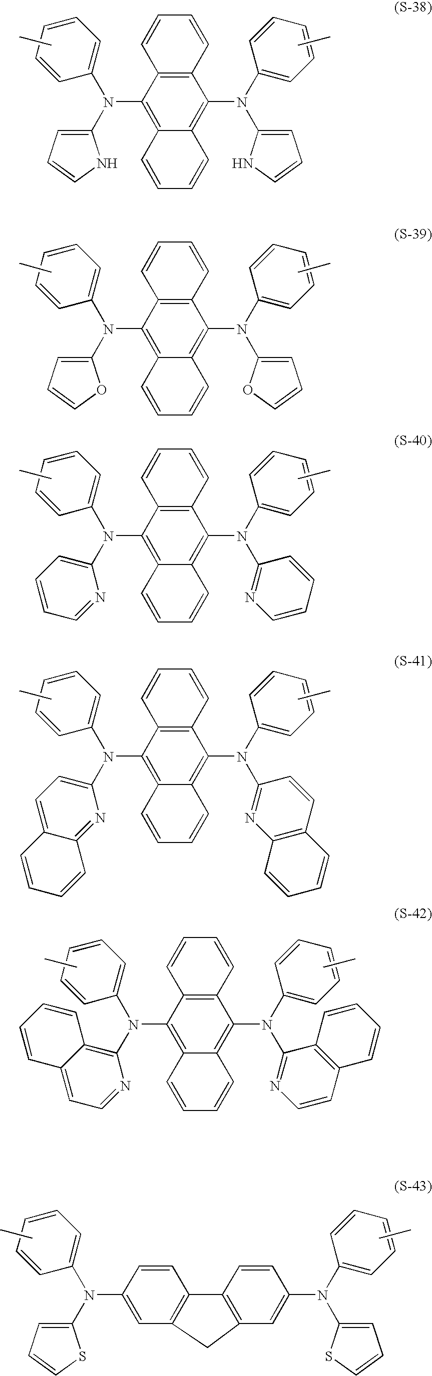

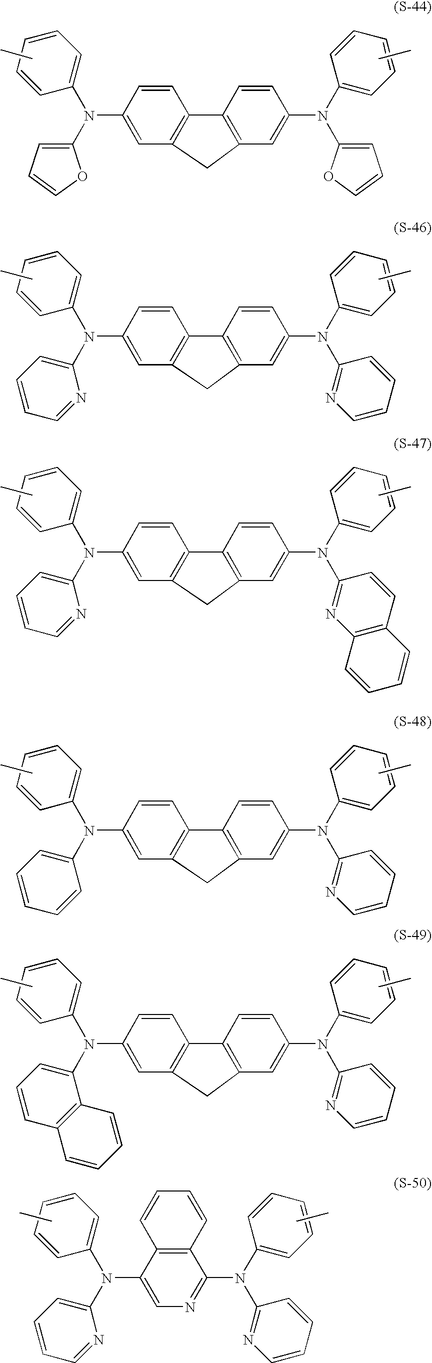

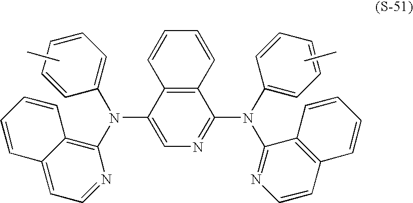

The repeating unit of the formula (1) includes preferably S-1 to S-3, S-6 to S-9, S-11 to S-20, S-31 to S-34, S-37 to S-40, S-43 to S-46, S-48 and S-50, and these S-1 to S-3, S-6 to S-9, S-11 to S-20, S-31 to S-34, S-37 to S-40, S-43 to S-46, S-48 and S-50 each having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, more preferably S-1 to S-3, S-6 to S-9, S-11 to S-20, S-34, S-40, S-46 and S-50, and these S-1 to S-3, S-6 to S-9, S-11 to S-20, S-34, S-40, S-46 and S-50 each having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, even preferably S-1 to S-3, S-6 to S-9, S-11 to S-20 each having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, further preferably S-1 to S-3, S-6 to S-9, S-14 to S-15, and these S-1 to S-3, S-6 to S-9, S-14 to S-15 each having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, and above all preferably S-9, S-14 to S-15, and these S-9, S-14 to S-15 each having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like.

From the standpoints of obtaining green light emission, and the like, particularly preferable are S-9, and S-9 having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, and for example, divalent groups of the following formula (S-52) are mentioned.

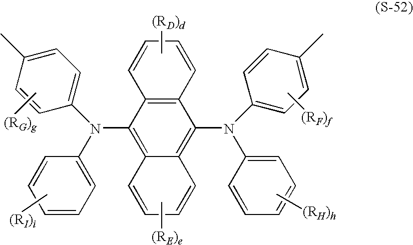

(wherein, R_{D}, R_{E}, R_{F}, R_{G}, R_{H} and R_{I} represent each independently and alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. When there are two or more R_{D}s, R_{E}s, R_{F}s, R_{G}s, R_{H}s or R_{I}s, respectively, they may be mutually the same or different. d, e, f and g represent each independently an integer of 0 to 4, and h and i represent each independently an integer of 0 to 5.).

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group represented by R_{D}, R_{E}, R_{F}, R_{G}, R_{H} and R_{I} in the formula (S-52) are the same as the definitions and examples for a substituent when Ar¹ in the above-described formula (1) has a substituent. It is preferable from the standpoints of solubility, easiness of synthesis, device properties and the like that the substituent represented by R_{D}, R_{E}, R_{F}, R_{G}, R_{H} and R_{I} in the formula (S-52) is selected from an alkyl group, alkoxy group, aryl group, aryloxy group, arylalkyl group, arylalkoxy group, substituted amino group, substituted silyl group, acyl group, substituted carboxyl group and cyano group, more preferably selected from an alkyl group, alkoxy group, aryl group, aryloxy group, arylalkyl group, arylalkoxy group and substituted carboxyl group, even preferably selected from an alkyl group, alkoxy group and aryl group, and further preferable are an alkyl group and alkoxy group, particularly preferable is an alkyl group.

d, e, f and g in the formula (S-52) represent each independently an integer of 0 to 4, preferably an integer of 0 to 2, more preferably an integer of 0 to 1, and further preferably 0.

h and i in the formula (S-52) represent each independently an integer of 0 to 5, and from the standpoints of device properties, solubility and the like, preferably an integer of 1 to 3, more preferably 1.

From the standpoint of stability of a compound, it is preferable that R_{I} and R_{H} are present at a para-position of a nitrogen atom.

From the standpoints of obtaining blue light emission, and the like, further preferable are S-14, and S-14 having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, and for example, divalent groups of the following formula (S-53) are mentioned.

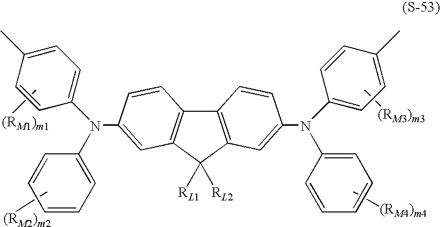

(wherein, R_{M1}, R_{M2}, R_{M3} and R_{M4} represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. When there are two or more R_{M1}s, R_{M2}s, R_{M3}s or R_{M4}s, respectively, they may be mutually the same or different. m1 and m3 represent each independently an integer of 0 to 4, and m2 and m4 represent each independently an integer of 0 to 5. R_{L1} and R_{L2} represent each independently an alkyl group, aryl group, arylalkyl group or monovalent heterocyclic group.).

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group represented by R_{M1}, R_{M2}, R_{M3} and R_{M4} in the formula (S-53) are the same as the definitions and examples for a substituent when Ar¹ in the above-described formula (1) has a substituent. It is preferable from the standpoints of solubility, easiness of synthesis, device properties and the like that the substituent represented by R_{M1}, R_{M2}, R_{M3} and R_{M4} in the formula (S-53) is selected from an alkyl group, alkoxy group, aryl group, aryloxy group, arylalkyl group, arylalkoxy group, substituted amino group, substituted silyl group, acyl group, substituted carboxyl group and cyano group, more preferably selected from an alkyl group, alkoxy group, aryl group, aryloxy group, arylalkyl group, arylalkoxy group and substituted carboxyl group, even preferably selected from an alkyl group, alkoxy group and aryl group, and further preferable are an alkyl group and alkoxy group, particularly preferable is an alkyl group.

m1 and m3 in the formula (S-53) represent each independently an integer of 0 to 4, preferably an integer of 0 to 2, more preferably an integer of 0 to 1, and further preferably 0.

m2 and m4 in the formula (S-53) represent each independently an integer of 0 to 5, and from the standpoints of device properties, solubility and the like, preferably an integer of 1 to 3, more preferably 1.

The definitions and examples of the alkyl group, aryl group, arylalkyl group or monovalent heterocyclic group represented by R_{L1} and R_{L2} in the formula (S-53) are the same as the definitions and

examples for a substituent when Ar¹ in the above-described formula (1) has a substituent. From the standpoints of solubility, easiness of synthesis, device properties and the like, the substituent represented by R_{L1} and R_{L2} in the formula (S-53) preferably include an alkyl group and aryl group.

The polymer compound of the present invention contains at least one of repeating units selected from the above-described formulae (2) and (3).

In the formula (2), a ring A and a ring B represent each independently an aromatic hydrocarbon ring optionally having a substituent, and at least one of them is an aromatic hydrocarbon ring having two or more benzene rings condensed. In the aromatic hydrocarbon ring, an aromatic hydrocarbon ring other than a benzene ring and/or a non-aromatic hydrocarbon-type condensed cyclic compound may further be condensed. In the polymer compound of the present invention, the aromatic hydrocarbon ring A and the aromatic hydrocarbon ring B may have mutually the same ring structure or different ring structures, however, it is preferable from the standpoints of heat resistance and fluorescence intensity that the aromatic hydrocarbon ring A and the aromatic hydrocarbon ring B have mutually different ring structures.

The aromatic hydrocarbon ring is preferably a single benzene ring or a ring having two or more benzene rings condensed, and examples thereof include aromatic hydrocarbon rings such as a benzene ring, naphthalene ring, anthracene ring, tetracene ring, pentacene ring, pyrene ring, phenanthrene ring and the like, and preferably a benzene ring, naphthalene ring, anthracene ring and phenanthrene ring.

As the combination of a ring A and a ring B, preferably mentioned are combinations of a benzene ring and a naphthalene ring, a benzene ring and an anthracene ring, a benzene ring and a phenanthrene ring, a naphthalene ring and an anthracene ring, a naphthalene ring and a phenanthrene ring, and an anthracene ring and a phenanthrene ring, and more preferable is a combination of a benzene ring and a naphthalene ring.

The expression that the aromatic hydrocarbon ring A and the aromatic hydrocarbon ring B have mutually different ring structures means that: when

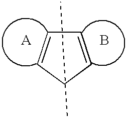

in the formula (2) is depicted by a planar structural formula, the aromatic hydrocarbon ring A and the aromatic hydrocarbon ring B are asymmetrical over a symmetrical axis (dotted line) connecting a peak of a 5-membered ring at the center of the structural formula and a middle point of a side facing the peak.

For example, when both the ring A and the ring B represent a naphthalene ring, the ring A and the ring B have different ring structures in the case of:

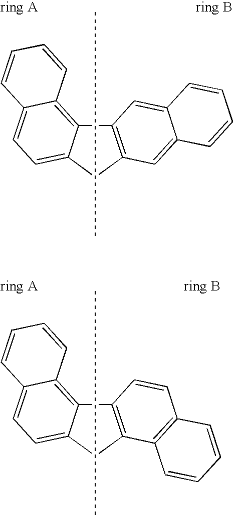

On the other hand, even if both the ring A and the ring B represent a naphthalene ring, the ring A and the ring B have the same ring structure in the case of:

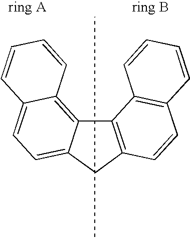

When the aromatic hydrocarbon ring has a substituent, it is preferable from the standpoints of solubility in organic solvents, device properties, easiness of synthesis and the like that the substituent is selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group. The substituent is more preferably selected from an alkyl group, alkoxy group, aryl group, aryloxy group, arylalkyl group, arylalkoxy group, substituted amino group, substituted silyl group, acyl group, substituted carboxyl group and cyano group, even preferably selected from an alkyl group, alkoxy group, aryl group, aryloxy group, arylalkyl group, arylalkoxy group and substituted carboxyl group, further preferably selected from an alkyl group, alkoxy group and aryl group, and particularly preferable is an alkyl group.

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group are the same as the definitions and examples for a substituent when Ar¹ in the above-described formula (1) has a substituent.

In the formula (2), Rw and Rx represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group, and Rw and Rx may be mutually connected to form a ring.

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group represented by Rw and Rx are the same as the definitions and examples for a substituent when Ar¹ in the above-described formula (1) has a substituent.

From the standpoints of fluorescence intensity and device light emission efficiency, it is excellent that Rw and Rx form a ring having a total number of carbon and other elements of 5 to 20.

The repeating unit of the formula (2) includes, for example the following repeating units (1A-1 to 1A-64, 1B-1 to 1B-64, 1C-1 to 1C-64, 1D-1 to 1D-18), and these units having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like.

In the following formulae, bonds in aromatic hydrocarbon rings can take any position.

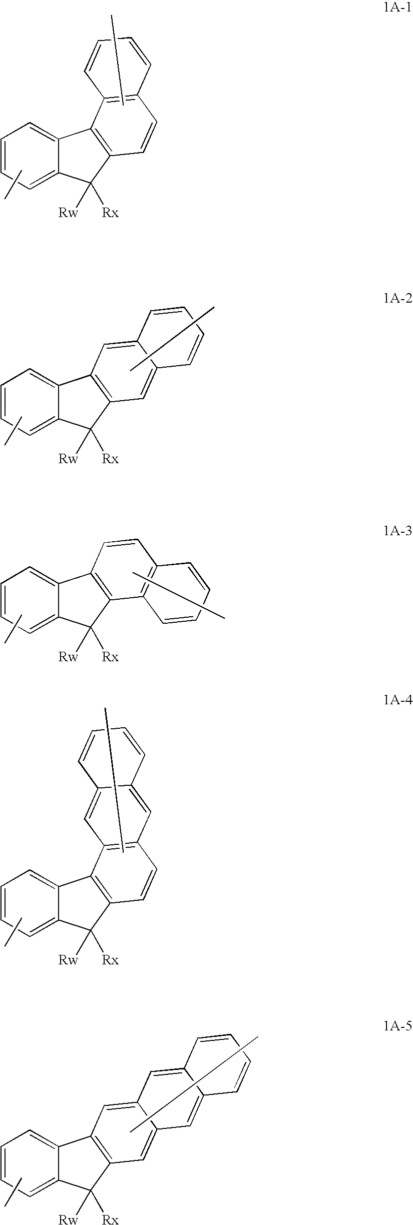

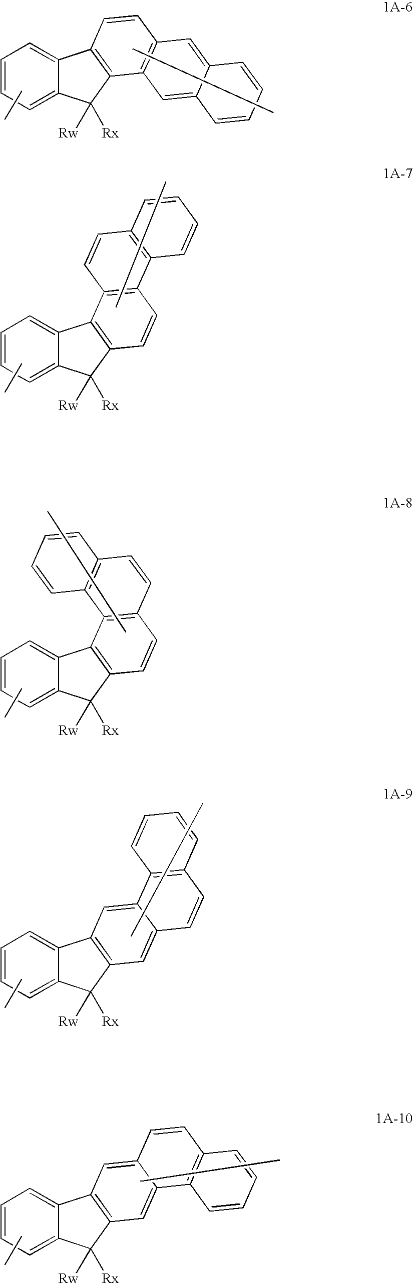

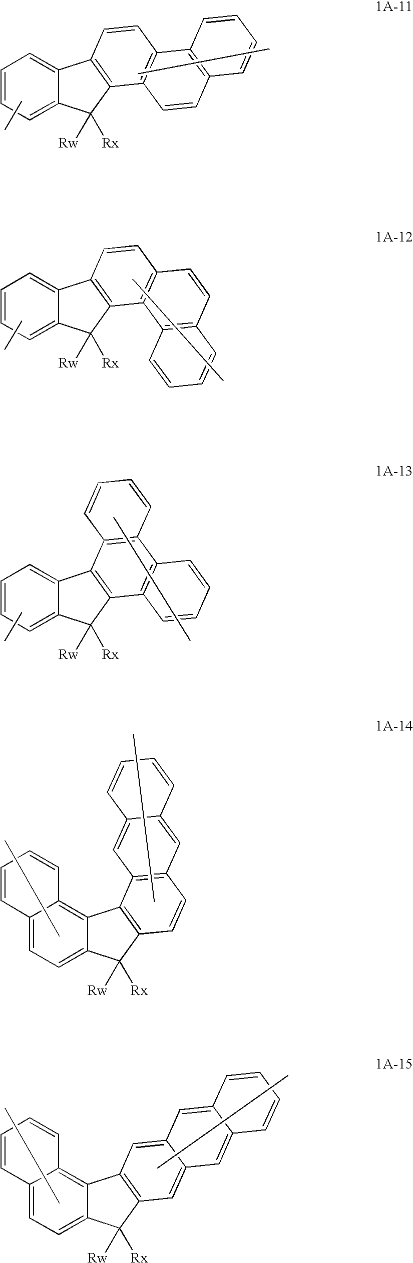

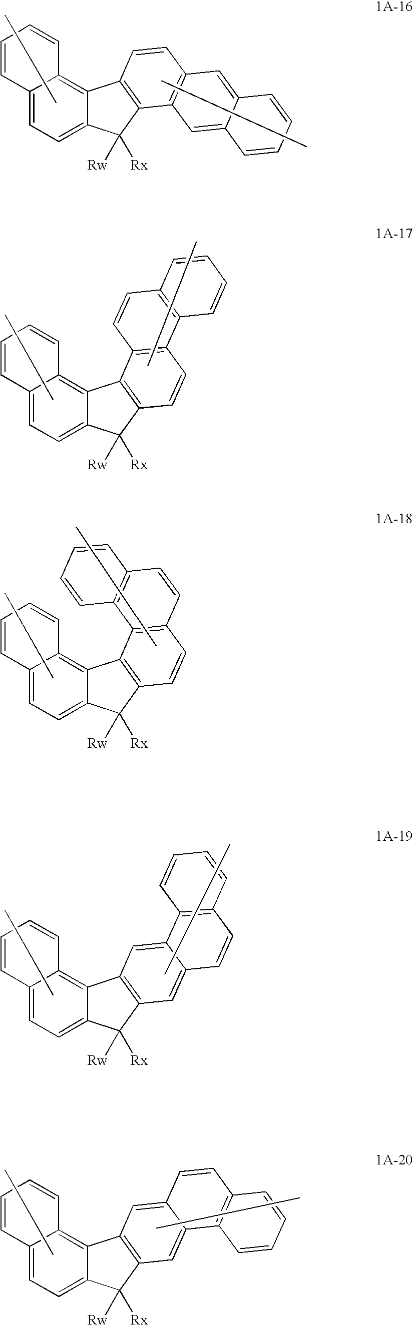

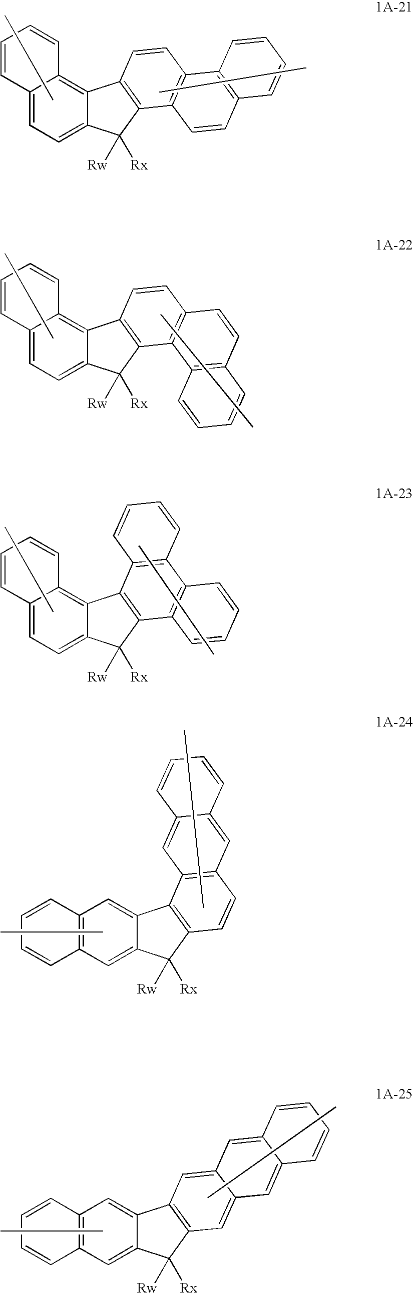

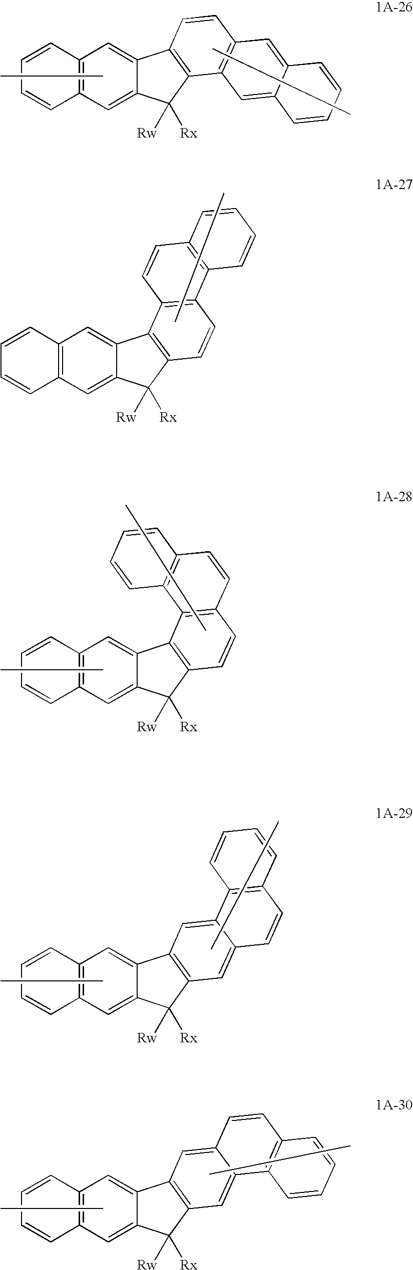

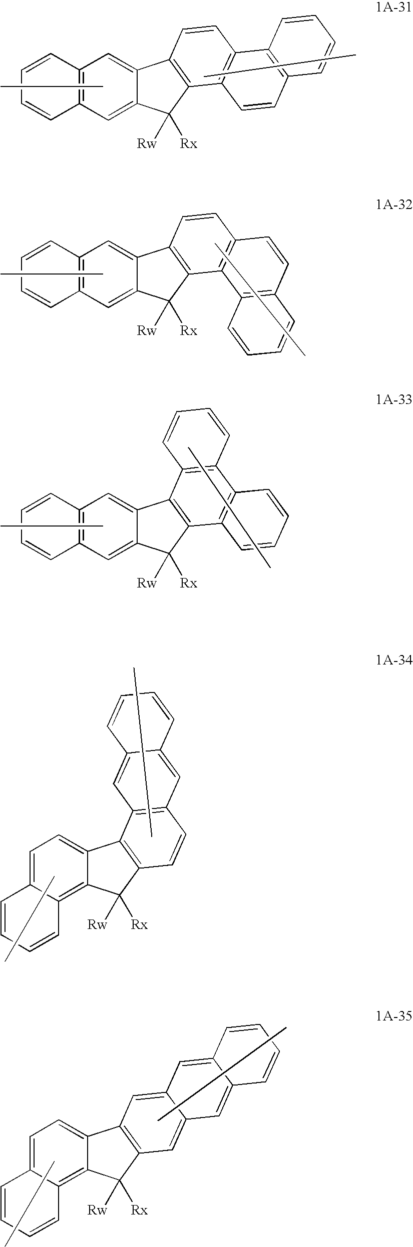

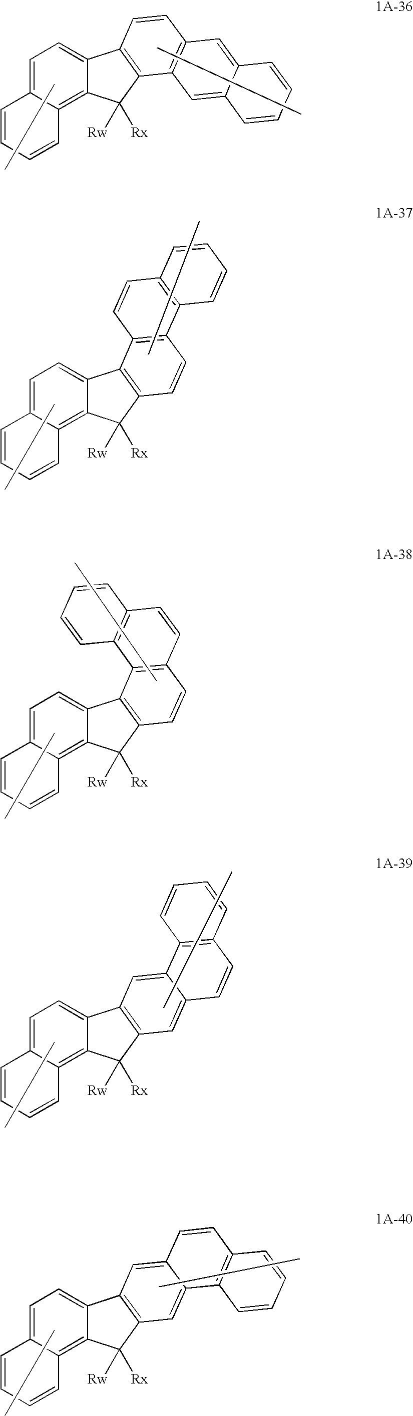

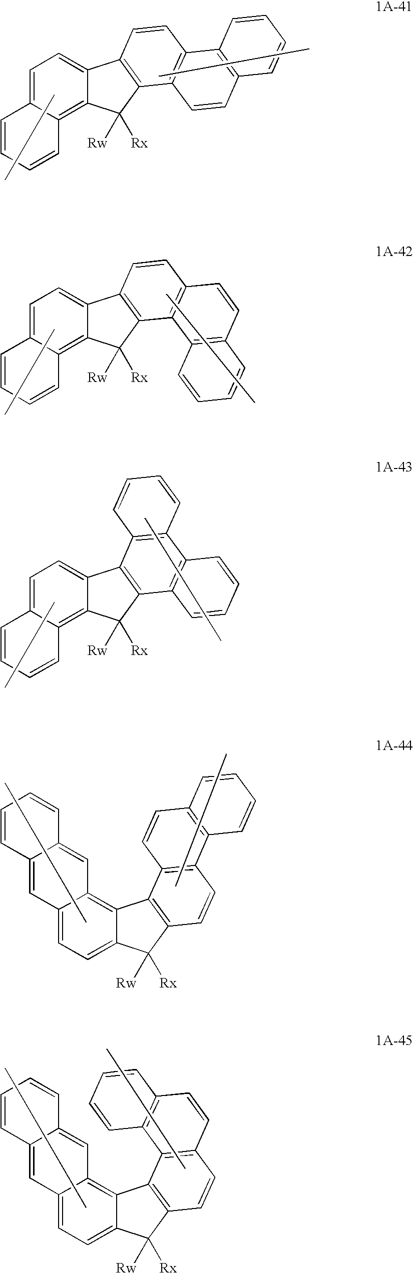

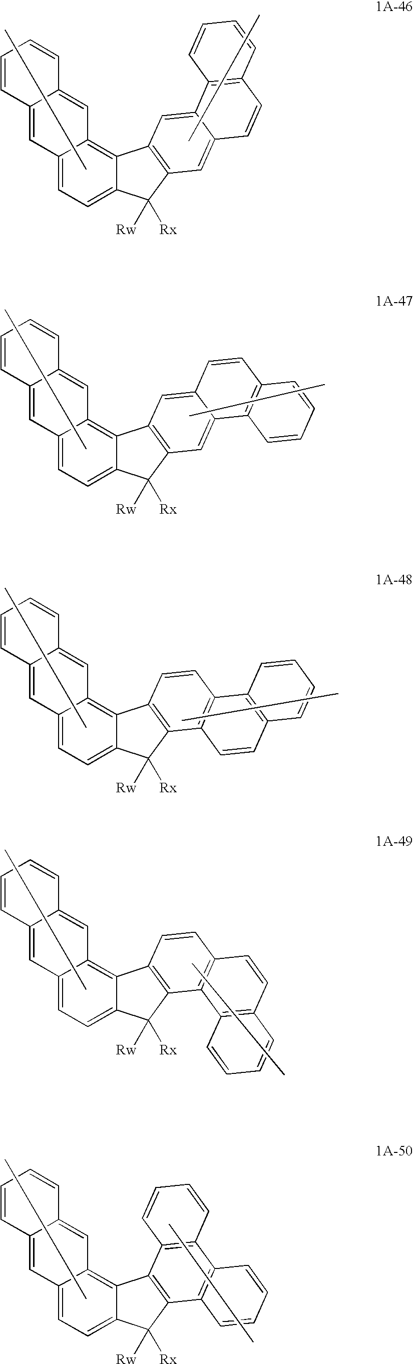

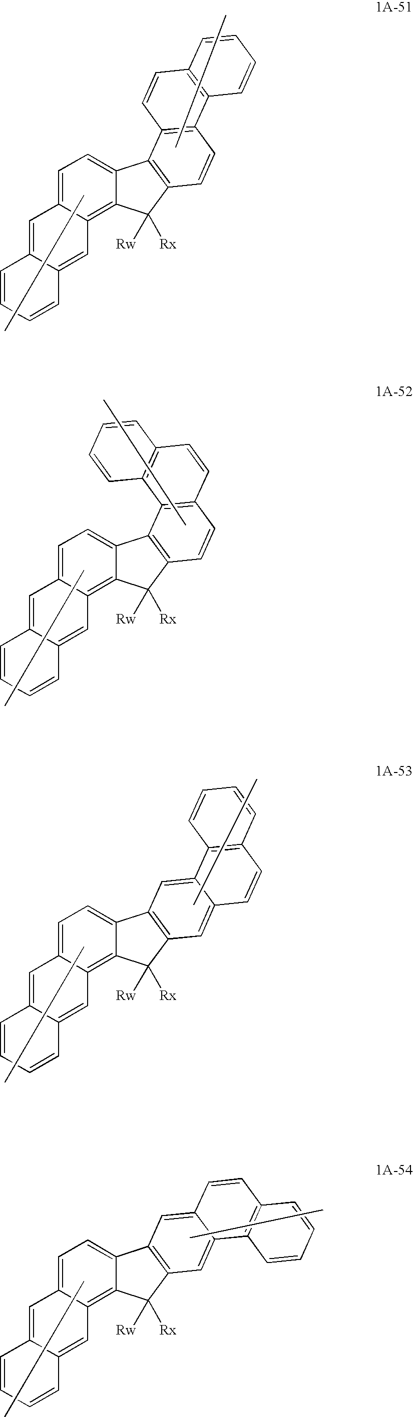

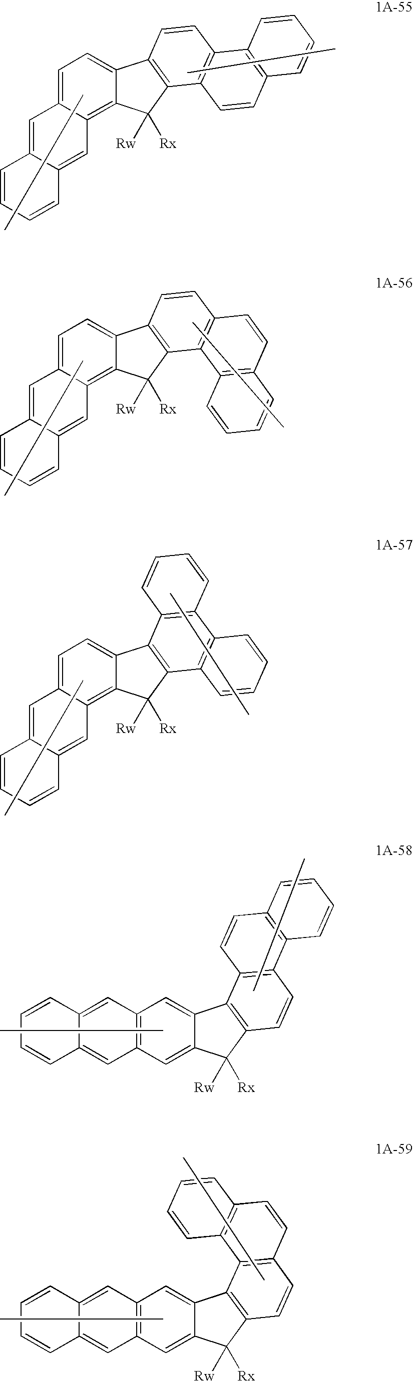

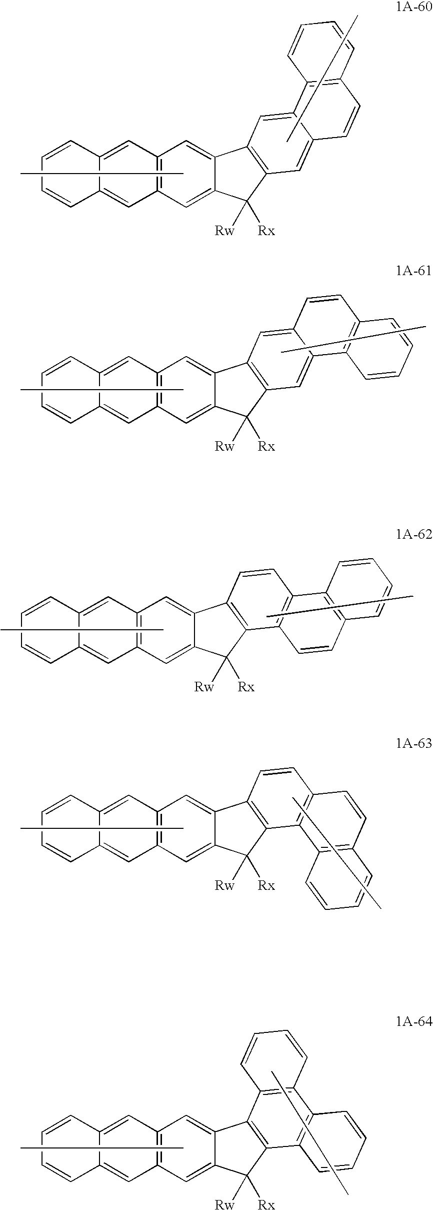

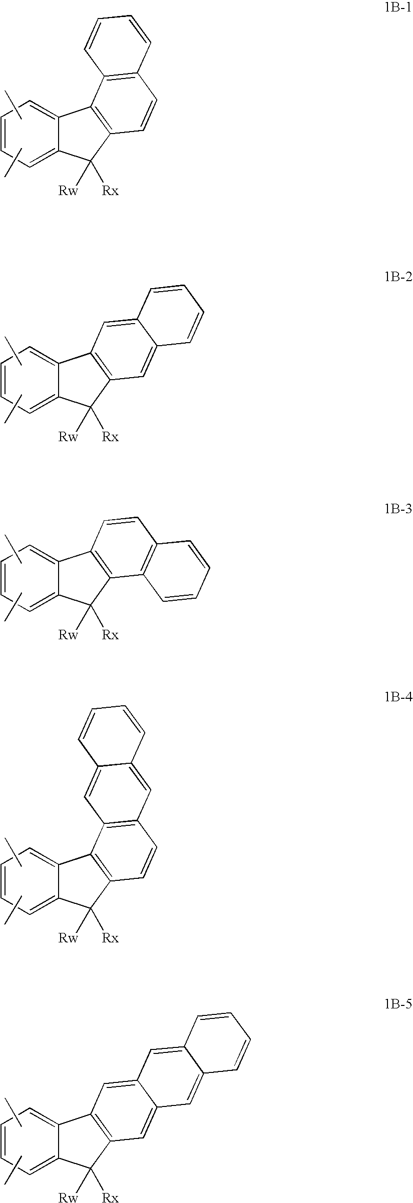

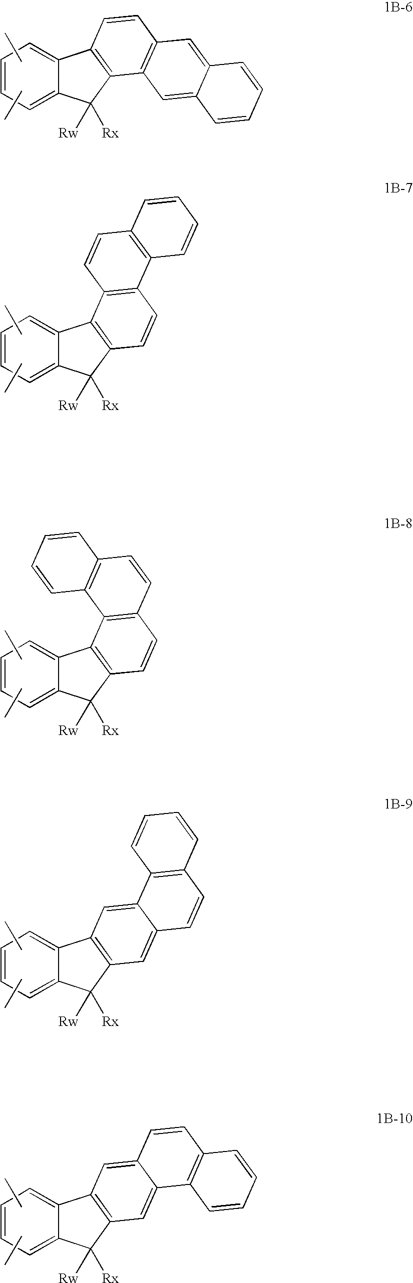

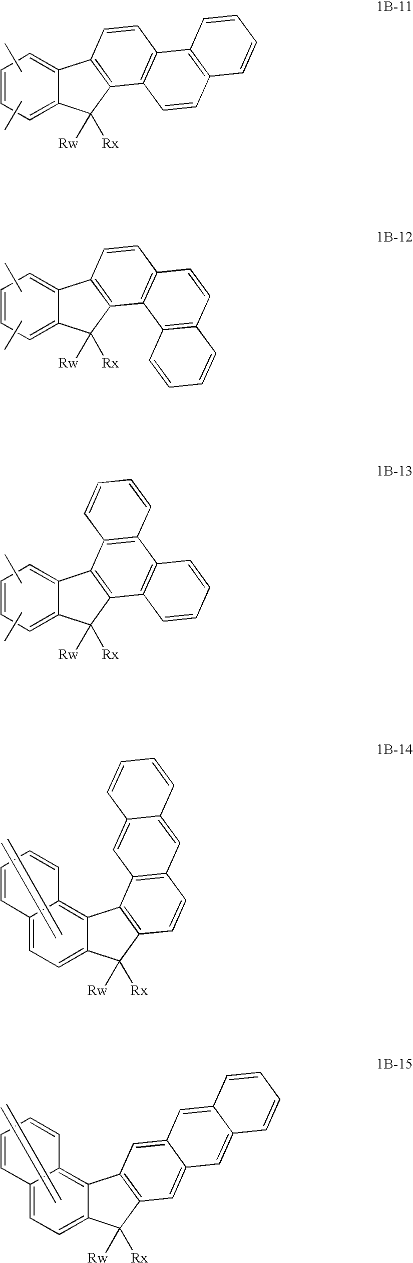

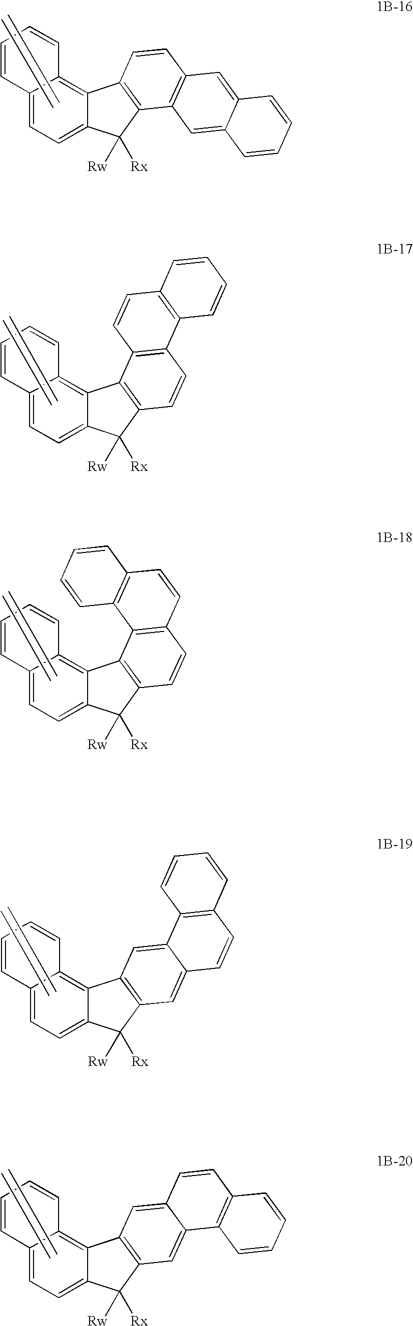

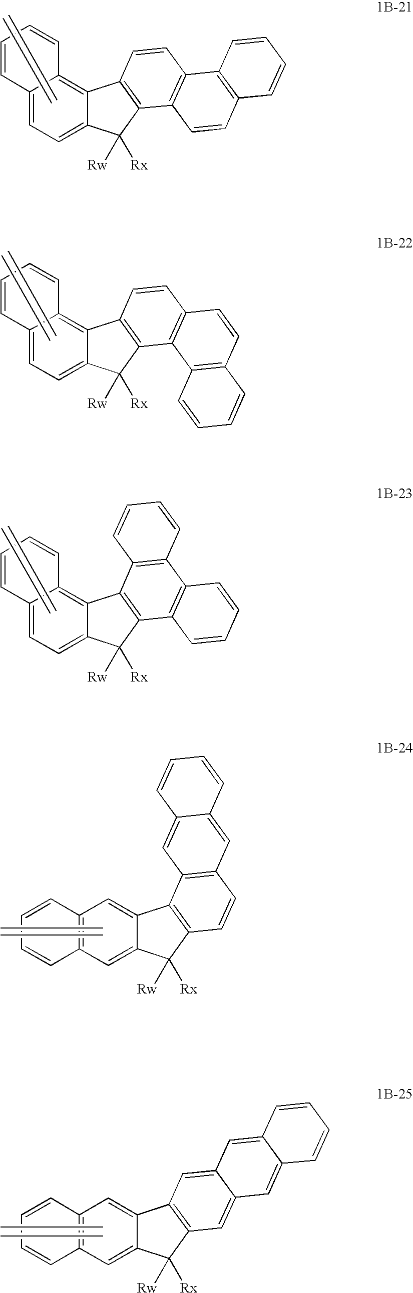

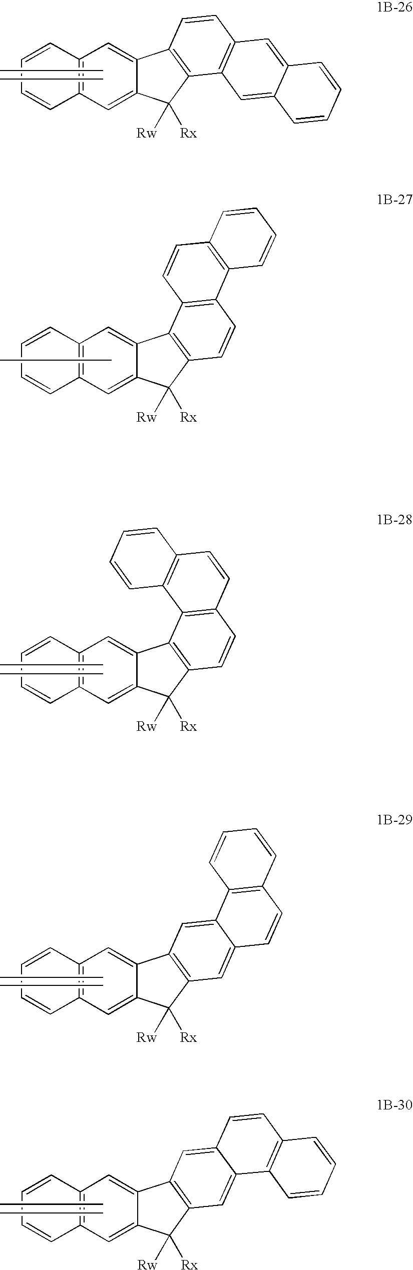

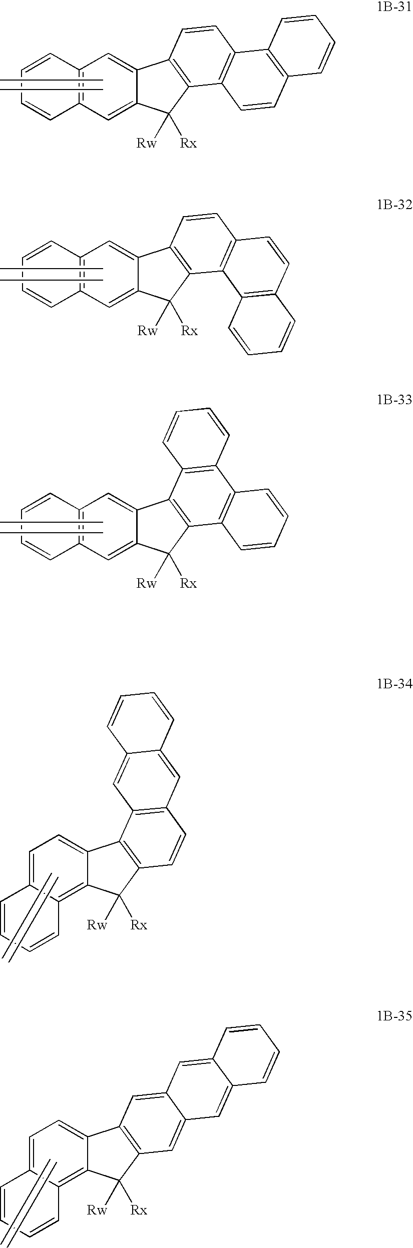

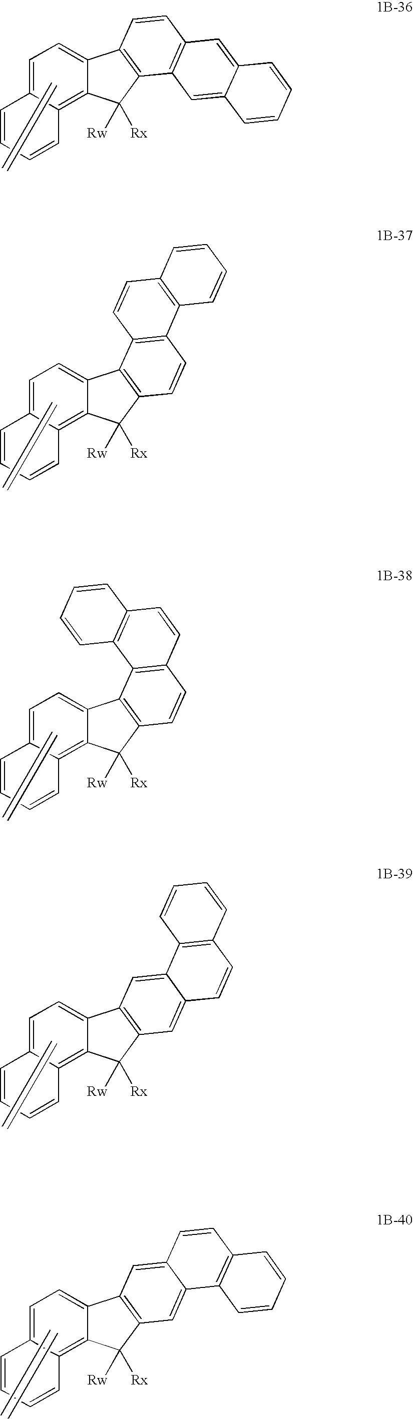

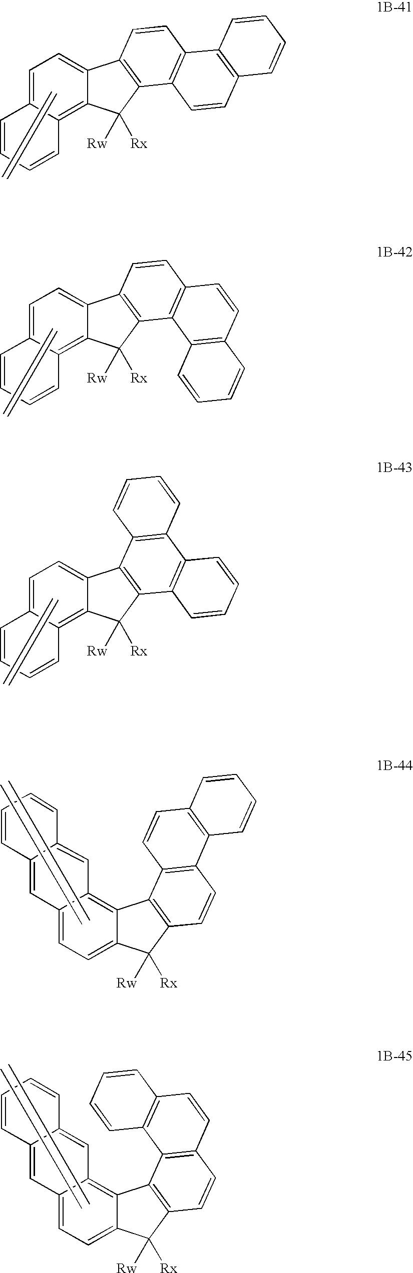

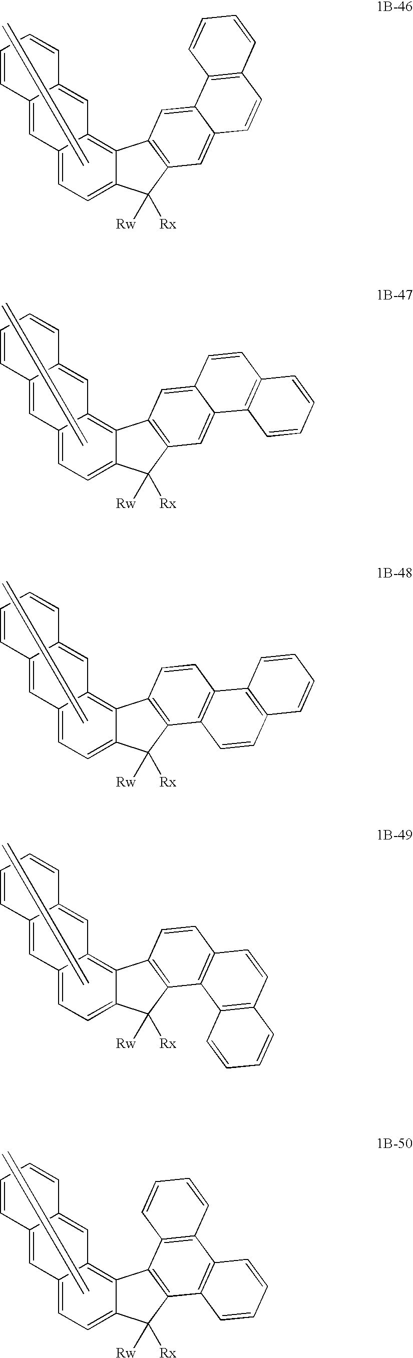

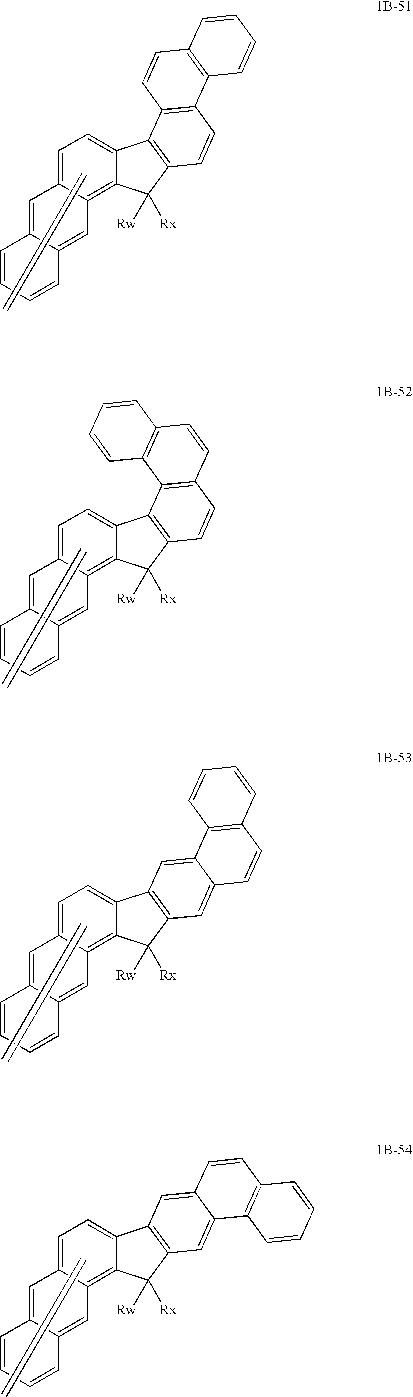

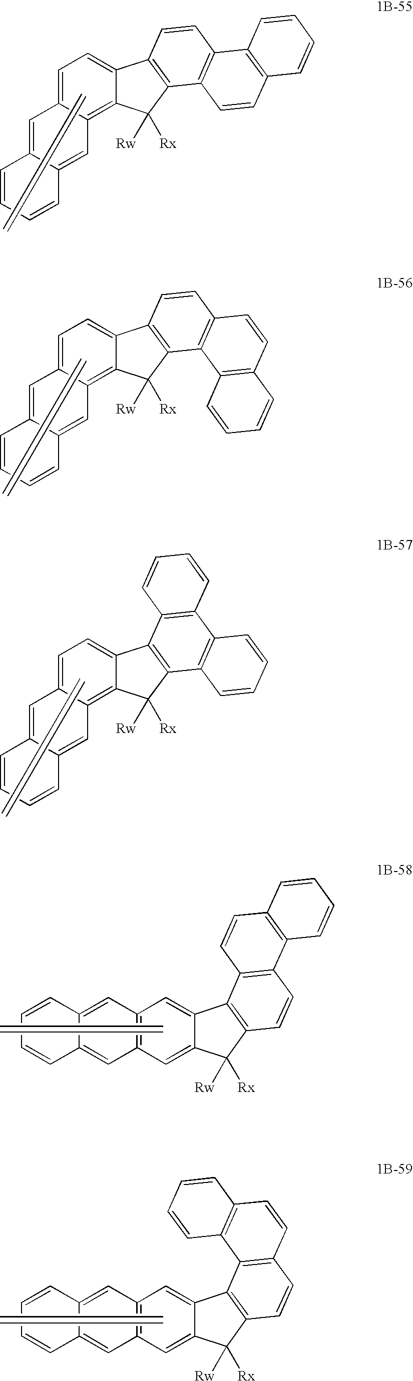

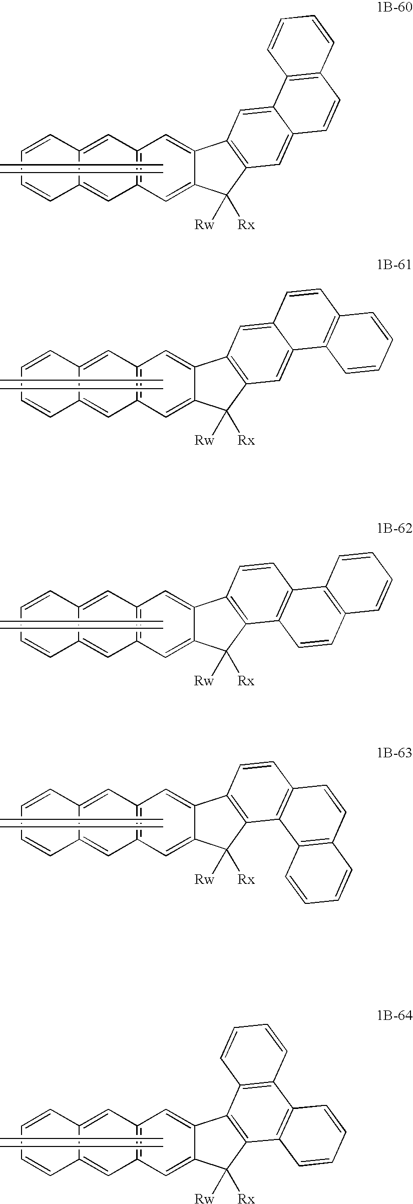

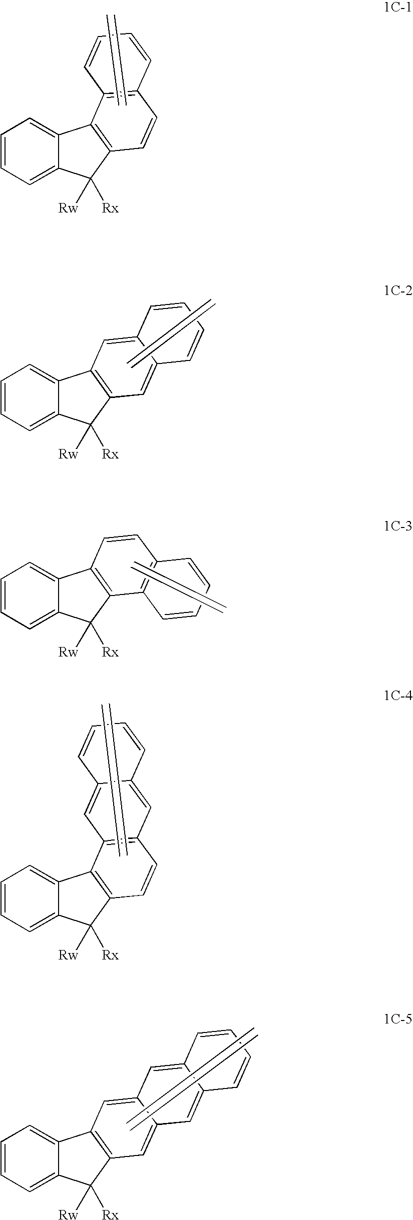

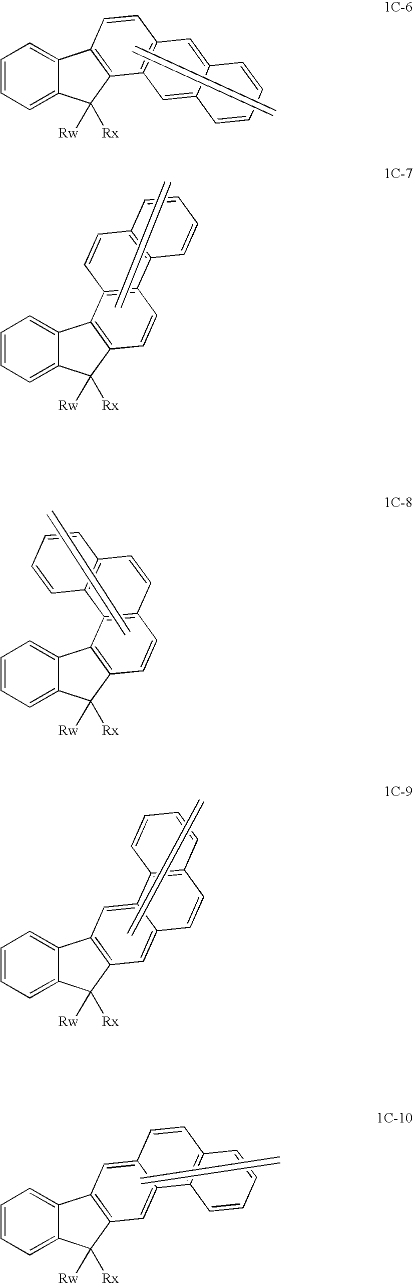

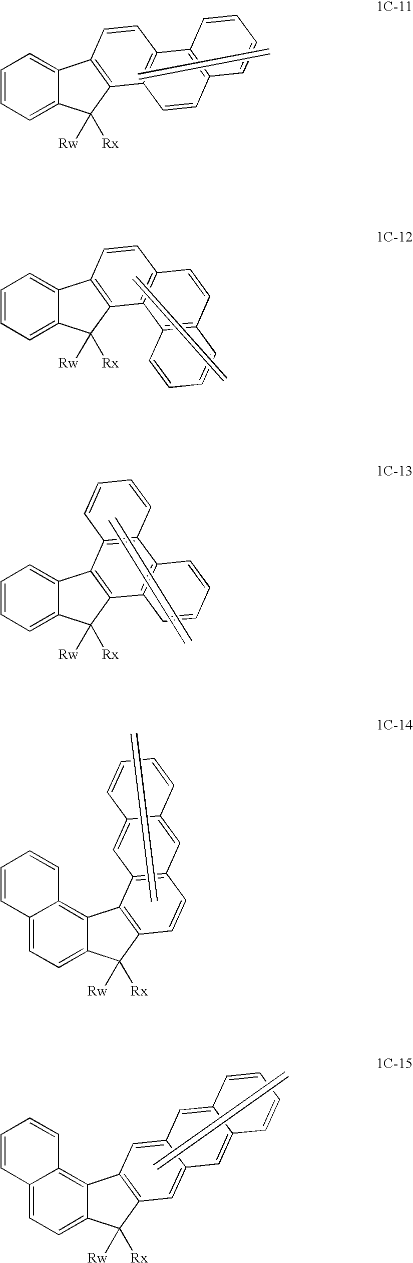

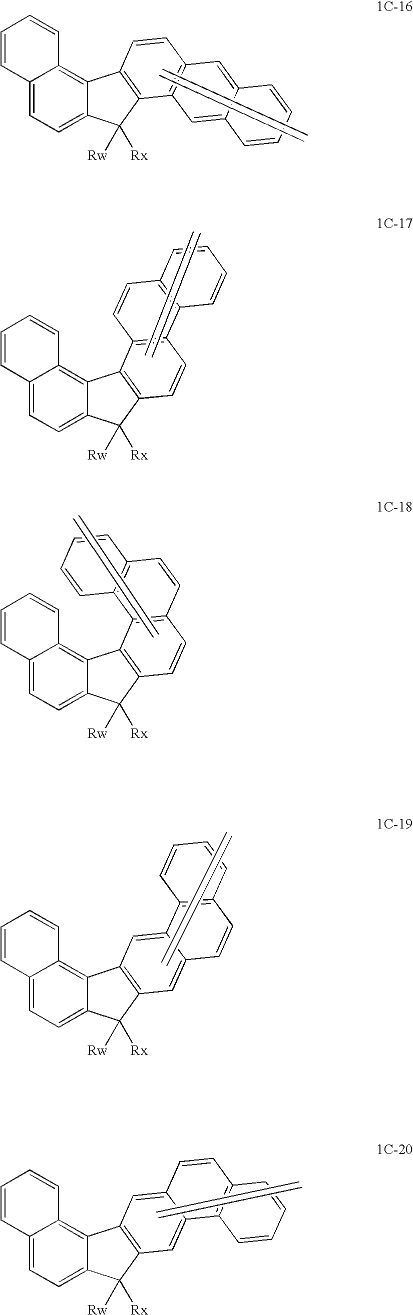

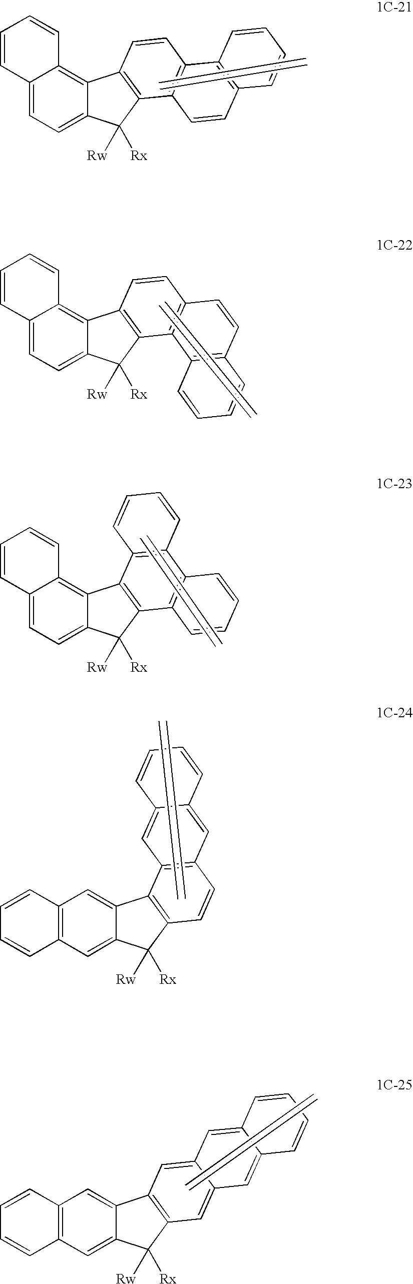

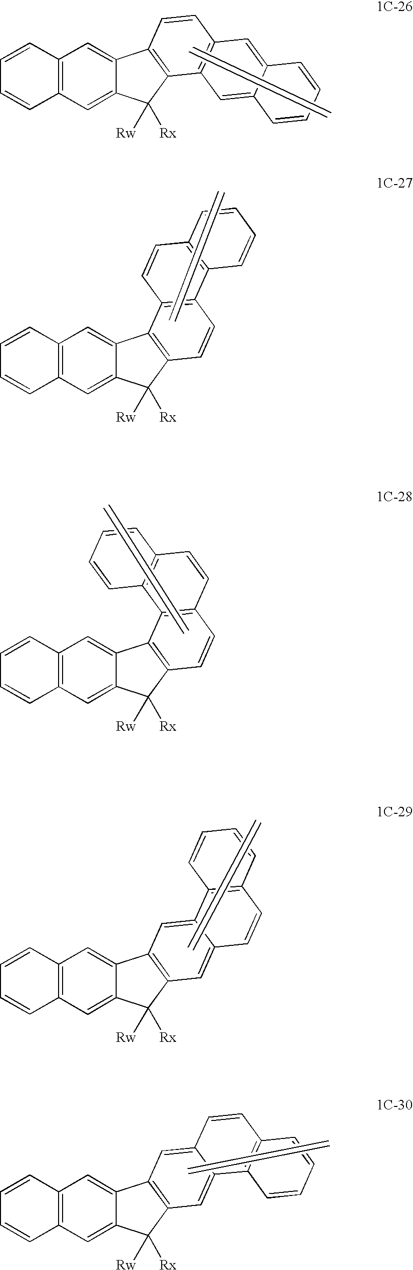

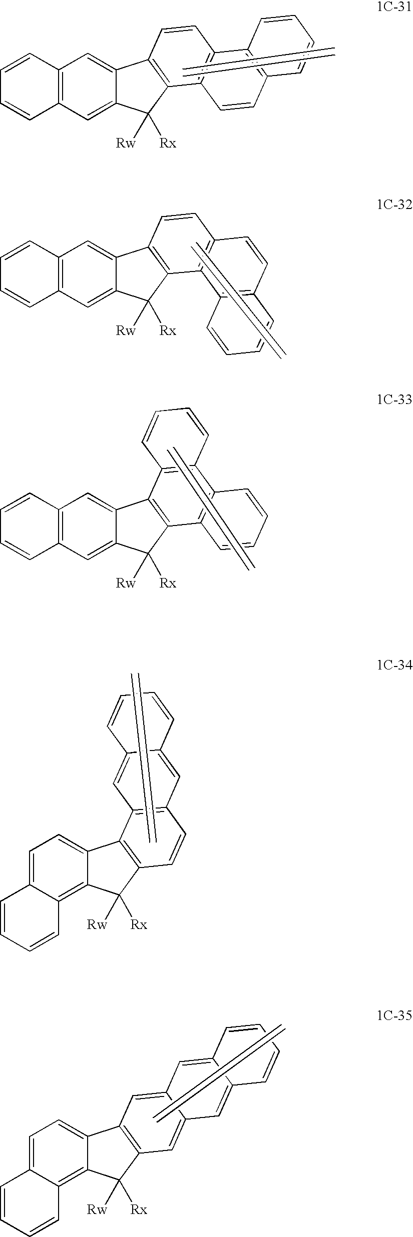

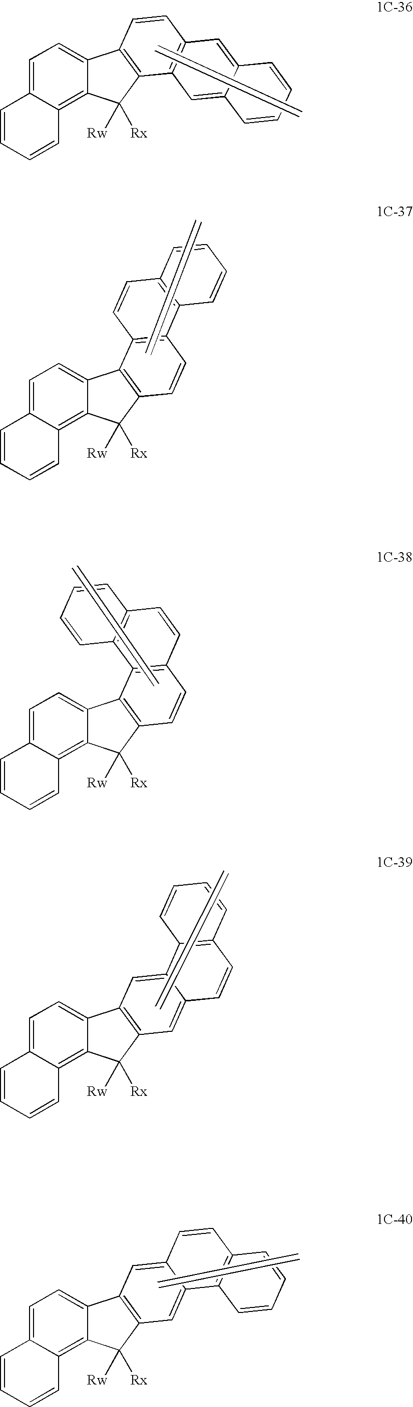

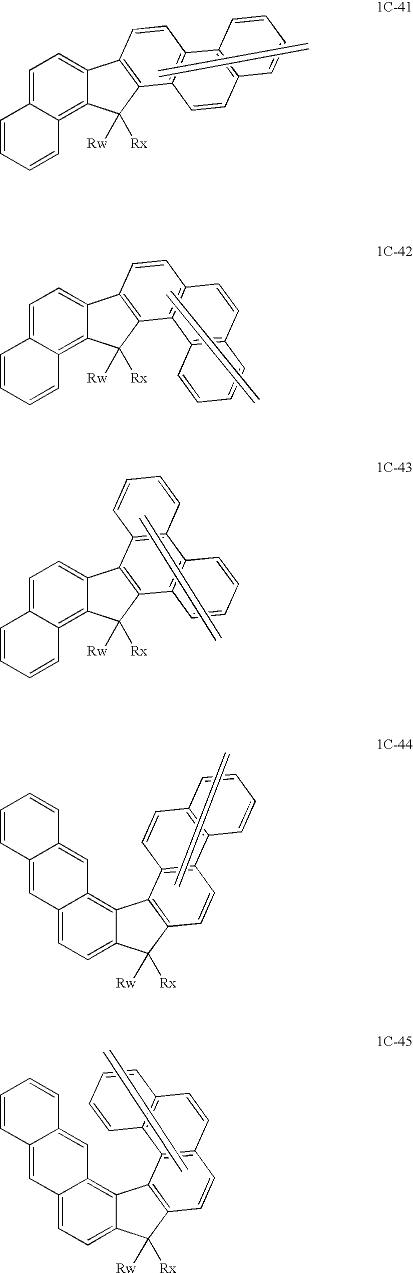

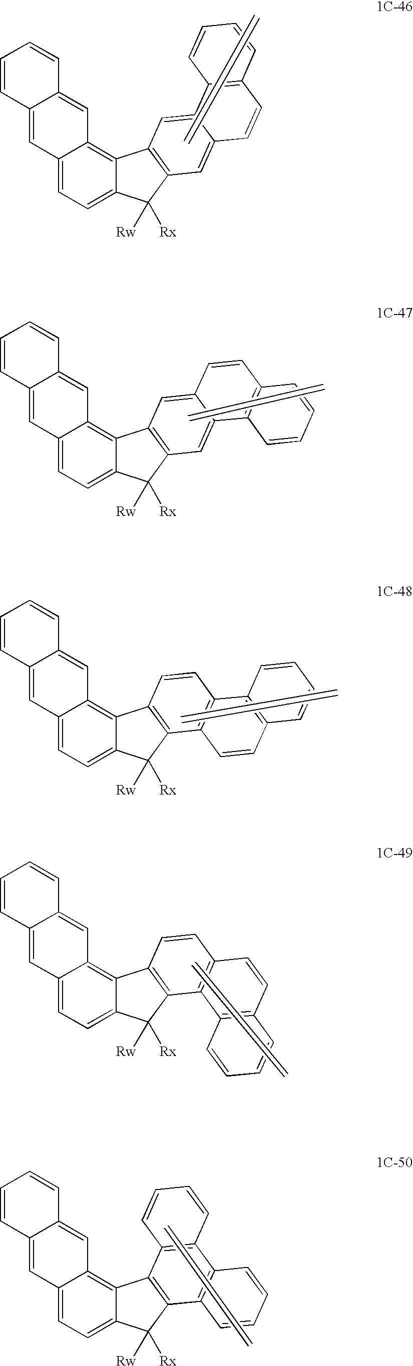

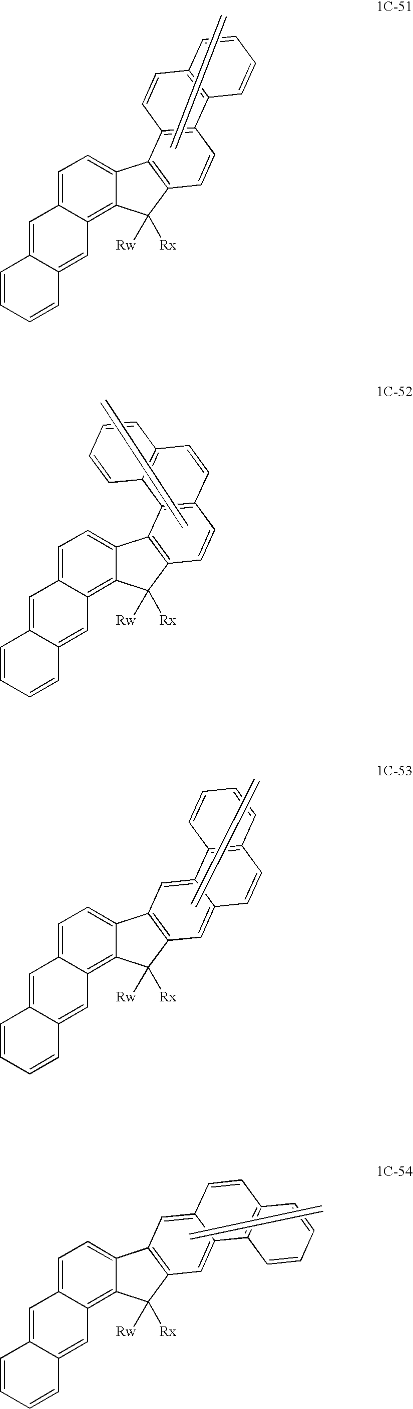

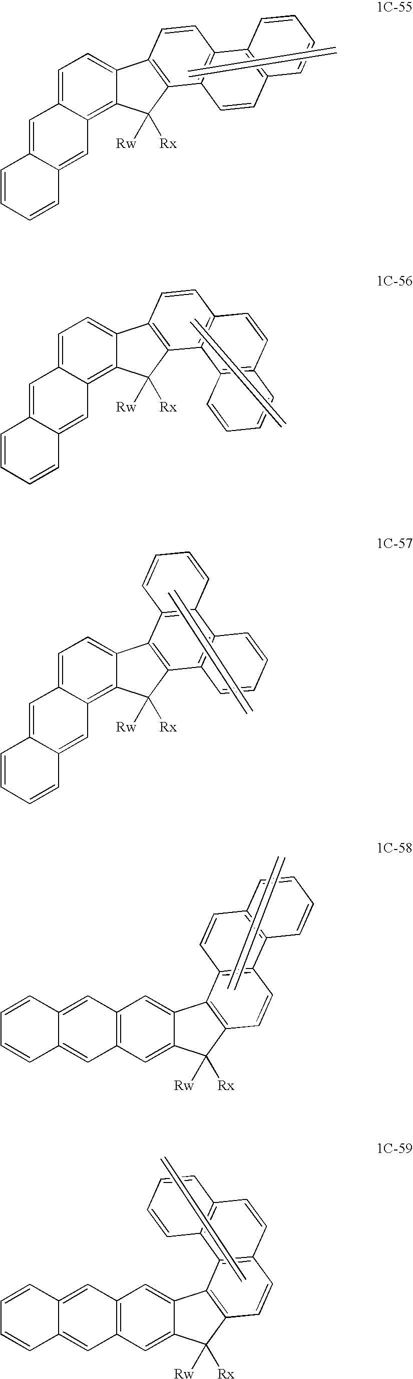

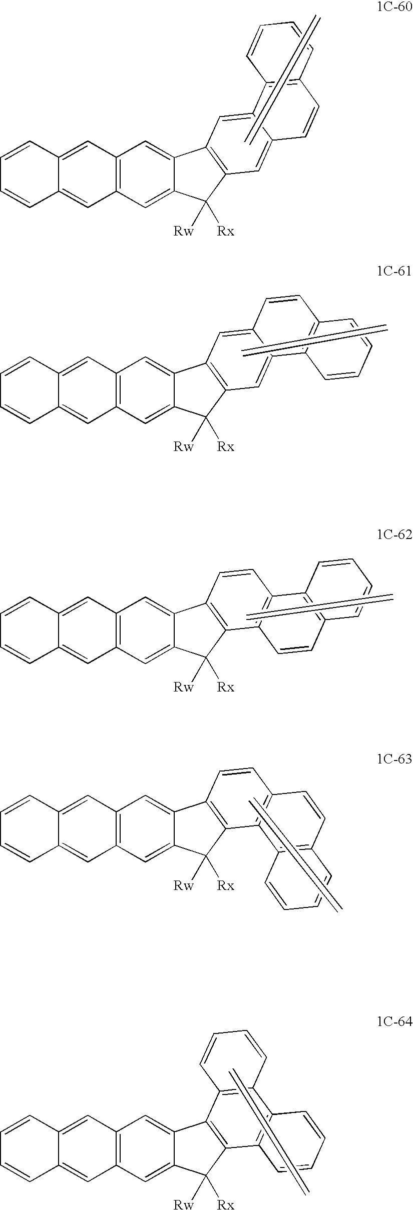

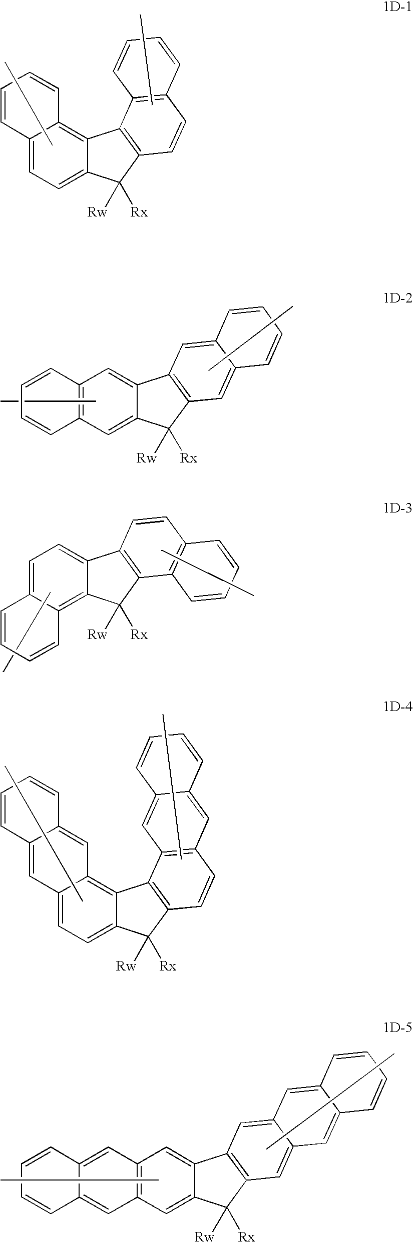

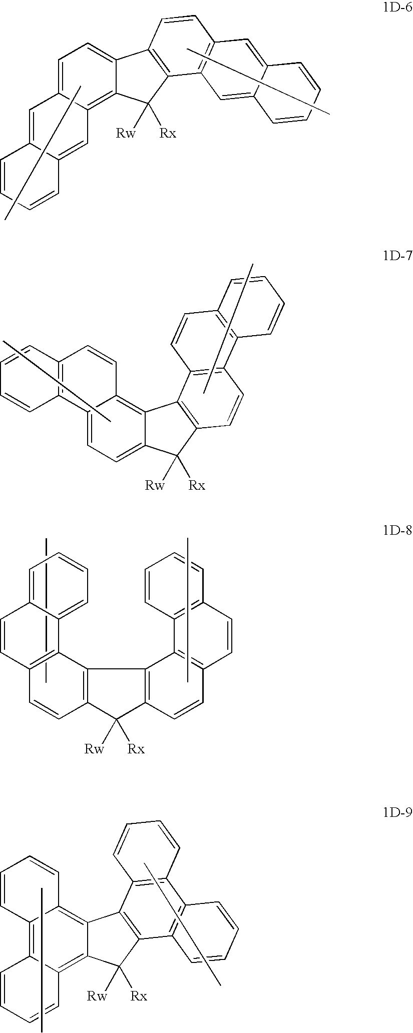

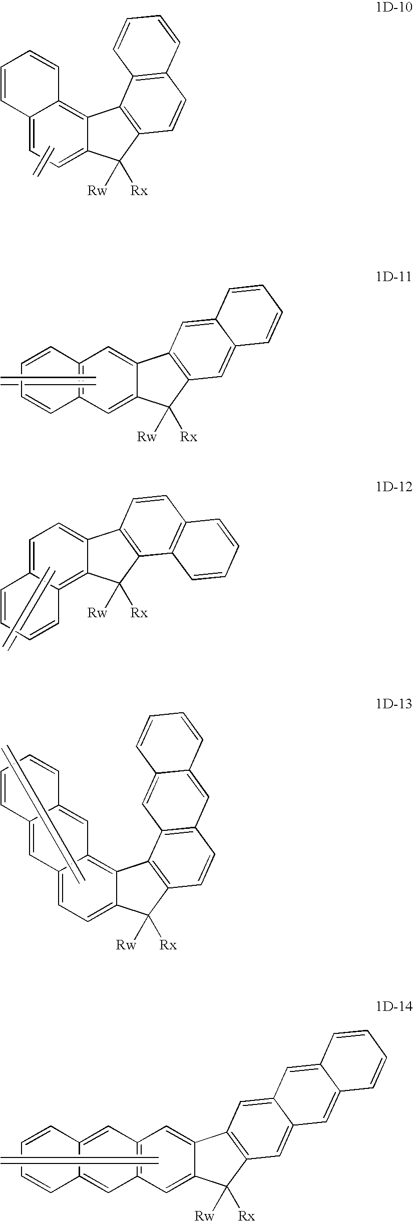

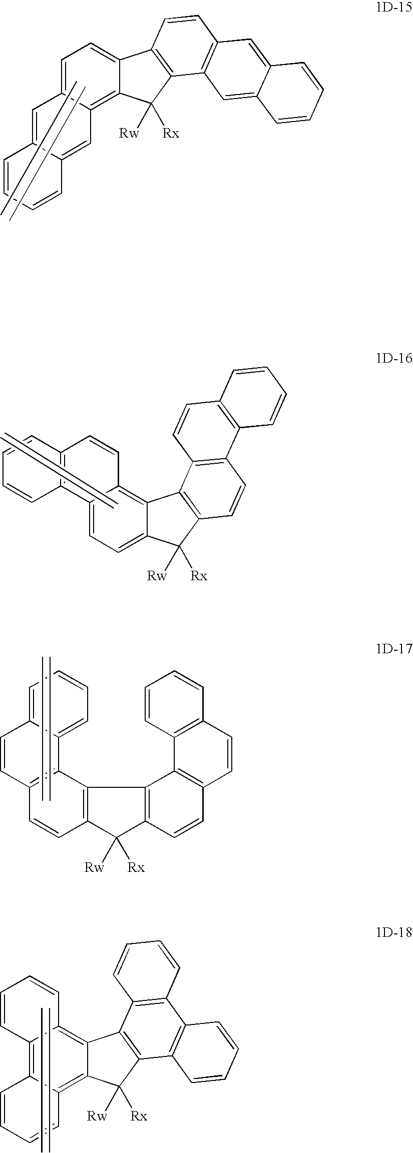

(wherein, Rw and Rx represent the same meanings as described above.).

In the repeating units of the above-described formula (2), it is preferable that one bond is present on the ring A and one bond is present on the ring B, and it is more preferable that each of the ring A and the ring B has a combination of a benzene ring and a naphthalene ring, from the standpoints of heat resistance, fluorescence intensity and the like.

Among others, repeating units of the following formulae (1-1) and (1-2) and repeating units of the following formulae (1-3) and (1-4) are preferable.

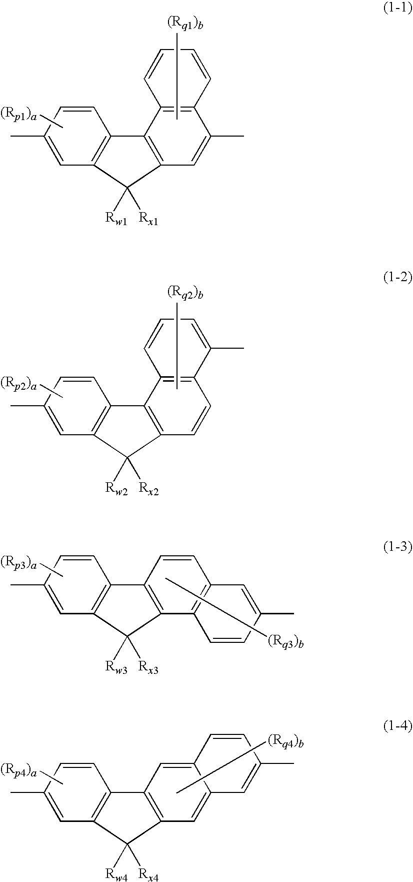

(wherein, Rₚ₁, R_{q1}, Rₚ₂, R_{q2}, Rₚ₃, R_{q3}, Rₚ₄ and R_{q4} represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. a represents an integer of 0 to 3, and b represents an integer of 0 to 5. When there are two or more Rₚ₁s, R_{q1}S, Rₚ₂s, R_{q2}s, Rₚ₃s, R_{q3}s, Rₚ₄s or R_{q4}s, they may be the same or different. R_{w1}, Rₓ₁, R_{w2}, Rₓ₂, R_{w3}, Rₓ₃, R_{w4} and Rₓ₄ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group, and, R_{w1} and Rₓ₁, R_{w2} and Rₓ₂, R_{w3} and Rₓ₃, and R_{w4} and Rₓ₄ each may be mutually connected to form a ring.).

In the above-described formulae (1-1), (1-2), (1-3) and (1-4), Rₚ₁, R_{q1}, Rₚ₂, R_{q2}, Rₚ₃, R_{q3}, Rₚ₄ and R_{q4} represent preferably an alkyl group, alkoxy group, alkylthio group, aryl group, aryloxy group, arylthio group, arylalkyl group, arylalkoxy group, arylalkylthio group, substituted amino group, substituted silyl group, fluorine atom, acyl group, acyloxy group, amide group, acid imide group, monovalent heterocyclic group, carboxyl group, substituted carboxyl group and cyano group, and further preferably an alkyl group, alkoxy group, aryl group, aryloxy group, arylalkyl group, arylalkoxy group and arylalkylthio group, from the standpoints of solubility in organic solvents, device properties, easiness of synthesis and the like.

In the above-described formulae (1-1), (1-2), (1-3) and (1-4), R_{w1}, Rₓ₁, R_{w2}, Rₓ₂, R_{w3}, Rₓ₃, R_{w4} and Rₓ₄ represent preferably an alkyl group, alkoxy group, alkylthio group, aryl group, aryloxy group, arylthio group, arylalkyl group, arylalkoxy group, arylalkylthio group, substituted amino group, substituted silyl group, fluorine atom, acyl group, acyloxy group, amide group, acid imide group, monovalent heterocyclic group, carboxyl group, substituted carboxyl group and cyano group, more preferably an alkyl group, alkoxy group, aryl group, aryloxy group, arylalkyl group, arylalkoxy group and arylalkylthio group, and further preferably an alkyl group, alkoxy group and aryl group, from the standpoints of solubility in organic solvents, device properties, easiness of synthesis and the like.

As the alkyl group, alkoxy group and aryl group, examples are linear, branched or cyclic alkyl groups having a carbon number of usually about from 1 to 20 such as a methyl group, ethyl group, propyl group, i-propyl group, butyl group, i-butyl group, t-butyl group, pentyl group, isoamyl group, hexyl group, cyclohexyl group, heptyl group, cyclohexylmethyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group and the like; alkoxy groups having a carbon number of usually about from 1 to 20 such as a methoxy group, ethoxy group, propyloxy group, i-propyloxy group, butoxy group, i-butoxy group, t-butoxy group, pentyloxy group, hexyloxy group, cyclohexyloxy group, heptyloxy group, cyclohexylmethyloxy group, octyloxy group, 2-ethylhexyloxy group, nonyloxy group, decyloxy group, 3,7-dimethyloctyloxy group, lauryloxy group, trifluoromethoxy group, pentafluoroethoxy group, perfluorobutoxy group, perfluorohexyl group, perfluorooctyl group, methoxymethyloxy group, 2-methoxyethyloxy group and the like; aryl groups having a carbon number of usually about from 6 to 60 such as a phenyl group, C₁ to C₁₂ alkoxyphenyl groups, C₁ to C₁₂ alkylphenyl groups, 1-naphthyl group, 2-naphthyl group, 1-anthracenyl group, 2-anthracenyl group, 9-anthracenyl group, pentafluorophenyl group and the like.

Here, as the C₁ to C₁₂ alkoxy, examples are methoxy, ethoxy, propyloxy, i-propyloxy, butoxy, i-butoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, lauryloxy and the like, and as the C₁ to C₁₂ alkylphenyl group, examples are a methylphenyl group, ethylphenyl group, dimethylphenyl group, propylphenyl group, mesityl group, methylethylphenyl group, i-propylphenyl group, butylphenyl group, i-butylphenyl group, t-butylphenyl group, pentylphenyl group, isoamylphenyl group, hexylphenyl group, heptylphenyl group, octylphenyl group, nonylphenyl group, decylphenyl group, dodecylphenyl group and the like.

Examples of the repeating units of the above-described formulae (1-1), (1-2), (1-3) and (1-4) include the following formula groups (1-1-2), (1-2-2), (1-3-2) and (1-4-2) in which R_{w1} and Rₓ₁, R_{w2} and Rₓ₂, R_{w3} and Rₓ₃, and R_{w4} and Rₓ₄ are mutually connected to form rings, respectively. These structures may further have a substituent.

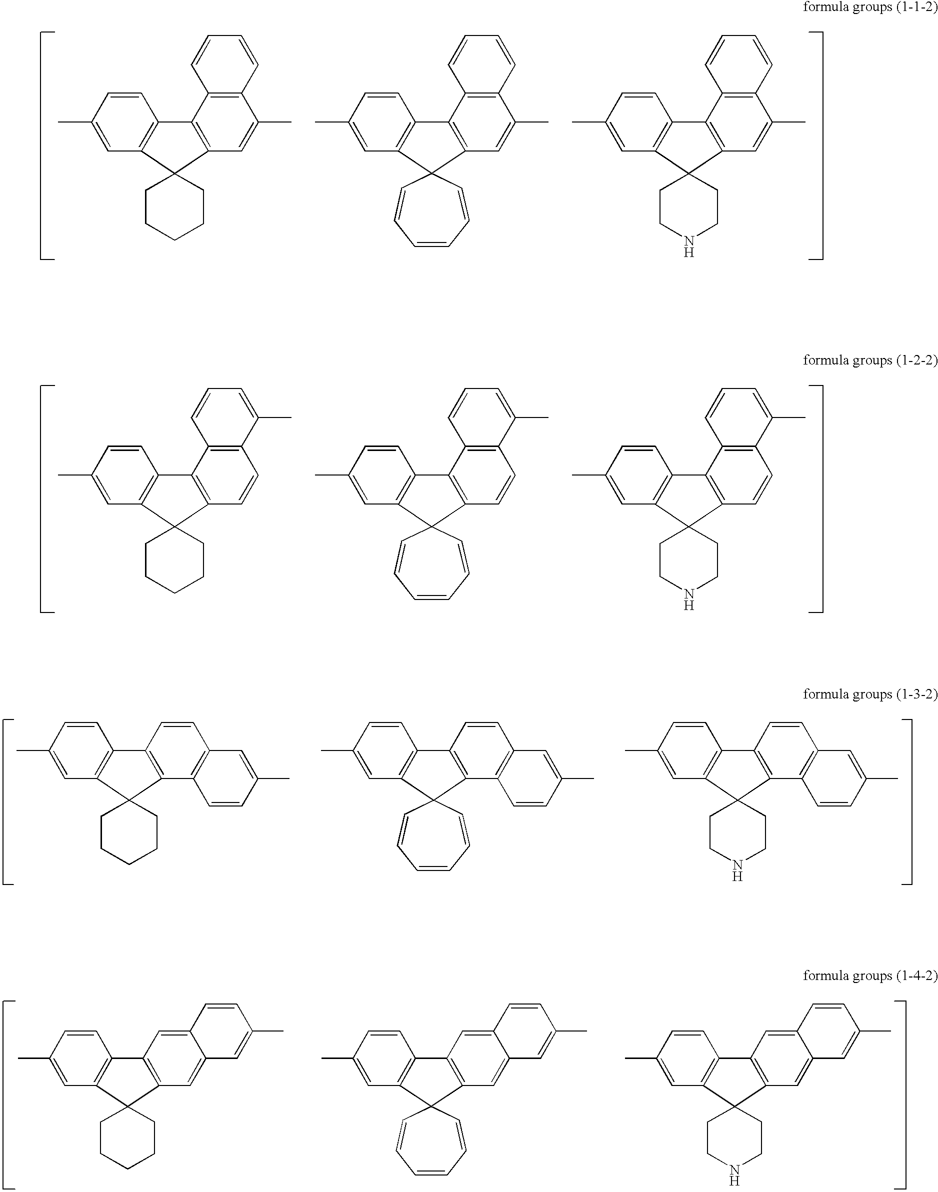

In the above-described formulae (1-1) and (1-2), it is preferable that a and b are 0 from the standpoints of attainment of high molecular weight and improvement in heat resistance.

Among the polymer compounds of the present invention, preferable are those containing a repeating unit of the formula (1-1), (1-3) or (1-4), more preferable is the formula (1-1) from the standpoint of easiness of synthesis of raw material compounds.

From the standpoint of improvement in solubility of a synthesized polymer compound in organic solvents and for balance with heat resistance thereof, R_{w1} and Rₓ₁ are preferably alkyl groups, more preferably those having a carbon number of 3 or more, even preferably those having a carbon number of 7 or more, and further preferably those having a carbon number of 8 or more. Particularly preferable is an n-octyl group, giving a structure of the following formula (1E-1).

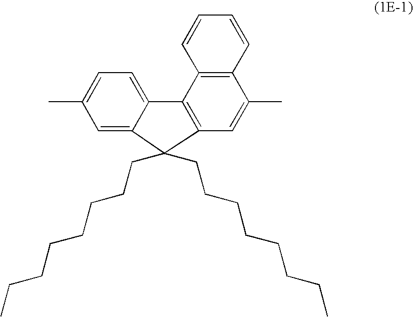

In the formula (3), a ring C and a ring D represent each independently an aromatic ring optionally having a substituent.

The aromatic ring includes aromatic hydrocarbon rings such as a benzene ring, naphthalene ring, anthracene ring, tetracene ring, pentacene ring, pyrene ring, phenanthrene ring and the like; and heteroaromatic rings such as a pyridine ring, bipyridine ring, phenanthroline ring, quinoline ring, isoquinoline ring, thiophene ring, furan ring, pyrrole ring and the like. Here, the aromatic ring C and the aromatic ring D may be the same or different kind of rings. The aromatic ring includes preferably a benzene ring, naphthalene ring, anthracene ring, tetracene ring, pentacene ring, pyrene ring and phenanthrene ring, more preferably a benzene ring, naphthalene ring and anthracene ring, and further preferably a benzene ring.

When the aromatic ring has a substituent, it is preferable from the standpoints of solubility in organic solvents, device properties, easiness of synthesis and the like that the substituent is selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group. The substituent is more preferably selected from an alkyl group, alkoxy group, aryl group, aryloxy group, arylalkyl group, arylalkoxy group, substituted amino group, substituted silyl group, acyl group, substituted carboxyl group and cyano group, even preferably selected from an alkyl group, alkoxy group, aryl group, aryloxy group, arylalkyl group, arylalkoxy group and substituted carboxyl group, further preferably selected from an alkyl group, alkoxy group and aryl group, and particularly preferably selected from an alkyl group and alkoxy group.

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group are the same as the definitions and examples for a substituent when Ar¹ in the above-described formula (1) has a substituent.

In the formula (3), Y represents an oxygen atom, sulfur atom or —O—C(R^{K})₂—.

R^{K} in —O—C(R^{K})₂— represented by Y in the formula (3) represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, nitro group or cyano group. Two R^{K}s may be the same or different.

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group are the same as the definitions and examples for a substituent when Ar¹ in the above-described formula (1) has a substituent. From the standpoints of solubility, easiness of synthesis, device properties and the like, the substituent represented by R^{K} is preferably selected from an alkyl group, alkoxy group, aryl group, aryloxy group, arylalkyl group, arylalkoxy group, substituted amino group, substituted silyl group, acyl group, substituted carboxyl group and cyano group, more preferably selected from an alkyl group, alkoxy group, aryl group, aryloxy group, arylalkyl group, arylalkoxy group and substituted carboxyl group, even preferably selected from an alkyl group, alkoxy group and aryl group, and further preferable are an alkyl group and alkoxy group, particularly preferable is an alkyl group.

The repeating units of the formula (3) include, for example, the following repeating units (G-1 to G-26, H-1 to H-26, K-1 to K-26), and these repeating units having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like.

In the following formulae, bonds in aromatic rings can take any position.

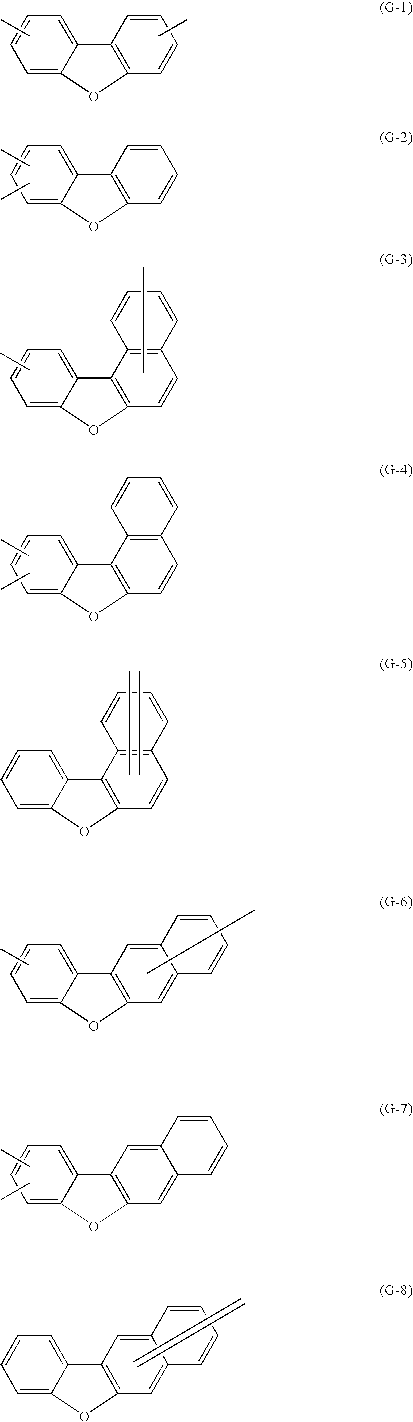

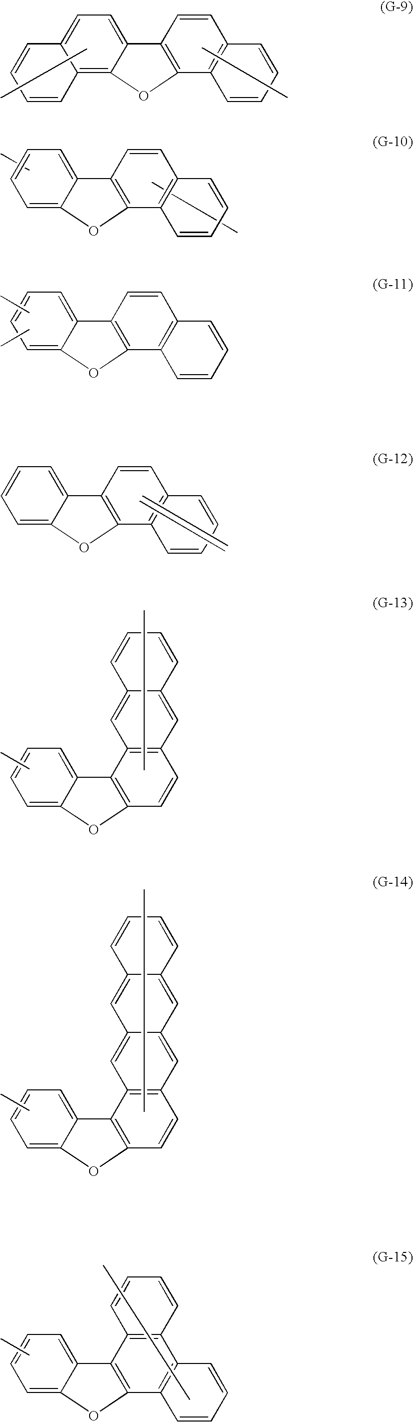

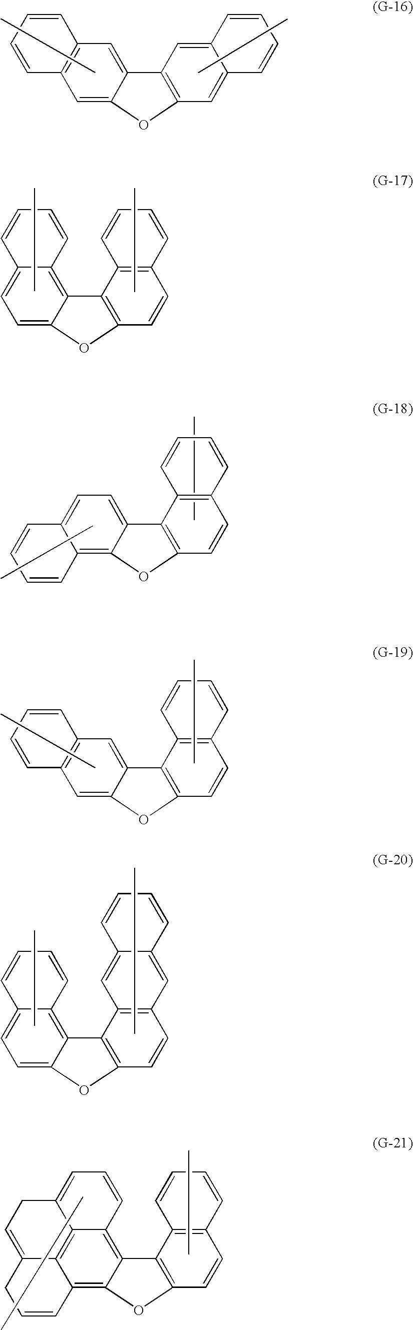

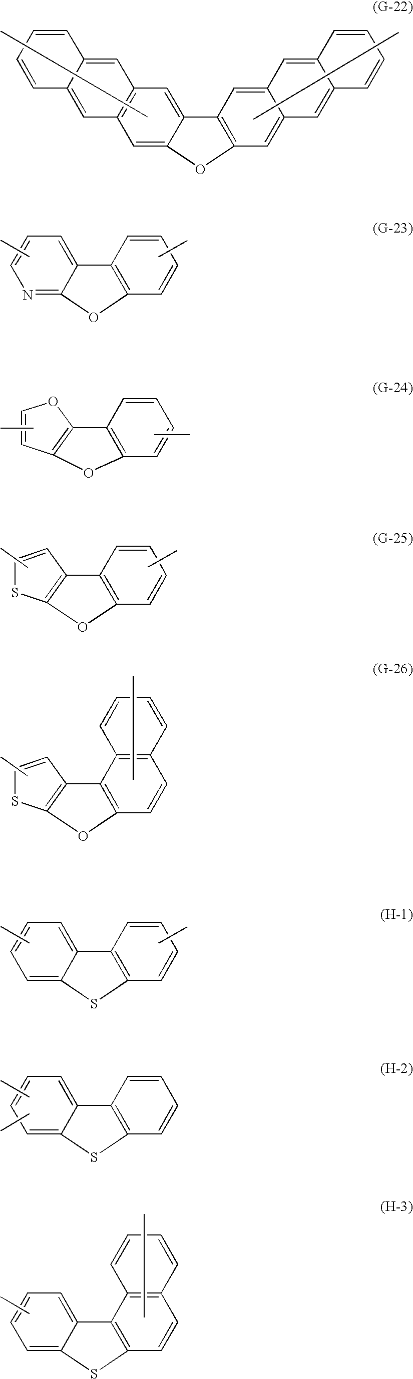

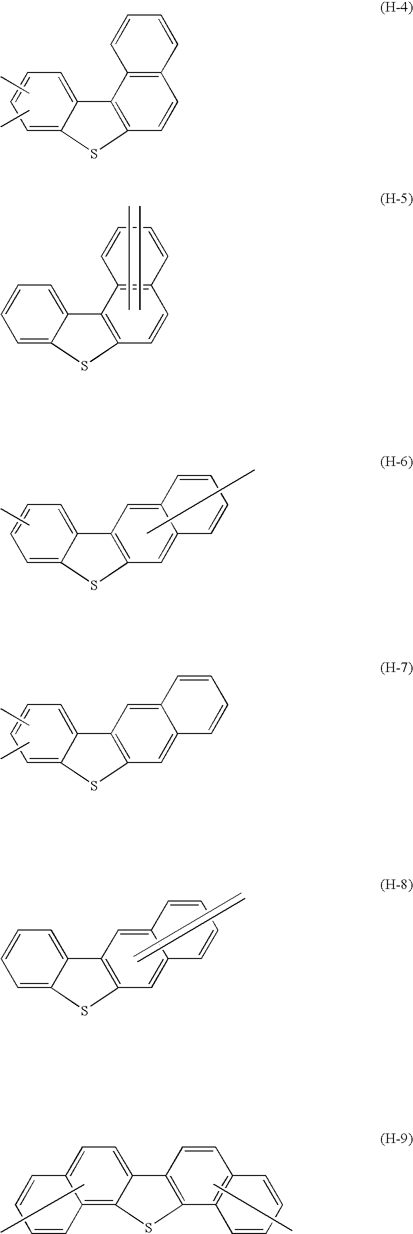

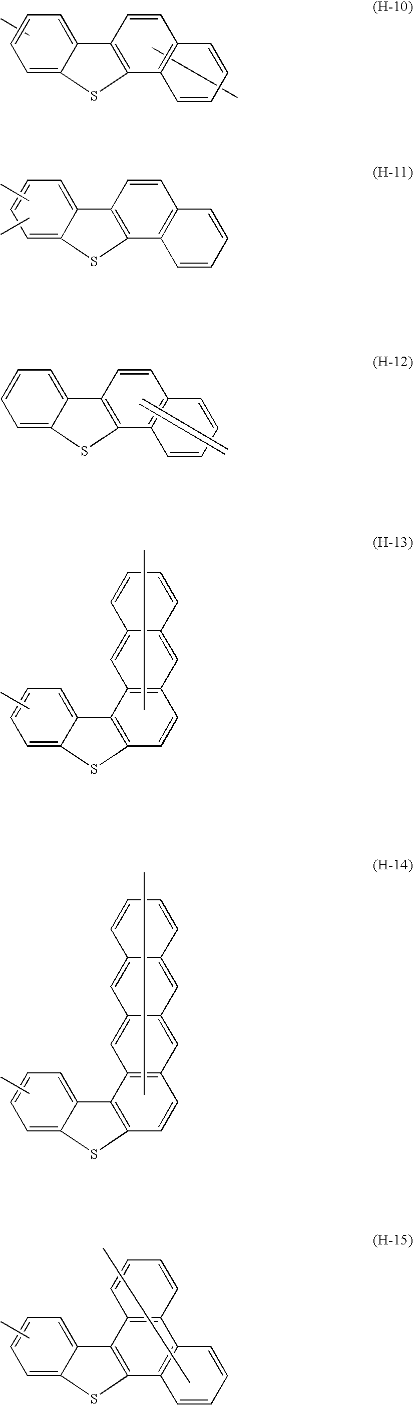

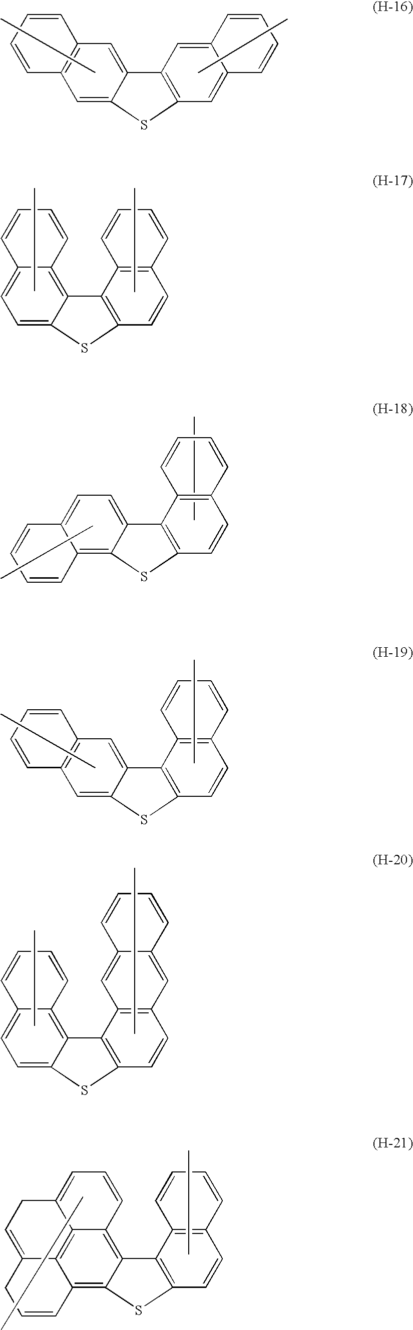

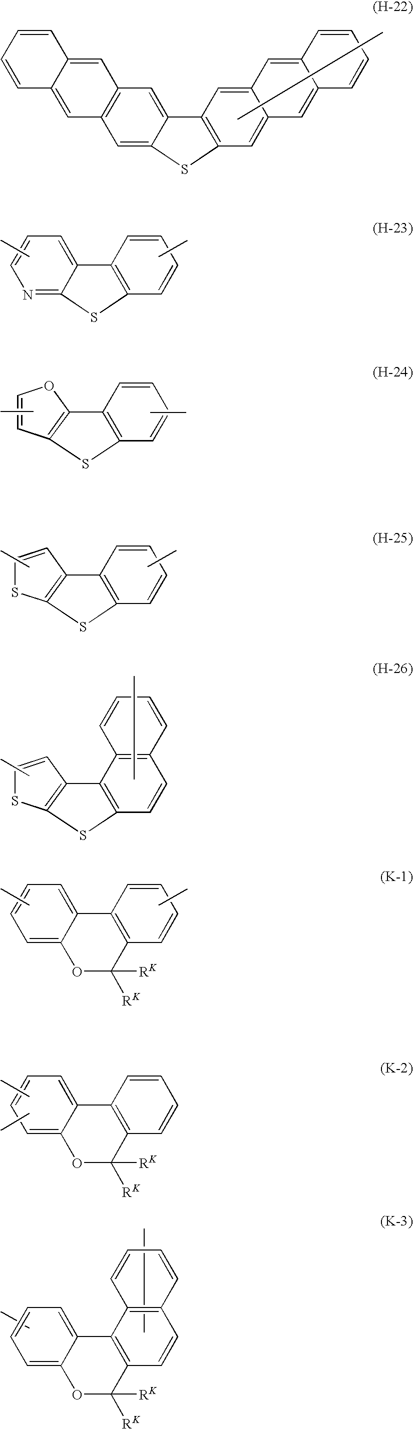

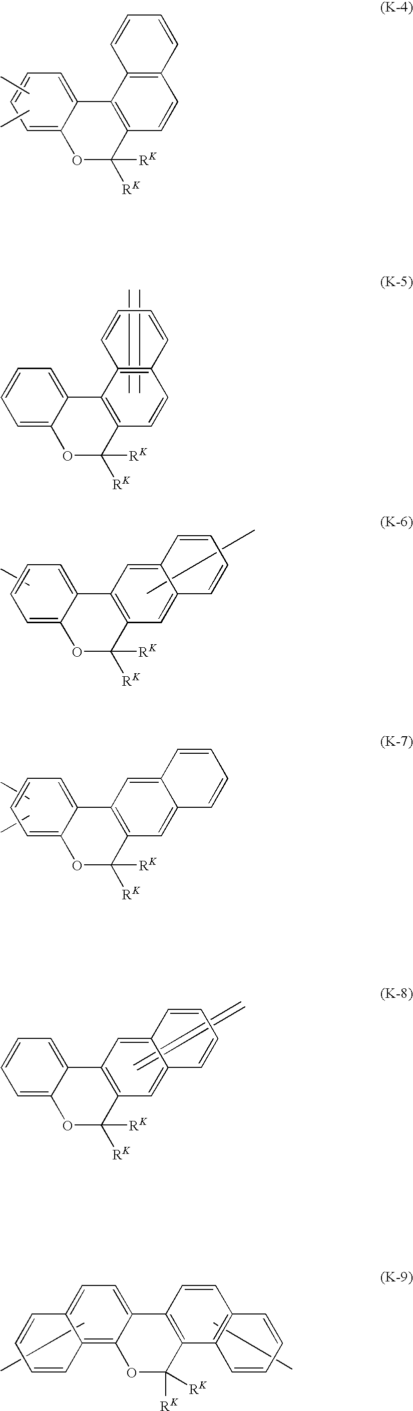

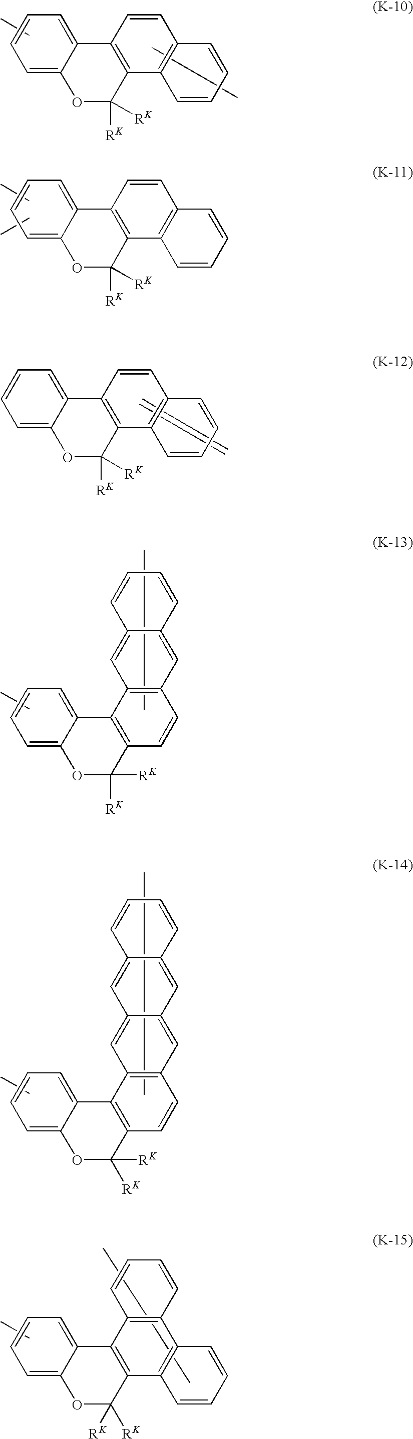

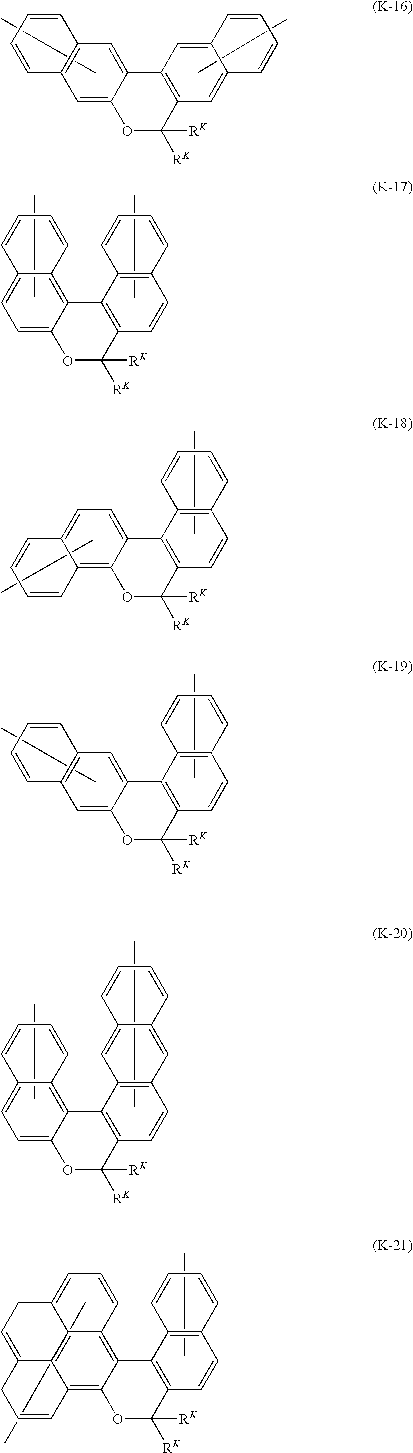

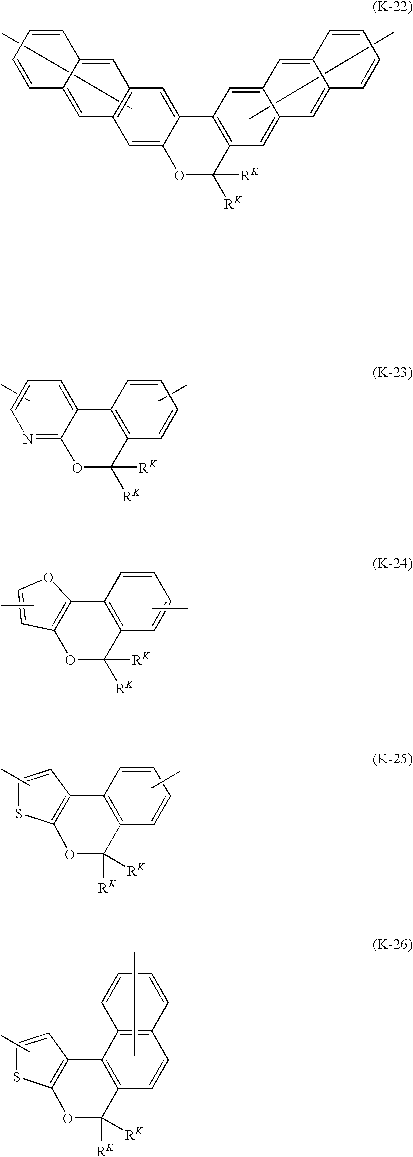

(wherein, R^{K} represents the same meaning as for R^{K} in the formula (3)).

The repeating units of the formula (3) include, preferably G-1 to G-22, H-1 to H-22, and K-1 to K-22, and these G-1 to G-22, H-1 to H-22, and K-1 to K-22 each having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, more preferably G-1 to G-12, H-1 to H-12, and K-1 to K-12, and these G-1 to G-12, H-1 to H-12, and K-1 to K-12 each having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, even preferably G-1 to G-2, H-1 to H-2, and K-1 to K-2, and these G-1 to G-2, H-1 to H-2, and K-1 to K-2 each having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, further preferably G-1, H-1 and K-1, and these G-1, H-1 and K-1 having a substituent such as an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group and the like, and particularly preferably divalent groups of the following formula (G-27).

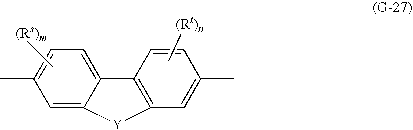

(wherein, Y represents the same meaning as for Y in the formula (3), and R^{s} and R^{t} represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, nitro group or cyano group. When there are two or more R^{s}s or R^{t}s, they may be the same or different. m and n represent each independently an integer of 0 to 3.).

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group represented by R^{s} and R^{t} in the formula (G-27) are the same as the definitions and examples for a substituent when Ar¹ in the above-described formula (1) has a substituent. It is preferable from the standpoints of solubility, easiness of synthesis, device properties and the like that the substituent represented by R^{s} and R^{t} in the formula (G-27) is selected from an alkyl group, alkoxy group, aryl group, aryloxy group, arylalkyl group, arylalkoxy group, substituted amino group, substituted silyl group, acyl group, substituted carboxyl group and cyano group, more preferably selected from an alkyl group, alkoxy group, aryl group, aryloxy group, arylalkyl group, arylalkoxy group and substituted carboxyl group, even preferably selected from an alkyl group, alkoxy group and aryl group, and further preferable are an alkyl group and alkoxy group, particularly preferable is an alkyl group.

m and n in the formula (G-27) represent each independently an integer of 0 to 3, preferably an integer of 1 to 2, more preferably 1.

The proportion of the sum of repeating units of the formula (1), repeating units of the formula (2) and repeating units of the formula (3) based on all repeating units contained in a polymer compound of the present invention is usually from 1 to 100 mol %, preferably 10 to 100 mol %, more preferably 30 to 100 mol %, even preferably 40 to 100 mol %, further preferably 40 to 80 mol %, further even preferably 40 to 70 mol %, and particularly preferably 40 to 60 mol %.

From the standpoints of fluorescence intensity, device properties and the like, the molar ratio of repeating units of the formula (1) to the sum of repeating units of the formula (2) and repeating units of the formula (3) is preferably 0.01:99.99 to 70.00:30.00, more preferably 0.10:99.90 to 50.00:50.00.

The polymer compound of the present invention preferably contains at least one repeating unit other than repeating units of the above-described formulae (1), (2) and (3), and preferable as the repeating unit other than repeating units of the above-described formulae (1), (2) and (3) are repeating units of the following formula (4) and/or formula (5).

—Ar³— (4)

(wherein, Ar³ represents a divalent aromatic group optionally having a substituent.)

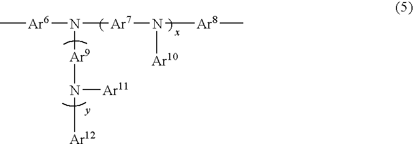

(in the formula (5), Ar⁶, Ar⁷, Ar⁸ and Ar⁹ represent each independently a 1,4-phenylene group or 4,4′-biphenylene group. Ar¹⁰, Ar¹¹ and Ar¹² represent each independently an aryl group. Ar⁶, Ar⁷, Ar⁸, Ar⁹, Ar¹⁰, Ar¹¹ and Ar¹² optionally have a substituent. x and y represent each independently 0 or a positive integer.).

In the formula (4), Ar³ represents a divalent aromatic group optionally having a substituent.

Here, the divalent aromatic group means an atomic group obtained by removing two hydrogen atoms from an aromatic hydrocarbon compound or an aromatic heterocyclic compound. The divalent aromatic group has a carbon number of usually about from 5 to 60, preferably 5 to 48, more preferably 6 to 30, further preferably 6 to 22, and particularly preferably 6 to 14. This carbon number does not include the carbon number of substituents.

Examples of the divalent aromatic ring include a 1,4-phenylene group, 1,3-phenylene group, 1,2-phenylene group, 1,4-naphthylene group, 1,5-naphthylene group, 2,6-naphthylene group, 1,4-anthracenediyl group, 1,5-anthracenediyl group, 2,6-anthracenediyl group, 9,10-anthracenediyl group, 2,7-phenanthrylene group, 1,7-naphthacenylene group, 2,8-naphthacenylene group, 2,7-fluorenediyl group, 2,7-pyrenediyl group, 4,10-pyrenediyl group, 2,6-pyridyl group, 2,5-thiophenyl group, 2,5-furanyl group, 2,6-quinolinediyl group, 1,5-isoquinolinedlyl group, 5,8-quinoxalinediyl group, 4,7-benzo[1,2,5]thiadiazolediyl group, 4,7-benzothiazolediyl group, 2,7-carbazolediyl group, 3,7-phenoxazinediyl group and the like, preferably a 1,4-phenylene group, 1,4-naphthylene group, 1,5-naphthylene group, 2,6-naphthylene group, 1,4-anthracenediyl group, 1,5-anthracenediyl group, 2,6-anthracenediyl group, 9,10-anthracenediyl group, 2,7-fluorenediyl group, 5,8-quinoxalinediyl group, 4,7-benzo[1,2,5]thiadiazolediyl group, 4,7-benzothiazolediyl group, 2,7-carbazolediyl group and 3,7-phenoxazinediyl group, and more preferably a 2,7-fluorenediyl group and 3,7-phenoxazinediyl group.

When the divalent aromatic group have a substituent, it is preferable from the standpoints of solubility in organic solvents, device properties, easiness of synthesis and the like that the substituent is selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group. The substituent is more preferably selected from an alkyl group, alkoxy group, aryl group, aryloxy group, arylalkyl group, arylalkoxy group, substituted amino group, substituted silyl group, acyl group, substituted carboxyl group and cyano group, even preferably selected from an alkyl group, alkoxy group, aryl group, aryloxy group, arylalkyl group, arylalkoxy group and substituted carboxyl group, and further preferably selected from an alkyl group, alkoxy group and aryl group.

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group are the same as the definitions and examples for a substituent when Ar¹ in the above-described formula (1) has a substituent.

Ar¹⁰, Ar¹¹ and Ar¹² in the formula (5) represent each independently an aryl group, and here, the aryl group is an atomic group obtained by removing one hydrogen atom from an aromatic hydrocarbon, and includes those having an independent benzene ring or condensed ring. The aryl group has a carbon number of usually about from 6 to 60, preferably 6 to 48, more preferably 6 to 30, even preferably 6 to 18, further preferably 6 to 10, and particularly preferably 6. This carbon number does not include the carbon number of substituents. Examples of the aryl group include a phenyl group, 1-naphthyl group, 2-naphthyl group, 1-anthracenyl group, 2-anthracenyl group, 9-anthracenyl group, 1-phenanthryl group, 9-phenanthryl group, 1-naphthacenyl group, 2-naphthacenyl group and the like, preferably a phenyl group, 1-naphthyl group, 2-naphthyl group, 1-anthracenyl group, 2-anthracenyl group and 9-anthracenyl group, more preferably a phenyl group, 1-naphthyl group and 2-naphthyl group, and particularly preferably a phenyl group.

When Ar⁶, Ar⁷, Ar⁸, Ar⁹, Ar¹⁰, Ar¹¹ and Ar¹² in the formula (5) have a substituent, it is preferable from the standpoints of solubility in organic solvents, device properties, easiness of synthesis and the like that the substituent is selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group. The substituent is more preferably selected from an alkyl group, alkoxy group, aryl group, aryloxy group, arylalkyl group, arylalkoxy group, substituted amino group, substituted silyl group, acyl group, substituted carboxyl group and cyano group, even preferably selected from an alkyl group, alkoxy group, aryl group, aryloxy group, arylalkyl group, arylalkoxy group and substituted carboxyl group, further preferably selected from an alkyl group, alkoxy group and aryl group, and particularly preferable is an alkyl group.

The definitions and examples of the alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group and substituted carboxyl group are the same as the definitions and examples for a substituent when Ar¹ in the above-described formula (1) has a substituent.

Examples of the repeating unit of the formula (5) include the following formulae (5-1) to (5-4). Here, Rs are selected each independently from a hydrogen atom, or an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group.

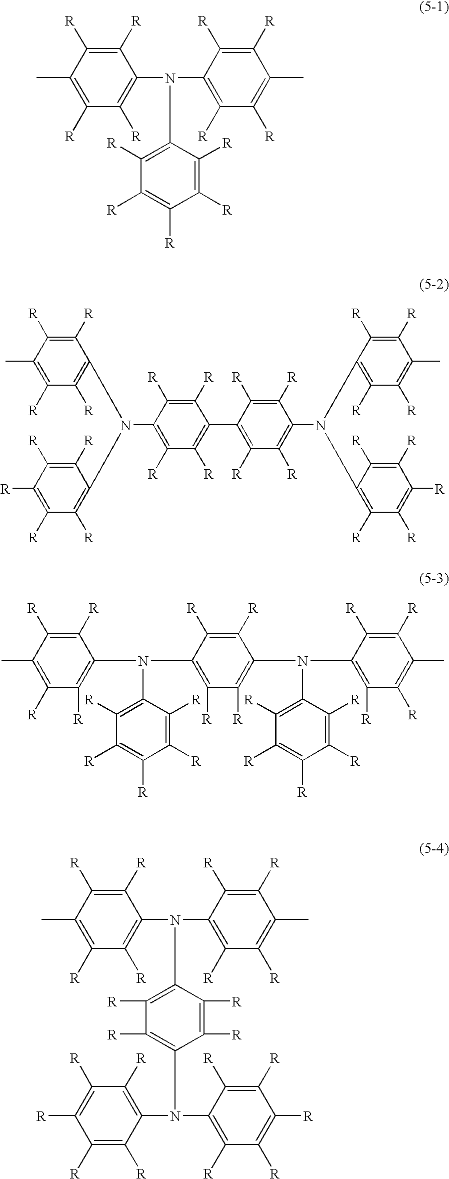

The polymer compound of the present invention more preferably contains at least one repeating unit of the formula (1), at least one repeating unit of the formula (2) and at least one repeating unit of the formula (4), and further preferably contains one repeating unit of the formula (1), one repeating unit of the formula (2) and two or more repeating units of the formula (4), from the standpoint of device properties. Further preferable are combinations of one repeating unit of the formula (S-52), a repeating unit of the formula (I-1), one 2,7-fluorenediyl group having a substituent, and one 3,7-phenoxazinediyl group having a substituent.

The polystyrene-reduced number average molecular weight (Mn) according to size exclusion chromatography (hereinafter, referred to as SEC) of a polymer compound of the present invention is usually about from 10³ to 10⁸, preferably 10⁴ to 10⁶. The polystyrene-reduced weight average molecular weight (Mw) is usually about from 10³ to 10⁸, and from the standpoint of film formability and from the standpoint of efficiency when made into a device, preferably 5×10⁴ to 5×10⁶, more preferably 10⁵ to 10⁶.

An end group of a polymer compound of the present invention is preferably protected by a stable group since when a polymerization active group remains intact; there is a possibility of decrease in light emission property and life when made into a device. A structure containing a conjugation bond continuous with a conjugation structure of the main chain is preferable, and for example, a structure bonding to an aryl group or heterocyclic group via a carbon-carbon bond is illustrated. Examples include substituents described in chemical formula 10 in JP-A No. 9-45478, and the like.

The polymer compound of the present invention, when used as a light emission material, charge transporting material and the like, may be used in admixture with other polymer compound.

Next, preferable methods for producing a polymer compound of the present invention will be illustrated.

The polymer compound of the present invention can be produced, for example, by using a compound of the following formula (a) and a compound of the following formula (b), further, if necessary, a compound of the following formula (c), as raw materials, and condensation-polymerizing them.

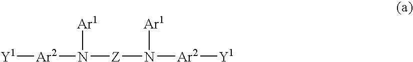

(in the formula (a), Ar¹, Ar² and Z represent the same meanings as for Ar¹, Ar² and Z, respectively, in the formula (1). Y¹s represent each independently a halogen atom, sulfonate group of the formula (a-1), methoxy group, borate group, boric acid group, group of the formula (a-2), group of the formula (a-3) or group of the formula (a-4)).

Y¹—Ar¹³—Y¹ (b)

(in the formula (b), Ar¹³ represents a divalent group of the formula (2) or the formula (3). Y¹ represents the same meaning as for Y¹ in the formula (a)).

Y¹—Ar¹⁴—Y¹ (c)

(in the formula (c), Ar¹⁴ represents a divalent group of the formula (4) or the formula (5). Y¹ represents the same meaning as for Y¹ in the formula (a)).

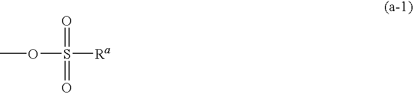

(in the formula (a-1), R^{a} represents an alkyl group or aryl group optionally having a substituent.).

—MgX_{A} (a-2)

(in the formula (a-2), X_{A} represents a halogen atom. As the halogen atom, a chlorine atom, bromine atom and iodine atom are mentioned.).

—ZnX_{A} (a-3)

(in the formula (a-3), X_{A} represents a halogen atom. As the halogen atom, a chlorine atom, bromine atom and iodine atom are mentioned.).

—SnR^{a} (a-3)

(in the formula (a-3), R^{a} represents the same meaning as for R^{a} in the (a-1).).

Y¹s in the formulae (a), (b) and (c) represent each independently a halogen atom, sulfonate group of the formula (a-1), methoxy group, borate group, boric acid group (namely, group of —B(OH)₂), group of the formula (a-2), group of the formula (a-3) or group of the formula (a-4).

The halogen atom represented by Y¹ includes a chlorine atom, bromine atom and iodine atom.

Examples of the borate group represented by Y¹ include groups of the following formulae.

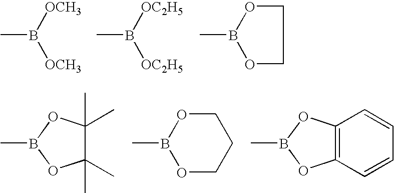

The definitions and examples of the alkyl group or aryl group represented by R^{a} in the formula (a-1) are the same as the definitions and examples, respectively, for a case in which Ar¹ in the formula (1) has a substituent. Examples of the sulfonate group represented by the formula (a-1) include a methane sulfonate group, trifluoromethane sulfonate group, phenyl sulfonate group, 4-methylphenyl sulfonate group and the like.

As the compounds of the formulae (a), (b) and (c), those previously synthesized and isolated may be used, alternatively these compounds may be prepared in a reaction system and used without any other operation.

Y¹ in the formulae (a), (b) and (c) preferably represents a halogen atom, borate group or boric acid group from the standpoints of easiness of synthesis, easiness of handling, toxicity and the like.

As the condensation polymerization method, methods are mentioned in which monomers of the formulae (a), (b) and (c) are reacted, if necessary, using a suitable catalyst or a suitable base.

The catalyst for condensation polymerization includes catalysts containing, for example, a transition metal complex such as palladium complexes such as palladium[tetrakis(triphenylphosphine)], [tris(dibenzylideneacetone)]dipalladium, palladium acetate and the like, nickel complexes such as nickel[tetrakis(triphenylphosphine)], [1,3-bis(diphenylphosphino)propane]dichloronickel, [bis(1,4-cyclooctadiene)]nickel and the like, and if necessary, further a ligand such as triphenylphosphine, tri(t-butylphosphine), tricyclohexylphosphine, diphenylphosphinopropane, bipyridyl and the like.

As the catalyst, those previously synthesized can be used, or those prepared in a reaction system can be used. In the present invention, the catalysts can be used singly or in admixture of two or more of them.

Though the catalyst can be used in any amount, the amount of transition metal compounds is, in general, preferably from 0.001 to 300 mol %, more preferably 0.005 to 50 mol %, further preferably 0.01 to 20 mol % based on the sum of the mol numbers of compounds of the formulae (a), (b) and (c).

In condensation polymerization, if necessary, a base is used in some cases. The base includes inorganic bases such as sodium carbonate, potassium carbonate, cesium carbonate, potassium fluoride, cesium fluoride, tripotassium phosphate and the like, and organic bases such as tetrabutylammonium fluoride, tetrabutylammonium chloride, tetrabutylammonium bromide, tetrabutylammonium hydroxide and the like.

Though the base can be used in any amount, the amount thereof is, in general, preferably 0.5 to 20 equivalents, more preferably 1 to 10 equivalents based on the sum of the mol numbers of compounds of the formulae (a), (b) and (c).

The condensation polymerization can be carried out in the absence of a solvent, however, it is usually carried out in the presence of an organic solvent.

The organic solvent to be used includes toluene, xylene, mesitylene, tetrahydrofuran, 1,4-dioxane, dimethoxyethane, N,N-dimethylacetamide, N,N-dimethylformamide and the like. These organic solvents may be used singly or in admixture of two or more of them.

The organic solvent is usually used in a proportion so as to provide a monomer concentration of 0.1 to 90 wt %. The proportion thereof is preferably 1 to 50 wt %, more preferably 2 to 30 wt %.

It is desirable that the organic solvent is subjected to a deoxygenation treatment, in general, to suppress side reactions though varying depending on the compounds and reactions to be used.

The reaction temperature at which condensation polymerization is carried out is not particularly restricted providing it is in a range wherein a reaction medium is kept liquid. The temperature range is preferably from −100° C. to 200° C., more preferably 80° C. to 150° C., further preferably 1° C. to 120° C.

The reaction time is usually 1 hour or longer, preferably from 2 to 500 hours though varying depending on the reaction conditions such as the reaction temperature and the like.

It is desirable, in some cases, that the condensation polymerization is carried out, if necessary, under dehydration conditions. Particularly, when Y¹ in the formulae (a), (b) and (c) is a group of the formula (a-2), it is necessary that the condensation polymerization is carried out under dehydration conditions.

Regarding the condensation polymerization conditions, illustrated are, for example, a method of polymerization by the Suzuki reaction (Chem. Rev., vol. 95, p. 2457 (1995)), a method of polymerization by the Grignard reaction (Kyoritsu Publication, Polymer Functional Material (kobunshi kino zairyou) Series vol. 2, Synthesis and Reaction of Polymer (kobunshi no gosei to hanno) (2), p. 432 to 433), a method of polymerization by the Yamamoto polymerization method (Prog. Polym. Sci.), vol. 17, p. 1153 to 1205, 1992), and the like.

The post treatment can be effected according to a known method. For example, to a lower alcohol such as methanol and the like is added a reaction solution to deposit a precipitate which is then filtrated and dried, thus, an intended polymer compound can be obtained.

When the polymer compound obtained by the above-described post treatment has low purity, it can be purified by usual methods such as re-crystallization, continuous extraction by a soxhlet extraction apparatus, column chromatography and the like.

Next, the polymer light emitting device of the present invention will be described.

The polymer light emitting device of the present invention is characterized in that an organic layer is present between electrodes composed of an anode and a cathode and the organic layer contains a polymer compound of the present invention.

The organic layer may be a light emitting layer, hole transporting layer, hole injection layer, electron transporting layer, electron injection layer, INTERLAYER layer and the like, and the organic layer is preferably a light emitting layer.

Here, the light emitting layer means a layer having a function of light emission, the hole transporting layer means a layer having a function of transporting holes, and the electron transporting layer means a layer having a function of transporting electrons. The INTERLAYER layer means a layer which is present adjacent to a light emitting layer between the light emitting layer and an anode, and has a function of insulating a light emitting layer and an anode, or a light emitting layer and a hole injection layer or hole transporting layer. The electron transporting layer and the hole transporting layer are generically called a charge transporting layer. The electron injection layer and the hole injection layer are generically called a charge injection layer. Two or more light emitting layers, two or more hole transporting layers, two or more hole injection layers, two or more electron transporting layers or two or more electron injection layers may be used each independently.

When the organic layer is a light emitting layer, the light emitting layer as an organic layer may further contain a hole transporting material, electron transporting material or light emitting material. Here, the light emitting material means a material showing fluorescence or phosphorescence.

When a polymer compound of the present invention and a hole transporting material are mixed, the mixing ratio of the hole transporting material based on the whole mixture is from 1 wt % to 80 wt %, preferably 5 wt % to 60 wt %. When a polymer material of the present invention and an electron transporting material are mixed, the mixing ratio of the electron transporting material based on the whole mixture is from 1 wt % to 80 wt %, preferably 5 wt % to 60 wt %. Further, when a polymer compound of the present invention and a light emitting material are mixed, the mixing ratio of the light emitting material based on the whole mixture is from 1 wt % to 80 wt %, preferably 5 wt % to 60 wt %. When a polymer compound of the present invention, a light emitting material, a hole transporting material and/or an electron transporting material are mixed, the mixing ratio of the light emitting material based on the whole mixture is from 1 wt % to 50 wt %, preferably 5 wt % to 40 wt %, the ratio of the sum the hole transporting material and the electron transporting material is from 1 wt % to 50 wt %, preferably 5 wt % to 40 wt %. Thus, the content of the polymer compound of the present invention is from 98 wt % to 1 wt %, preferably 90 wt % to 20 wt %.

As the hole transporting material, electron transporting material and light emitting material to be mixed, known low molecular weight compounds, triplet light emitting complexes or polymer compounds can be used, and polymer compounds are preferably used.

Examples of the hole transporting material, electron transporting material and light emitting material as polymer compounds include polyfluorene, its derivatives and copolymers, polyarylene, its derivatives and copolymers, polyarylenevinylene, its derivatives and copolymers, and (co)polymers of aromatic amine and its derivatives disclosed in WO99/13692, WO99/48160, GB2340304A, WO00/53656, WO01/19834, WO00/55927, GB2348316, WO00/46321, WO00/06665, WO99/54943, WO99/54385, U.S. Pat. No. 5,777,070, WO98/06773, WO97/05184, WO00/35987, WO00/53655, WO01/34722, WO99/24526, WO00/22027, WO00/22026, WO98/27136, US573636, WO98/21262, U.S. Pat. No. 5,741,921, WO97/09394, WO96/29356, WO96/10617, EP0707020, WO95/07955, JP-A Nos. 2001-181618, 2001-123156, 2001-3045, 2000-351967, 2000-303066, 2000-299189, 2000-252065, 2000-136379, 2000-104057, 2000-80167, 10-324870, 10-114891, 9-111233, 9-45478 and the like.

The fluorescent material of lower molecular weight, there can be used, for example, includes naphthalene derivatives, anthracene or its derivatives, perylene or its derivatives, and polymethine, xanthene, coumarin and cyanine coloring matters, metal complexes of 8-hydrozyquinoline or its derivatives, aromatic amine, tetraphenylcyclopentadiene or its derivatives, or tetraphenylbutadiene or its derivatives, and the like.

Known compounds such as those described in, for example, JP-A Nos. 57-51781, 59-194393, and the like can be used.

The triplet light emitting complex, for example, includes Ir(ppy)₃, Btp₂Ir(acac) containing iridium as a central metal, PtOEP containing platinum as a central metal, Eu(TTA)₃-phen containing europium as a central metal, and the like.

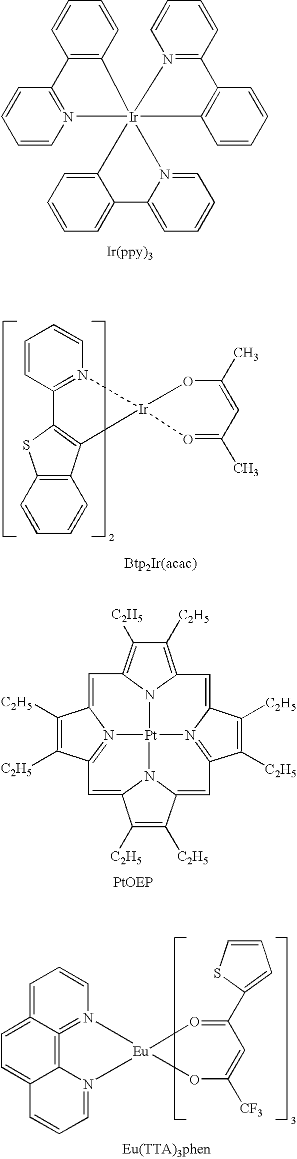

The triplet light emitting complex is described, for example, in Nature, (1998), 395, 151, Appl. Phys. Lett. (1999), 75(1), 4, Proc. SPIE-Int. Soc. Opt. Eng. (2001), 4105 (Organic Light-Emitting Materials and Devices IV), 119, J. Am. Chem. Soc., (2001), 123, 4304, Appl. Phys. Lett., (1997), 71(18), 2596, Syn. Met., (1998), 94(1), 103, Syn. Met., (1999), 99(2), 1361, Adv. Mater., (1999), 11(10), 852, Jpn. J. Appl. Phys., 34, 1883 (1995), and the like.

The polymer composition of the present invention contains at least one material selected from hole transporting materials, electron transporting materials and light emitting materials, and a polymer compound of the present invention, and can be used as a light emitting material or charge transporting material.

The content ratio of at least one material selected from hole transporting materials, electron transporting materials and light emitting materials to a polymer compound of the present invention may be determined depending on use, and in the case of use of a light emitting material, the same content ratio as in the above-described light emitting layer is preferable.

The polymer composition of the present invention has a polystyrene-reduced number average molecular weight of usually about from 10³ to 10⁸, preferably 10⁴ to 10⁶. The polystyrene-reduced weight average molecular weight is usually about from 10³ to 10⁸, and from the standpoint of film formability and from the standpoint of efficiency when made into a device, preferably 1×10⁴ to 5×10⁶. Here, the average molecular weight of a polymer composition is a value obtained by analyzing a composition obtained by mixing two or more polymer compounds by GPC.

The thickness of a light emitting layer of a polymer light emitting device of the present invention manifests the optimum value varying depending on the material to be used, and may be advantageously selected so as to give optimum driving voltage and light emission efficiency, and it is, for example, from 1 nm to 1 μm, preferably 2 nm to 500 nm, further preferably 5 nm to 200 nm.

The method for forming a light emitting layer, for example, includes a method of film formation from a solution. The film formation method from a solution includes application methods such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like. Printing methods such as a screen printing method, flexo printing method, offset printing method, inkjet printing method and the like are preferable since pattern formation and multicolor separate painting are easy.

As the solution (ink composition) used in printing methods, it is advantageous that at least one of polymer compounds of the present invention be contained, and in addition to the polymer compound of the present invention, additives such as a hole transporting material, electron transporting material, light emitting material, solvent, stabilizer and the like may be contained.

The ratio of a polymer compound of the present invention in the ink composition is usually from 20 wt % to 100 wt %, preferably 40 wt % to 100 wt % based on the total weight of the composition excepting a solvent.

The ratio of a solvent when the ink composition contains a solvent is from 1 wt % to 99.9 wt %, preferably 60 wt % to 99.5 wt %, further preferably 80 wt % to 99.0 wt % based on the total weight of the composition.

Though the viscosity of an ink composition depends on a printing method, when an ink composition passes through a discharge apparatus such as in an inkjet print method and the like, the viscosity at 25° C. is preferably in a range of 1 to 20 mPa·s, for preventing clogging and curving in flying in discharging.

The solution of the present invention may contain additives for regulating viscosity and/or surface tension in addition to the polymer compound of the present invention. As the additive, a polymer compound (thickening agent) having high molecular weight for enhancing viscosity and a poor solvent, a compound of low molecular weight for lowering viscosity, a surfactant for lowering surface tension, and the like may be appropriately combined and used.

As the above-described polymer compound having high molecular weight, a compound which is soluble in the same solvent as for the polymer compound of the present invention and which does not disturb light emission and charge transportation may be used. For example, polystyrene of high molecular weight, polymethyl methacrylate, polymer compounds of the present invention having larger molecular weights, and the like can be used. The weight-average molecular weight is preferably 500000 or more, more preferably 1000000 or more.

It is also possible to use a poor solvent as a thickening agent. Namely, by adding a small amount of poor solvent for solid components in a solution, viscosity can be enhanced. When a poor solvent is added for this purpose, the kind and addition amount of the solvent may be advantageously selected in a range not causing deposition of solid components in a solution. When stability in preservation is taken into consideration, the amount of a poor solvent is preferably 50 wt % or less, further preferably 30 wt % or less based on the whole solution.

The solution of the present invention may contain an antioxidant in addition to the polymer compound of the present invention for improving preservation stability. As the antioxidant, a compound which is soluble in the same solvent as for the polymer compound of the present invention and which does not disturb light emission and charge transportation is permissible, and examples are phenol-type antioxidants, phosphorus-based antioxidants and the like.

The solvent to be used as an ink composition is not particularly restricted, compounds which can dissolve or uniformly disperse materials other than the solvent constituting the ink composition are preferable. Examples of the solvent are chlorine-based solvents such as chloroform, methylene chloride, 1,2-dichloroethane, 1,1,2-trichloroethane, chlorobenzene, o-dichlorobenzene and the like, ether solvents such as tetrahydrofuran, dioxane, anisole and the like, aromatic hydrocarbon solvents such as toluene, xylene and the like, aliphatic hydrocarbon solvents such as cyclohexane, methylcyclohexane, n-pentane, n-hexane, n-heptane, n-octane, n-nonane, n-decane and the like, ketone solvents such as acetone, methyl ethyl ketone, cyclohexanone, benzophenone, acetophenone and the like, ester solvents such as ethyl acetate, butyl acetate, ethylcellosolve acetate, methyl benzoate, phenyl acetate and the like, polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexanediol and the like and derivatives thereof, alcohol solvents such as methanol, ethanol, propanol, isopropanol, cyclohexanol and the like, sulfoxide solvents such as dimethyl sulfoxide and the like, amide solvents such as N-methyl-2-pyrrolidone, N,N-dimethylformamide and the like. These organic solvents can be used singly or in combination of two or more.

Of them, preferable from the standpoints of solubility of a polymer compound and the like, uniformity in film formation, viscosity property and the like are aromatic hydrocarbon solvents, ether solvents, aliphatic hydrocarbon solvents, ester solvents and ketone solvents, and preferable are toluene, xylene, ethylbenzene, diethylbenzene, trimethylbenzene, n-propylbenzene, isopropylbenzene, n-butylbenzene, isobutylbenzene, s-butylbenzene, n-hexylbenzene, cyclohexylbenzene, 1-methylnaphthalene, tetralin, anisole, ethoxybenzene, cyclohexane, bicyclohexyl, cyclohexenylcyclohexanone, n-heptylcyclohexane, n-hexylcyclohexanone, decalin, methyl benzoate, cyclohexanone, 2-propylcyclohexanone, 2-heptanone, 3-heptanone, 4-heptanone, 2-octanone, 2-nonanone, 2-decanone, dicyclohexylketone, acetophenone and benzophenone.

The number of solvents in a solution is preferably 2 or more, more preferably 2 to 3, further preferably 2, from the standpoint of film formability and from the standpoints of device properties and the like.

When two solvents are contained in a solution, one of them may be solid at 25° C. From the standpoint of film formability, it is preferable that one solvent has a boiling point of 180° C. or higher, and a solvent having a boiling point of 200° C. or higher is more preferable. From the standpoint of viscosity, it is preferable that an aromatic polymer is dissolved in an amount of 1 wt % or more at 60° C. in both solvents, and it is preferable that one of two solvents dissolves an aromatic polymer in an amount of 1 wt % or more at 25° C.

When two or more solvents are contained in a solution, the content of a solvent having highest boiling point is preferably from 40 to 90 wt %, more preferably 50 to 90 wt %, further preferably 65 to 85 wt % based on the weight of all solvents in the solution from the standpoints of viscosity and film formability.

Aromatic polymers of the present invention may be contained singly or in combination of two or more in a solution, and a polymer compound other than the aromatic polymers of the present invention may also be contained in a range not deteriorating device properties and the like.

The solution of the present invention may contain water, metal and its salt in an amount of from 1 to 1000 ppm. The metal includes lithium, sodium, calcium, potassium, iron, copper, nickel, aluminum, zinc, chromium, manganese, cobalt, platinum, iridium and the like. Further, silicon, phosphorus, fluorine, chlorine and/or bromine may be contained in an amount of from 1 to 1000 ppm.

Using a solution of the present invention, a thin film can be formed by a spin coat method, casting method, micro gravure coat method, gravure coat method, bar coat method, roll coat method, wire bar coat method, dip coat method, spray coat method, screen printing method, flexo printing method, offset printing method, inkjet printing method and the like. Particularly, a solution of the present invention is preferably used for film formation by a screen printing method, flexo printing method, offset printing method or inkjet printing method, and more preferably used for film formation by an inkjet method.

When a thin film is formed using a solution of the present invention, baking at temperatures of 100° C. or higher is possible since a polymer compound contained in the solution has higher glass transition temperature, and even if baking is performed at a temperature of 130° C., lowering of device properties is very small. Depending on the kind of the polymer compound, baking at temperatures of 160° C. or higher is also possible.

As the thin film which can be formed using a solution of the present invention, examples include a light emitting thin film, electrically conductive thin film and organic semiconductor thin film.

The electrically conductive thin film of the present invention preferably has a surface resistance of 1 KΩ/ or less. By doping a thin film with a Lewis acid, ionic compound and the like, electric conductivity can be enhanced. The surface resistance is preferably 100Ω/ or less, further preferably 10 Ω/or less.

In the organic semiconductor thin film of the present invention, one larger parameter of electron mobility or hole mobility is preferably 10⁻⁵ cm²/V/s or more. More preferably, it is 10⁻³ cm²/V/s or more, and further preferably 10⁻¹ cm²/V/s or more.

By forming the organic semiconductor thin film on a Si substrate carrying a gate electrode and an insulation film of SiO₂ and the like formed thereon, and forming a source electrode and a drain electrode with Au and the like, an organic transistor can be obtained.

In the polymer light emitting device of the present invention, the maximum external quantum yield when a voltage of 3.5 V or more is applied between an anode and a cathode is preferably 1% or more, more preferably 1.5% or more from the standpoints of device brilliance and the like.

The polymer light emitting device of the present invention includes a polymer light emitting device having an electron transporting layer placed between a cathode and a light emitting layer, a polymer light emitting device having a hole transporting layer placed between an anode and a light emitting layer, a polymer light emitting device having an electron transporting layer placed between a cathode and a light emitting layer and a hole transporting layer placed between an anode and a light emitting layer, and the like.

For example, the following structures a) to d) are illustrated.

a) anode/light emitting layer/cathode

b) anode/hole transporting layer/light emitting layer/cathode

c) anode/light emitting layer/electron transporting layer/cathode

d) anode/hole transporting layer/light emitting layer/electron transporting layer/cathode (wherein, / means adjacent lamination of layers, being applicable also in the followings)

Also illustrated are structures having an INTERLAYER layer provided adjacent to a light emitting layer between the light emitting layer and an anode in the above-described structures. That is, the following structures a′) to d′) are illustrated.

a′) anode/INTERLAYER layer/light emitting layer/cathode

b′) anode/hole transporting layer/INTERLAYER layer/light emitting layer/cathode

c′) anode/INTERLAYER layer/light emitting layer/electron transporting layer/cathode

d′) anode/hole transporting layer/INTERLAYER layer/light emitting layer/electron transporting layer/cathode

When the polymer light emitting device of the present invention contains a hole transporting layer, examples of the hole transporting material to be used are polyvinylcarbazole or its derivatives, polysilane or its derivatives, polysiloxane derivatives having an aromatic amine on the side chain or main chain, pyrazoline derivatives, arylamine derivatives, stilbene derivatives, triphenyldiamine derivatives, polyaniline or its derivatives, polythiophene or its derivatives, polypyrrole or its derivatives, poly(p-phenylenevinylene) or its derivatives, poly(2,5-thienylenevinylene) or its derivatives, and the like.

Examples of the hole transporting material are those described in JP-A Nos. 63-70257, 63-175860, 2-135359, 2-135361, 2-209988, 3-37992 and 3-152184, and the like.

Among them, preferable as the hole transporting material used in a hole transporting layer are polymer hole transporting materials such as polyvinylcarbazole or its derivatives, polysilane or its derivatives, polysiloxane derivatives having an aromatic amine compound group on the side chain or main chain, polyaniline or its derivatives, polythiophene or its derivatives, poly(p-phenylenevinylene) or its derivatives, poly(2,5-thienylenevinylene) or its derivatives, and the like, and further preferable are polyvinylcarbazole or its derivatives, polysilane or its derivatives, and polysiloxane derivatives having an aromatic amine on the side chain or main chain.

Examples of the hole transporting material of low molecular weight are pyrazoline derivatives, arylamine derivatives, stilbene derivatives, and triphenyldiamine derivatives. In the case of the hole transporting material of low molecular weight, it is preferably dispersed in a polymer binder in use.

The polymer binder to be mixed is preferably that which does not extremely disturb charge transportation, and those showing no strong absorption against visible ray are suitably used. Examples of the polymer binder are poly(N-vinylcarbazole), polyaniline or its derivatives, polythiophene or its derivatives, poly(p-phenylenevinylene) or its derivatives, poly(2,5-thienylenevinylene) or its derivatives, polycarbonate, polyacrylate, polymethyl acrylate, polymethyl methacrylate, polystyrene, polyvinyl chloride, polysiloxane and the like.

Polyvinylcarbazole or its derivative can be obtained, for example, from a vinyl monomer by cation polymerization or radical polymerization.

As the polysilane or its derivative, compounds described in Chem. Rev., vol. 89, p. 1359 (1989), GB Patent No. 2300196 publication, and the like are illustrated. Also as the synthesis method, methods described in them can be used, and particularly, the Kipping method is suitably used.

In the polysiloxane or its derivative, the siloxane skeleton structure shows little hole transporting property, thus, those having a structure of the above-described hole transporting material of low molecular weight on the side chain or main chain are suitably used. Particularly, those having an aromatic amine showing hole transportability on the side chain or main chain are illustrated.

Though the film formation method of a hole transporting layer is not particularly restricted, a method of film formation from a mixed solution with a polymer binder is illustrated, in the case of a hole transporting material of low molecular weight. In the case of a hole transporting material of high molecular weight, a method of film formation from a solution is illustrated.

As the solvent used for film formation from a solution, those which can dissolve or uniformly disperse a hole transporting material are preferable. Examples of the solvent are chlorine-based solvents such as chloroform, methylene chloride, 1,2-dichloroethane, 1,1,2-trichloroethane, chlorobenzene, o-dichlorobenzene and the like, ether solvents such as tetrahydrofuran, dioxane and the like, aromatic hydrocarbon solvents such as toluene, xylene and the like, aliphatic hydrocarbon solvents such as cyclohexane, methylcyclohexane, n-pentane, n-hexane, n-heptane, n-octane, n-nonane, n-decane and the like, ketone solvents such as acetone, methyl ethyl ketone, cyclohexanone and the like, ester solvents such as ethyl acetate, butyl acetate, ethylcellosolve acetate and the like, polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexanediol and the like and derivatives thereof, alcohol solvents such as methanol, ethanol, propanol, isopropanol, cyclohexanol and the like, sulfoxide solvents such as dimethyl sulfoxide and the like, amide solvents such as N-methyl-2-pyrrolidone, N,N-dimethylformamide and the like. These organic solvents can be used singly or in combination of two or more.

As the method for film formation from a solution, there can be used application methods from a solution such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like.

Regarding the thickness of a hole transporting layer, the optimum value varies depending on a material to be used, and it may be advantageously selected so as to give suitable driving voltage and light emission efficiency, and a thickness at least causing no formation of pin holes is necessary, and when the thickness is too large, the driving voltage of a device increases undesirably. Therefore, the thickness of the hole transporting layer is, for example, from 1 nm to 1 μm, preferably 2 nm to 500 nm, further preferably 5 nm to 200 nm.

When the polymer light emitting device of the present invention has an electron transporting layer, known materials can be used as the electron transporting material to be used, and examples are oxadiazole derivatives, anthraquinodimethane or its derivatives, benzoquinone or its derivatives, naphthoquinone or its derivatives, anthraquinone or its derivatives, tetracyanoanthraquinodimethane or its derivatives, fluorenone derivatives, diphenyldicyanoethylene or its derivatives, diphenoquinone derivatives, metal complexes of 8-hydroxyquinoline or its derivatives, polyquinoline or its derivatives, polyquinoxaline or its derivatives, polyfluorene or its derivatives, and the like.

Specifically, those described in JP-A Nos. 63-70257, 63-175860, 2-135359, 2-135361, 2-209988, 3-37992, 3-152184, and the like are illustrated.

Of them, oxadiazole derivatives, benzoquinone or its derivatives, anthraquinone or its derivatives, metal complexes of 8-hydroxyquinoline or its derivatives, polyquinoline or its derivatives, polyquinoxaline or its derivatives, polyfluorene or its derivatives are preferable, and 2-(4-biphenylyl)-5-(4-t-butylphenyl)-1,3,4-oxadiazole, benzoqinone, anthraquinone, tris(8-quinolinol)aluminum and polyquinoline are further preferable.

The film formation method of an electron transporting layer is not particularly restricted, and in the case of an electron transporting material of low molecular weight, illustrated are a vacuum vapor-deposition method from powder, film formation methods from solution or melted condition, and in the case of an electron transporting material of high molecular weight, film formation methods from solution or melted condition are illustrated, respectively. In film formation from solution or melted condition, the above-described polymer binders may be used together.

As the solvent used in film formation from a solution, compounds which can dissolve or uniformly disperse an electron transporting material and/or polymer binder are preferable. Examples of the solvent are chlorine-based solvents such as chloroform, methylene chloride, 1,2-dichloroethane, 1,1,2-trichloroethane, chlorobenzene, o-dichlorobenzene and the like, ether solvents such as tetrahydrofuran, dioxane and the like, aromatic hydrocarbon solvents such as toluene, xylene and the like, aliphatic hydrocarbon solvents such as cyclohexane, methylcyclohexane, n-pentane, n-hexane, n-heptane, n-octane, n-nonane, n-decane and the like, ketone solvents such as acetone, methyl ethyl ketone, cyclohexanone and the like, ester solvents such as ethyl acetate, butyl acetate, ethylcellosolve acetate and the like, polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexanediol and the like and derivatives thereof, alcohol solvents such as methanol, ethanol, propanol, isopropanol, cyclohexanol and the like, sulfoxide solvents such as dimethyl sulfoxide and the like, amide solvents such as N-methyl-2-pyrrolidone, N,N-dimethylformamide and the like. These organic solvents can be used singly or in combination of two or more.

As the film formation method from solution or melted condition, application methods such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like can be used.

Regarding the thickness of an electron transporting layer, the optimum value varies depending on a material to be used, and it may be advantageously selected so as to give suitable driving voltage and light emission efficiency, and a thickness at least causing no formation of pin holes is necessary, and when the thickness is too large, the driving voltage of a device increases undesirably. Therefore, the thickness of the electron transporting layer is, for example, from 1 nm to 1 μm, preferably 2 nm to 500 nm, further preferably 5 nm to 200 nm.

Among charge transporting layers placed adjacent to an electrode, those having a function of improving charge injection efficiency from an electrode and having an effect of lowering the driving voltage of a device are, in particular, called generally a charge injection layer (hole injection layer, electron injection layer).

Further, for improving close adherence with an electrode and improving charge injection from an electrode, the above-described charge injection layer or an insulation layer having a thickness of 2 nm or less may be placed adjacent to the electrode, alternatively, for improving close adherence of an interface and preventing mixing, a thin buffer layer may be inserted into an interface of a charge transporting layer and a light emitting layer.

The order and number of layers to be laminated, and thickness of each layer can be appropriately determined in view of light emission efficiency and life of a device.

In the present invention, as the polymer light emitting device carrying a provided charge injection layer (electron injection layer, hole injection layer), mentioned are polymer light emitting devices having a charge injection layer provided adjacent to a cathode and polymer light emitting devices having a charge injection layer provided adjacent to an anode.

For example, the following structures e) to p) are specifically mentioned.

e) anode/charge injection layer/light emitting layer/cathode

f) anode/light emitting layer/charge injection layer/cathode

g) anode/charge injection layer/light emitting layer/charge injection layer/cathode

h) anode/charge injection layer/hole transporting layer/light emitting layer/cathode

i) anode/hole transporting layer/light emitting layer/charge injection layer/cathode

j) anode/charge injection layer/hole transporting layer/light emitting layer/charge injection layer/cathode

k) anode/charge injection layer/light emitting layer/electron transporting layer/cathode

l) anode/light emitting layer/electron transporting layer/charge injection layer/cathode

m) anode/charge injection layer/light emitting layer/electron transporting layer/charge injection layer/cathode

n) anode/charge injection layer/hole transporting layer/light emitting layer/electron transporting layer/cathode

o) anode/hole transporting layer/light emitting layer/electron transporting layer/charge injection layer/cathode

p) anode/charge injection layer/hole transporting layer/light emitting layer/electron transporting layer/charge injection layer/cathode

Also illustrated are structures having an INTERLAYER layer placed adjacent to a light emitting layer between the light emitting layer and an anode in the above-described structures. In this case, the INTERLAYER layer may also function as a hole injection layer and/or hole transporting layer.

Examples of the charge injection layer are a layer containing an electric conductive polymer, a layer provided between an anode and a hole transporting layer and containing a material having ionization potential of a value between an anode material and a hole transporting material contained in a hole transporting layer, a layer provided between a cathode and an electron transporting layer and containing a material having electron affinity of a value between a cathode material and an electron transporting material contained in an electron transporting layer, and the like.

When the above-described charge injection layer contains an electric conductive polymer, electric conductivity of the electric conductive polymer is preferably 10⁻⁵ S/cm or more and 10³ or less, and for decreasing leak current between light emission picture elements, more preferably 10⁻⁵ S/cm or more and 10² or less, further preferably 10⁻⁵ S/cm or more and 10¹ or less.

When the above-described charge injection layer contains an electric conductive polymer, electric conductivity of the electric conductive polymer is preferably 10⁻⁵ S/cm or more and 10³ S/cm or less, and for decreasing leak current between light emission picture elements, more preferably 10⁻⁵ S/cm or more and 10² S/cm or less, further preferably 10⁻⁵ S/cm or more and 10¹ S/cm or less.

Usually, for controlling the electric conductivity of the electric conductive polymer to 10⁻⁵ S/cm or more and 10³ or less, the electric conductive polymer is doped with a suitable amount of ions.

As the kind of ions to be doped, an anion is used in a hole injection layer and a cation is used in an electron injection layer. Examples of the anion include a polystyrenesulfonic ion, alkylbenzenesulfonic ion, camphorsulfonic ion and the like, and examples of the cation include a lithium ion, sodium ion, potassium ion, tetrabutylammonium ion and the like.

The thickness of the charge injection layer is, for example, from 1 nm to 100 nm, preferably 2 nm to 50 nm.

The material used in the charge injection layer may be appropriately selected depending on a relation with materials of an electrode and an adjacent layer, and examples are polyaniline or its derivatives, polythiophene or its derivatives, polypyrrole and its derivatives, polyphenylenevinylene and its derivatives, polythienylenevinylene and its derivatives, polyquinoxaline and its derivatives, electric conductive polymers such as polymers containing an aromatic amine structure on the main chain or side chain, metal phthalocyanines (copper phthalocyanine and the like), carbon and the like.

An insulation layer having a thickness of 2 nm or less has a function of making charge injection easier. The material of the above-described insulation layer includes a metal fluoride, metal oxide, organic insulating material and the like. Polymer light emitting device carrying an insulation layer having a thickness of 2 nm or less provide thereon includes polymer light emitting devices in which an insulation layer having a thickness of 2 nm or less is placed adjacent to a cathode, and polymer light emitting devices in which an insulation layer having a thickness of 2 nm or less is placed adjacent to an anode.

Specifically, for example, the following structures q) to ab) are mentioned.

q) anode/insulation layer having a thickness of 2 nm or less/light emitting layer/cathode

r) anode/light emitting layer/insulation layer having a thickness of 2 nm or less/cathode

s) anode/insulation layer having a thickness of 2 nm or less/light emitting layer/insulation layer having a thickness of 2 nm or less/cathode

t) anode/insulation layer having a thickness of 2 nm or less/hole injection layer/light emitting layer/cathode

u) anode/hole injection layer/light emitting layer/insulation layer having a thickness of 2 nm or less/cathode

v) anode/insulation layer having a thickness of 2 nm or less/hole transporting layer/light emitting layer/insulation layer having a thickness of 2 nm or less/cathode

w) anode/insulation layer having a thickness of 2 nm or less/light emitting layer/electron transporting layer/cathode

x) anode/light emitting layer/electron transporting layer/insulation layer having a thickness of 2 nm or less/cathode

y) anode/insulation layer having a thickness of 2 nm or less/light emitting layer/electron transporting layer/insulation layer having a thickness of 2 nm or less/cathode

z) anode/insulation layer having a thickness of 2 nm or less/hole transporting layer/light emitting layer/electron transporting layer/cathode

aa) anode/hole transporting layer/light emitting layer/electron transporting layer/insulation layer having a thickness of 2 nm or less/cathode

ab) anode/insulation layer having a thickness of 2 nm or less/hole transporting layer/light emitting layer/electron transporting layer/insulation layer having a thickness of 2 nm or less/cathode

Also illustrated are structures having an INTERLAYER layer provided adjacent to a light emitting layer between the light emitting layer and an anode in the above-described structures. In this case, the INTERLAYER layer may also function as a hole injection layer and/or hole transporting layer.

In structures in which an INTERLAYER layer is applied to the above-described structures a) to ab), the INTERLAYER layer is preferably placed between an anode and a light emitting layer and constituted of a material having intermediate ionization potential between the anode or hole injection layer or hole transporting layer, and a polymer compound constituting the light emitting layer.

The material to be used in the INTERLAYER layer includes polymers containing an aromatic amine such as polyvinylcarbazole or its derivatives, polyarylene derivatives having an aromatic amine on the side chain or main chain, arylamine derivatives, triphenyldiamine derivatives and the like.

Though the method for forming the INTERLAYER layer is not particularly restricted, a method of film formation from a solution is exemplified, for example, in the case of use of a polymer material.

As the solvent to be used in film formation from a solution, compounds which can dissolve or uniformly disperse a material used in an INTERLAYER layer are preferable. Examples of the solvent are chlorine-based solvents such as chloroform, methylene chloride, 1,2-dichloroethane, 1,1,2-trichloroethane, chlorobenzene, o-dichlorobenzene and the like, ether solvents such as tetrahydrofuran, dioxane and the like, aromatic hydrocarbon solvents such as toluene, xylene and the like, aliphatic hydrocarbon solvents such as cyclohexane, methylcyclohexane, n-pentane, n-hexane, n-heptane, n-octane, n-nonane, n-decane and the like, ketone solvents such as acetone, methyl ethyl ketone, cyclohexanone and the like, ester solvents such as ethyl acetate, butyl acetate, ethylcellosolve acetate and the like, polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexanediol and the like and derivatives thereof, alcohol solvents such as methanol, ethanol propanol, isopropanol, cyclohexanol and the like, sulfoxide solvents such as dimethyl sulfoxide and the like, amide solvents such as N-methyl-2-pyrrolidone, N,N-dimethylformamide and the like. These organic solvents can be used singly or in combination of two or more.

As the film formation method from a solution, application methods from a solution such as a spin coat method, casting method, micro gravure coat method, gravure coat method, bar coat method, roll coat method, wire bar coat method, dip coat method, spray coat method, screen printing method, flexo printing method, offset printing method, inkjet printing method and the like can be used.

Regarding the thickness of an INTERLAYER layer, the optimum value varies depending on a material to be used, and it may be advantageously selected so as to give suitable driving voltage and light emission efficiency. The thickness thereof is, for example, from 1 nm to 1 μm, preferably 2 nm to 500 nm, further preferably 5 nm to 200 nm.

When the INTERLAYER layer is provided adjacent to a light emitting layer, particularly when both the layers are formed by an application method, the two layers may be mixed to exert an undesirable influence on device properties and the like in some cases. When the INTERLAYER layer is formed by an application method before formation of a light emitting layer by an application method, there is mentioned a method in which an INTERLAYER layer is formed by an application method, then, the INTERLAYER layer is heated to be insolubilized in an organic solvent to be used for manufacturing a light emitting layer, then, the light emitting layer is formed, as a method for reducing mixing of materials of the two layers. The heating temperature is usually about from 150° C. to 300° C., and the heating time is usually about from 1 minute to 1 hour. In this case, for removal of components not insolubilized in solvent by heating, the INTERLAYER layer can be removed by rinsing with a solvent to be used for formation of a light emitting layer, after heating and before formation of the light emitting layer. When insolubilization in solvent by heating is carried out sufficiently, rinsing with a solvent can be omitted. For insolubilization in solvent by heating to be carried out sufficiently, it is preferable to use a compound containing at least one polymerizable group in the molecule, as a polymer compound to be used in an INTERLAYER layer. Further, the number of polymerizable groups is preferably 5% or more based on the number of repeating units in the molecule.

The substrate which forms a polymer light emitting device of the present invention may be that forming an electrode and which does not change in forming a layer of an organic substance, and examples are, for example, substrates of glass, plastic, polymer film, silicon and the like. In the case of an opaque substrate, it is preferable that the opposite electrode is transparent or semi-transparent.

Usually, at least one of an anode and a cathode contained in a polymer light emitting device of the present invention is transparent or semi-transparent. It is preferable that a cathode is transparent or semi-transparent.

As the material of the cathode, an electric conductive metal oxide film, semi-transparent metal thin film and the like are used. Films (NESA and the like) formed using electric conductive glass composed of indium oxide, zinc oxide, tin oxide, and composite thereof: indium.tin.oxide (ITO), indium.zinc.oxide and the like, gold, platinum, silver, copper and the like are used, and ITO, indium.zinc.oxide, tin oxide are preferable. The manufacturing method includes a vacuum vapor-deposition method, sputtering method, ion plating method, plating method and the like. As the anode, organic transparent electric conductive films made of polyaniline or its derivative, polythiophene or its derivative, and the like may be used.

The thickness of an anode can be appropriately selected in view of light transmission and electric conductivity, and it is, for example, from 10 nm to 10 μm, preferably 20 nm to 1 μm, more preferably 50 nm to 500 nm.

For making charge injection easier, a layer made of a phthalocyanine derivative, electric conductive polymer, carbon and the like, or a layer having an average thickness of 2 nm or less made of a metal oxide, metal fluoride, organic insulation material and the like, may be provided on an anode.

As the material of a cathode used in a polymer light emitting device of the present invention, materials of small work function are preferable. For example, metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, alloys of two or more of them, or alloys made of at least one of them and at least one gold, silver, platinum, copper, manganese, titanium, cobalt, nickel, tungsten and tin, or graphite or graphite intercalation compounds and the like are used. Examples of the alloy include magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The cathode may take a laminated structure including two or more layers.

The thickness of a cathode can be appropriately selected in view of electric conductivity and durability, and it is, for example, from 10 nm to 10 μm, preferably 20 nm to 1 μm, further preferably 50 nm to 500 nm.

As the cathode manufacturing method, a vacuum vapor-deposition method, sputtering method, lamination method of thermally press-binding a metal thin film, and the like are used. A layer made of an electric conductive polymer, or a layer having an average thickness of 2 nm or less made of a metal oxide, metal fluoride, organic insulation material and the like, may be placed between a cathode and an organic substance layer, and after manufacturing a cathode, a protective layer for protecting the polymer light emitting device may be installed. For use of the polymer light emitting device stably for a long period of time, it is preferable to install a protective layer and/or protective cover, for protecting a device from outside.

As the protective layer, a polymer compound, metal oxide, metal fluoride, metal boride and the like can be used. As the protective cover, a metal plate, a glass plate, and a plastic plate having a surface which has been subjected to low water permeation treatment, and the like can be used, and a method of pasting the cover to a device substrate with a thermosetting resin or photo-curable resin to attain close seal is suitably used. When a space is kept using a spacer, prevention of blemishing of a device is easier. If an inert gas such as nitrogen, argon and the like is filled in this space, oxidation of a cathode can be prevented, further, by placing a drying agent such as barium oxide and the like in this space, it becomes easier to suppress moisture adsorbed in a production process or a trace amount of moisture invaded passing through the hardened resin from imparting damage to the device. It is preferable to adopt one strategy among these methods.

The polymer light emitting device of the present invention can be used as a sheet light source, segment display, dot matrix display, back light of a liquid crystal display, and the like.

For obtaining light emission in the form of sheet using a polymer light emitting device of the present invention, it may be advantages to place a sheet anode and a sheet cathode so as to overlap. For obtaining light emission in the form of pattern, there are a method in which a mask having a window in the form of pattern is placed on the surface of the above-described sheet light emitting device, a method in which an organic substance layer in non-light emitting parts is formed with extremely large thickness to give substantially no light emission, and a method in which either anode or cathode, or both electrodes are formed in the form pattern. By forming a pattern by any of these methods, and placing two or more electrodes so that on/off is independently possible, a display of segment type is obtained which can display digits, letters, simple marks and the like. Further, for providing a dot matrix device, it may be permissible that both an anode and a cathode are formed in the form of stripe, and placed so as to cross. By using a method in which two or more polymer fluorescent substances showing different emission colors are painted separately or a method in which a color filter or a fluorescence conversion filter is used, partial color display and multi-color display are made possible. In the case of a dot matrix device, passive driving is possible, and active driving may be carried out in combination with TFT and the like. These displays can be used as a display of a computer, television, portable terminal, cellular telephone, car navigation, view finder of video camera, and the like.

Further, the above-described sheet light emitting device is of self emitting and thin type, and can be suitably used as a sheet light source for back light of a liquid crystal display, or as a sheet light source for illumination. If a flexible substrate is used, it can also be used as a curved light source or display.

The present invention will be illustrated further in detail by examples below, but the invention is not limited to them.

### (Number Average Molecular Weight and Weight Average Molecular Weight)

Here, as the number average molecular weight and the weight average molecular weight, polystyrene-reduced number average molecular weight and weight average molecular weight were measured by GPC (manufactured by Shimadzu Corp., LC-10Avp). A polymer to be measured was dissolved in tetrahydrofuran so as to give a concentration of about 0.5 wt %, and the solution was injected in an amount of 50 μL into GPC. Tetrahydrofuran was used as the mobile phase of GPC, and allowed to flow at a flow rate of 0.6 mL/min. In the column, two TSKgel Super HM-H (manufactured by Tosoh Corp.) and one TSKgel Super H2000 (manufactured by Tosoh Corp.) were connected serially. A differential refractive index detector (RID-10A: manufactured by Shimadzu Corp.) was used as a detector.

### (Fluorescent Spectrum)

Fluorescent spectrum was measured according to the following method. A 0.8 wt % toluene solution of a polymer was spin-coated on quartz to form a thin film of the polymer. This thin film was excited at a wavelength of 350 nm, and fluorescent spectrum thereof was measured using a fluorescence spectrophotometer (Fluorolog manufactured by Horiba, Ltd.). For obtaining relative fluorescence intensity in the thin film, fluorescent spectrum plotted against wave number was integrated in the spectrum measuring range utilizing the intensity of Raman line of water as a standard, and measurement was performed using a spectrophotometer (Cary 5E, manufactured Varian), obtaining a value allocated to the absorbance at the excited wavelength.

### (Glass Transition Temperature)

The glass transition temperature was measured by DSC (DSC2920, manufactured by TA Instruments)<

### Synthesis Example 1

### Synthesis of Compound (J1)

Under an inert atmosphere, to a three-necked flask was added 37.6 g (0.11 mol) of 9,10-dibromoanthracene, 50.4 g (0.22 mol) of N-(4-t-butylphenyl)aniline, 25.8 g (0.27 mol) of t-butoxysodium, 2.1 g (2.2 mmol) of [tris(dibenzylideneacetone)]dipalladium, 1.8 g (9 mmol) of tri-t-butylphosphine and 91 mL of dehydrated toluene, and the mixture was stirred at 100° C. Thereafter, the reaction solution was cooled to room temperature, and 6.2 g of a 1 N hydrochloric acid aqueous solution and 1250 mL of methanol were added while stirring, the deposited crystal was filtrated, washed with MeOH and distilled water, and dried under reduced pressure to obtain a coarse product. The coarse product was re-crystallized from hexane, to obtain 61 g (yield: 100%, HPLC area percentage: 99.3%) of an intended compound (J1).

¹H-NMR (299.4 MHz, CDCl₃): 1.27 (s, 18H), 6.86 (m, 2H), 7.08 (m, 8H), 7.20 (m, 8H), 7.36 (m, 4H), 8.21 (m, 4H)

LC-MS (APPI-MS (posi)): 625 [M+H]⁺

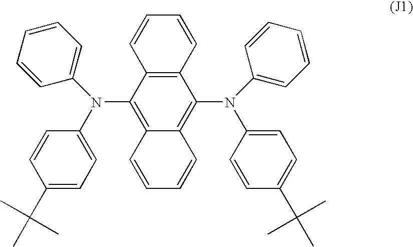

### Synthesis of Compound (J2)

Under an inert atmosphere, to a three-necked flask was added 50.0 g (80 mmol) of the compound (J1) and 1167 mL of chloroform and a uniform solution was prepared, and a solution composed of 29.4 g (165 mmol) of N-bromosuccinimide and 67 mL of dehydrated N,N-dimethylformamide was dropped at from 25 to 35° C. while stirring, and further stirred at from 25 to 35° C. Thereafter, the reaction mixture was refluxed under heat and cooled down to 25° C., and 1330 mL of methanol was dropped, the deposited crystal was filtrated, washed with methanol, and dried under reduced pressure to obtain 59 g (yield: 95%, HPLC area percentage: 99.2%) of an intended compound (J2).

¹H-NMR (299.4 MHz, CDCl₃): 1.27 (s, 18H), 6.90 (m, 4H), 7.08 (m, 4H), 7.25 (m, 8H), 7.39 (m, 4H), 8.16 (m, 4H)

LC-MS (APPI-MS (posi)): 781 [M+H]⁺

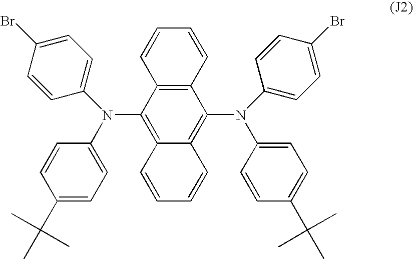

### Synthesis Example 2

### Synthesis of Compound (J3)

Under an inert atmosphere, to a three-necked flask was added 15.0 g (44.6 mmol) of 9,10-dibromoanthracene, 16.4 g (89.2 mmol) of N-(4-methylphenyl)aniline, 10.3 g (107.0 mol) of t-butoxysodium, 0.82 g (0.89 mmol) of [tris(dibenzylideneacetone)]dipalladium, 0.75 g (3.57 mmol) of tri-t-butylphosphine and 100 mL of dehydrated toluene, and the mixture was stirred at 100° C. for 5 hours. Thereafter, the reaction solution was cooled to room temperature, neutralized with a 1 N hydrochloric acid aqueous solution, 500 mL of methanol was added while stirring, and the deposited crystal was filtrated, washed with MeOH and distilled water, and dried under reduced pressure to obtain 22.7 g (yield: 93%, HPLC area percentage: 98.5%) of an intended compound (J3).

¹H-NMR (299.4 MHz, CDCl₃): 2.26 (s, 6H), 6.86 (m, 2H), 7.03 (m, 12H), 7.17 (m, 4H), 7.34 (m, 4H), 8.18 (m, 4H)

LC-MS (APPI-MS (posi)): 541 [M+H]⁺

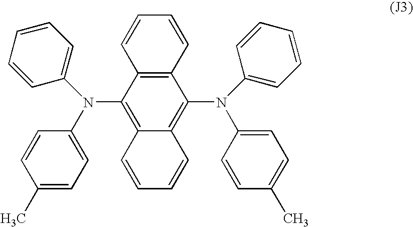

### Synthesis of Compound (J4)

Under an inert atmosphere, to a three-necked flask was added 5.0 g (9.2 mmol) of the compound (J3) and 150 mL of chloroform and heated to prepare a uniform solution, and a solution composed of 3.4 g of N-bromosuccinimide and 8 mL of dehydrated N,N-dimethylformamide was dropped at 25 to 35° C. while stirring, and further stirred at 25 to 35° C. for 4 hours. Thereafter, the reaction mixture was refluxed under heat and cooled down to 25 to 35° C., and the deposited crystal was filtrated, and dried under reduced pressure to obtain a coarse product. The coarse product was suspended in methanol, then, the crystal was filtrated, and washed with methanol and dried under reduced pressure, to obtain 6.0 g (yield: 92.3%, HPLC area percentage: 99.7%) of an intended compound (J4).

¹H-NMR (299.4 MHz, CDCl₃): 2.26 (s, 6H), 6.87 (m, 4H), 7.03 (m, 8H), 7.26 (m, 4H), 7.37 (m, 4H), 8.11 (m, 4H)

LC-MS (APPI-MS (posi)): 696 [M]⁺

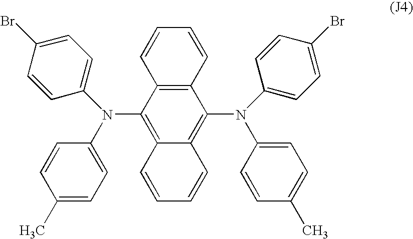

### Synthesis Example 3

### Synthesis of 2,6-di-t-butylanthracene

153 g of anthracene, 191 g of t-butyl alcohol and 860 mL of trifluoroacetic acid were stirred at from 80 to 84° C. for 24 hours, then, cooled down to 4° C. and the deposited precipitate was filtrated, washed with toluene and washed with hexane to obtain gray solid. The solid was re-crystallized from toluene to obtain 76.2 g (yield: 30.5%, HPLC area percentage: 99.1%) of intended 2,6-di-t-butylanthracene.

### Synthesis of 9,10-dibromo-2,6-di-t-butylanthracene

Into a solution composed of 76.2 g of 2,6-di-t-butylanthracene and 2.4 L of carbon tetrachloride, a solution composed of 82.5 g of bromine and 240 mL of carbon tetrachloride was dropped at from 24 to 30° C. over a period of 1 hour, and the mixture was further stirred for 3 hours. Then, in an ice bath, 1 L of 10% sodium hydroxide aqueous solution was dropped over a period of 1.5 hours, and the aqueous layer was separated from the organic layer. The resultant organic layer was washed with water, carbon tetrachloride was distilled off under reduced pressure until the volume reached 500 mL, the resultant solution was cooled down to 7° C. while stirring, and the deposited crystal was filtrated to obtain 110 g (yield: 95%, HPLC area percentage: 99.7%) of intended 9,10-dibromo-2,6-di-t-butylanthracene.

¹H-NMR (299.4 MHz, CDCl₃): 1.49 (s, 18H), 7.70 (d, 2H), 8.45 (s, 2H), 8.50 (d, 2H)

### Synthesis of Compound (J5)

Under an inert atmosphere, 50.0 g of 9,10-dibromo-2,6-di-t-butylanthracene, 50.0 g of N-(4-t-butylphenyl)aniline, 25.7 g of t-butoxysodium, 2.0 g of [tris(dibenzylideneacetone)]dipalladium, 1.8 g of tri-t-butylphosphine and 300 mL of dehydrated toluene were added, and the mixture was stirred at 90° C. for 1 hour. Thereafter, the reaction solution was cooled to room temperature, neutralized with 318 mL of a 1 N hydrochloric acid aqueous solution, 1 L of methanol was added while stirring, and the deposited crystal was filtrated, and washed with MeOH. The crystal was dissolved in 900 mL of toluene, 900 mL of hexane was added to this and the mixture was stirred for 2 hours, and the deposited crystal was filtrated and dried under reduced pressure to obtain 45.1 g (yield: 66%, HPLC area percentage: 99.0%) of an intended compound (J5).

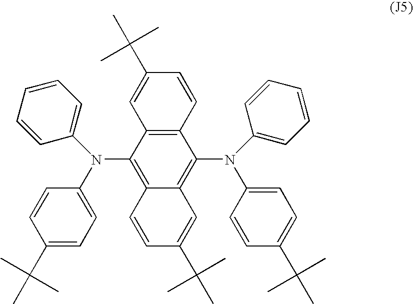

LC-MS (APPI-MS (posi)): 737 [M+H]⁺

### Synthesis of Compound (J6)

Under an inert atmosphere, 40.0 g of the compound (J5) and 840 mL of chlorobenzene were added and heated to prepare a uniform solution, and a solution composed of 17.7 g of N-bromosuccinimide and 40 mL of dehydrated N,N-dimethylformamide was dropped at 30° C. while stirring, and the mixture was stirred at 7° C. for 12 hours. Thereafter, 3360 mL of hexane was added to the reaction mixture and stirred for 1 hour, and the deposited crystal was removed by filtration, and the filtrate was concentrated until the total amount reached 200 mL and the deposited solid was filtrated. The solid was re-crystallized from toluene, to obtain 25.7 g (yield: 53%, HPLC area percentage: 99.3%) of an intended compound (J6).

¹H-NMR (299.4 MHz, CDCl₃): 1.21 (s, 18H), 1.26 (s, 18H), 6.89 (m, 4H), 7.07 (m, 4H), 7.25 (m, 8H), 7.42 (d, 2H), 8.01 (m, 4H)

LC-MS (APPI-MS (posi)): 893 [M+H]⁺

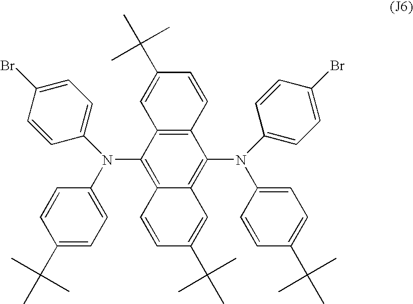

### Comparative Example 1

### Synthesis of polymer compound 1

Under an inert atmosphere, 0.188 g (0.24 mmol) of the following compound (J2), 2.06 g (3.76 mmol) of the following compound (J13), 2.10 g (3.96 mmol) of the following compound (J14), palladium acetate (2.7 mg), tris(2-methoxyphenyl)phosphine (29.6 mg), Aliquat 336 (0.52 g, manufactured by Aldrich) and toluene (40 mL) were mixed, and the mixture was heated at 105° C. Into this reaction solution, a 2M Na₂CO₃ aqueous solution (10.9 mL) was dropped, and the mixture was refluxed for 2 hours. After the reaction, phenylboric acid (50 mg) was added, and the mixture was further refluxed for 2 hours. Then, a sodium diethyldithiacarbamate aqueous solution was added and the mixture was stirred at 80° C. for 2 hours. After cooling, the mixture was washed with water (52 mL) twice, with a 3% acetic acid aqueous solution (52 mL) twice and with water (52 mL) twice, and the resultant solution was dropped into methanol (620 mL), and filtration was performed to obtain a precipitate. The precipitate was dissolved in toluene (124 mL), and purified by passing through an alumina column and a silica gel column. The resultant toluene solution was dropped into methanol (620 mL) and stirred, then, the resultant precipitate was filtrated and dried. The resultant polymer compound 1 had a yield of 2.54 g.

The polymer compound 1 had a polystyrene-reduced number average molecular weight of 1.1×10⁵ and a polystyrene-reduced weight average molecular weight of 2.5×10⁵. The fluorescence intensity was 4.5, and the glass transition temperature was 73° C.

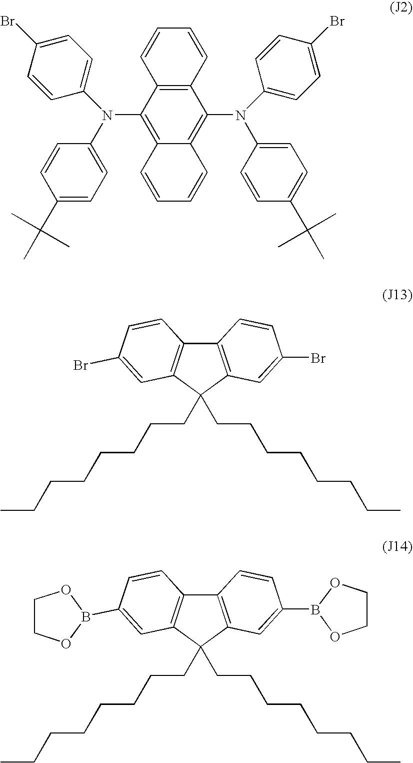

### Example 1

### Synthesis of polymer compound 2

Under an inert atmosphere, 0.188 g (0.24 mmol) of the following compound (J2), 2.25 g (3.76 mmol) of the following compound (J8), 2.74 g (3.96 mmol) of the following compound (J9), palladium acetate (2.7 mg), tris(2-methoxyphenyl)phosphine (29.6 mg), Aliquat 336 (0.52 g, manufactured by Aldrich) and toluene (40 mL) were mixed, and the mixture was heated at 105° C. Into this reaction solution, a 2M Na₂CO₃ aqueous solution (10.9 mL) was dropped, and the mixture was refluxed for 4.5 hours. After the reaction, phenylboric acid (50 mg) was added, and the mixture was further refluxed for 2 hours. Then, a sodium diethyldithiacarbamate aqueous solution was added and the mixture was stirred at 80° C. for 2 hours. After cooling, the mixture was washed with water (52 mL) twice, with a 3% acetic acid aqueous solution (52 mL) twice and with water (52 mL) twice, and the resultant solution was dropped into methanol (620 mL), and filtration was performed to obtain a precipitate. The precipitate was dissolved in toluene (124 mL), and purified by passing through an alumina column and a silica gel column. The resultant toluene solution was dropped into methanol (620 mL) and stirred, then, the resultant precipitate was filtrated and dried. The resultant polymer compound 2 had a yield of 2.55 g.

The polymer compound 2 had a polystyrene-reduced number average molecular weight of 1.0×10⁵ and a polystyrene-reduced weight average molecular weight of 2.3×10⁵. The fluorescence intensity was 7.1, and the glass transition temperature was 136° C. In comparison with the polymer compound 1 described in Comparative Example 1, the polymer compound 2 of the present invention shows strong fluorescence intensity and excellent in heat resistance.

The compounds (J8) and (J9) were synthesized by a method described in International Publication WO 2005/056633, p. 148 to 150.

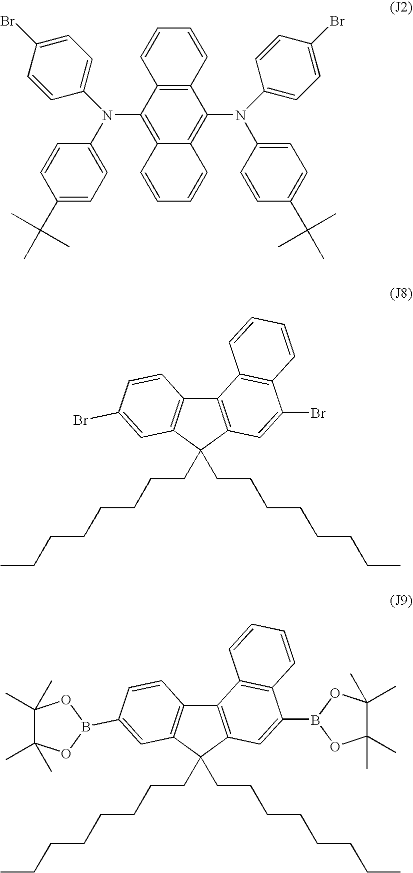

### Example 2

### Synthesis of polymer compound 3

Under an inert atmosphere, 0.157 g (0.20 mmol) of the following compound (J2), 1.835 g (3.15 mmol) of the following compound (J10), 1.777 g (3.35 mmol) of the following compound (J14), palladium acetate (2.3 mg), tris(2-methoxyphenyl)phosphine (24.8 mg), Aliquat 336 (0.43 g, manufactured by Aldrich) and toluene (34 mL) were mixed, and the mixture was heated at 105° C. Into this reaction solution, a 2M Na₂CO₃ aqueous solution (9.1 mL) was dropped, and the mixture was refluxed for 1.5 hours. After the reaction, phenylboric acid (41 mg) was added, and the mixture was further refluxed for 2 hours. Then, a sodium diethyldithiacarbamate aqueous solution was added and the mixture was stirred at 80° C. for 2 hours. After cooling, the mixture was washed with water (44 ml) twice, with a 3% acetic acid aqueous solution (44 ml) twice and with water (44 ml) twice, and the resultant solution was dropped into methanol (520 mL), and filtration was performed to obtain a precipitate. The precipitate was dissolved in toluene (104 mL), and purified by passing through an alumina column and a silica gel column. The resultant toluene solution was dropped into methanol (520 mL) and stirred, then, the resultant precipitate was filtrated and dried. The resultant polymer compound 3 had a yield of 2.19 g.

The polymer compound 3 had a polystyrene-reduced number average molecular weight of 1.1×10⁵ and a polystyrene-reduced weight average molecular weight of 3.3×10⁵.

The compound (J10) was synthesized by a method described in patent document JP-A No. 2004-59899, p. 90.

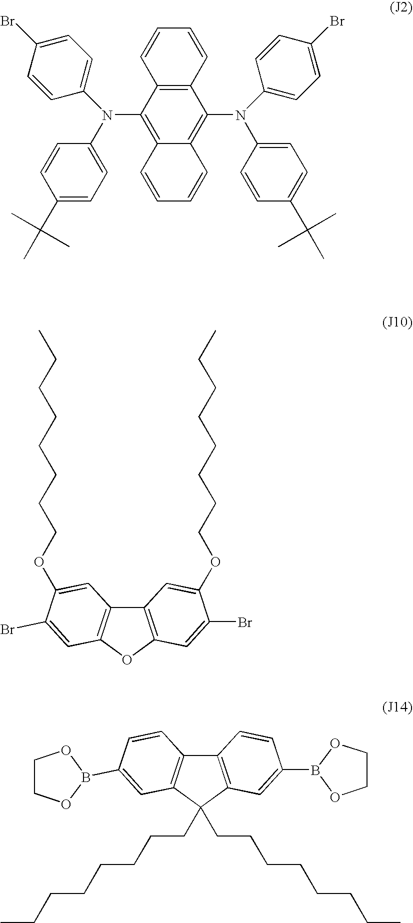

### Example 3

A 1.2 wt % xylene solution of the polymer compound 2 was prepared. On a glass substrate carrying an ITO film having a thickness of 150 nm formed thereon by a sputtering method, a solution of poly(ethylenedioxythiophene)/polystyrenesulfonic acid (manufactured by Bayer, Baytron P) was spin-coated to form a film having a thickness of 50 nm, and dried on a hot plate at 200° C. for 10 minutes. Next, the xylene solution prepared above was spin-coated at a rotational speed of 900 rpm to form a film. The thickness was about 100 nm. This was dried under a nitrogen gas atmosphere at 130° C. for 1 hour, then, as a cathode, barium was vapor-deposited with a thickness of about 5 nm, then, aluminum was vapor-deposited with a thickness of about 80 nm, to manufacture an EL device. After the degree of vacuum reached 1×10⁻⁴ Pa or less, vapor deposition of a metal was initiated. By applying voltage on the resulting device, green EL light emission (peak wavelength: 525 nm) was obtained. This device showed light emission of 100 cd/m² at 5.5 V, obtaining a maximum brilliance of as high as about 6000 cd/m² or more.

The device was driven at a constant current density of 49 mA/cm² to find a half life of 48 hours, indicating a longer life of the polymer compound 2 of the present invention as compared with the following Comparative Example 2 driven at the same current density.

### Example 4

A 1.0 wt % xylene solution of the polymer compound 3 was prepared, and an EL device was manufactured in the same manner as in Example 3. A light emitting layer was formed by spin coat at a rotational speed of 4000 rpm. The film thickness was about 80 nm. By applying voltage on the resulting device, green EL light emission (peak wavelength: 530 nm) was obtained. This device showed light emission of 100 cd/m² at 6 V, obtaining a maximum brilliance of as high as about 12000 cd/m² or more.

The device was driven at a constant current density of 49 mA/cm² to find a half life of 250 hours or longer, indicating a longer life of the polymer compound 3 of the present invention as compared with the following Comparative Example 2 driven at the same current density.

### Comparative Example 2

A 1.2 wt % xylene solution was prepared using the polymer compound 1 instead of the polymer compound 2 described in Example 3, and an EL device was manufactured in the same manner as in Example 3 using this xylene solution. A light emitting layer was formed by spin coat at a rotational speed of 1300 rpm. By applying voltage on the resulting device, green EL light emission (peak wavelength: 525 nm) was obtained.

The device was driven at a constant current density of 49 mA/cm² to find a half life of 0.07 hours.

### Comparative Example 3

### Synthesis of Polymer Compound 4

Under an inert atmosphere, 0.157 g (0.17 mmol) of the following compound (J6), 1.50 g (2.74 mmol) of the following compound (J13), 1.55 g (2.92 mmol) of the following compound (J14), palladium acetate (2.0 mg), tris(2-methoxyphenyl)phosphine (21.6 mg), Aliquat 336 (0.38 g, manufactured by Aldrich) and toluene (29 mL) were mixed, and the mixture was heated at 105° C. Into this reaction solution, a 2M Na₂CO₃ aqueous solution (7.9 mL) was dropped, and the mixture was refluxed for 4.5 hours. After the reaction, phenylboric acid (36 mg) was added, and the mixture was further refluxed for 2 hours. Then, a sodium diethyldithiacarbamate aqueous solution was added and the mixture was stirred at 80° C. for 2 hours. After cooling, the mixture was washed with water (38 ml) twice, with a 3% acetic acid aqueous solution (38 ml) twice and with water (38 ml) twice, and the resultant solution was dropped into methanol (450 mL), and filtration was performed to obtain a precipitate. The precipitate was dissolved in toluene (90 mL), and purified by passing through an alumina column and a silica gel column. The resultant toluene solution was dropped into methanol (450 mL) and stirred, then, the resultant precipitate was filtrated and dried. The resultant polymer compound 4 had a yield of 1.75 g.

The polymer compound 4 had a polystyrene-reduced number average molecular weight of 8.3×10⁴ and a polystyrene-reduced weight average molecular weight of 1.9×10⁵. The fluorescence intensity was 4.5, and the glass transition temperature was 78° C.

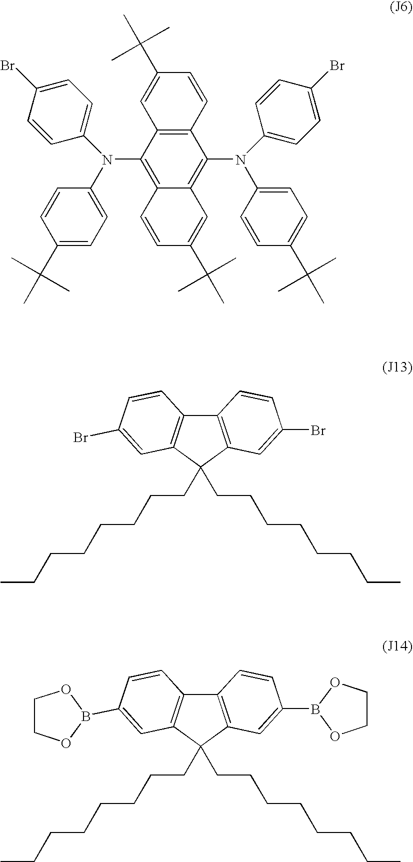

### Example 5

### Synthesis of Polymer Compound 5

Under an inert atmosphere, 0.180 g (0.20 mmol) of the following compound (J6), 1.89 g (3.15 mmol) of the following compound (J8), 2.32 g (3.35 mmol) of the following compound (J9), palladium acetate (2.3 mg), tris(2-methoxyphenyl)phosphine (24.8 mg), Aliquat 336 (0.43 g, manufactured by Aldrich) and toluene (34 mL) were mixed, and the mixture was heated at 105° C. Into this reaction solution, a 2M Na₂CO₃ aqueous solution (9.1 mL) was dropped, and the mixture was refluxed for 2 hours. After the reaction, phenylboric acid (41 mg) was added, and the mixture was further refluxed for 2 hours. Then, a sodium diethyldithiacarbamate aqueous solution was added and the mixture was stirred at 80° C. for 2 hours. After cooling, the mixture was washed with water (44 ml) twice, with a 3% acetic acid aqueous solution (44 ml) twice and with water (44 ml) twice, and the resultant solution was dropped into methanol (520 mL), and filtration was performed to obtain a precipitate. The precipitate was dissolved in toluene (104 mL), and purified by passing through an alumina column and a silica gel column. The resultant toluene solution was dropped into methanol (520 mL) and stirred, then, the resultant precipitate was filtrated and dried. The resultant polymer compound 5 had a yield of 1.48 g.

The polymer compound 5 had a polystyrene-reduced number average molecular weight of 8.8×10⁴ and a polystyrene-reduced weight average molecular weight of 1.8×10⁵. The fluorescence intensity was 8.1, and the glass transition temperature was 138° C. The polymer compound 5 of the present invention shows stronger fluorescence intensity and has more excellent heat resistance as compared with the polymer compound 4 described in Comparative Example 3.

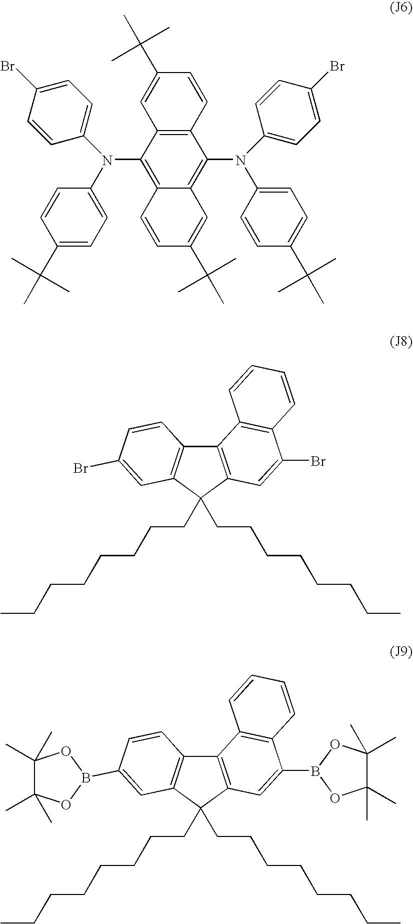

### Example 6

A 1.2 wt % xylene solution of the polymer compound 5 was prepared, and an EL device was manufactured in the same manner as in Example 3. A light emitting layer was formed by spin coat at a rotational speed of 1400 rpm. The film thickness was about 80 nm. By applying voltage on the resulting device, green EL light emission (peak wavelength: 520 nm) was obtained. The device showed light emission of 100 cd/m² at 5 V, obtaining a maximum brilliance of as high as about 12000 cd/m² or more.

The device was driven at a constant current density of 49 mA/cm² to find a half life of 3 hours, indicating a longer life of the polymer compound 5 of the present invention as compared with the following Comparative Example 4 driven at the same current density.

### Comparative Example 4

A 1.2 wt % xylene solution was prepared using the polymer compound 4 instead of the polymer compound 5 described in Example 6, and an EL device was manufactured in the same manner as in Example 3 using this xylene solution. A light emitting layer was formed by spin coat at a rotational speed of 900 rpm. By applying voltage on the resulting device, green EL light emission (peak wavelength: 525 nm) was obtained.

The device was driven at a constant current density of 49 mA/cm² to find a half life of 0.02 hours.

### Example 7

### Synthesis of Polymer Compound 6

Under an inert atmosphere, 0.630 g (0.69 mmol) of the following compound (J7), 0.276 g (0.46 mmol) of the following compound (J8), 0.810 g (1.17 mmol) of the following compound (J9), palladium acetate (0.8 mg), tris(2-methoxyphenyl)phosphine (4.9 mg), a 20 wt % tetraethylammonium hydroxide aqueous solution (8.5 g) and toluene (13 mL) were mixed, the mixture was heated at 105° C., and the refluxed for 3 hours. After the reaction, 4-t-butylbromobenzene (123 mg) was added, and the mixture was further refluxed for 2 hours. Then, a sodium diethyldithiacarbamate aqueous solution was added and the mixture was stirred at 65° C. for 2 hours. After cooling, the mixture was washed with 2 N hydrochloric acid (26 ml) twice, with a 10% sodium acetate aqueous solution (26 ml) twice and with water (26 ml) twice, passed through cerite, and the resultant solution was dropped into methanol (520 mL), and filtration was performed to obtain a precipitate. The precipitate was dissolved in toluene (104 mL), and the resultant toluene solution was dropped into methanol (520 ml) and stirred, then, the resultant precipitate was filtrated and dried, and this series of operation was repeated twice. The resultant polymer compound 6 had a yield of 0.95 g.

The polymer compound 6 had a polystyrene-reduced number average molecular weight of 2.8×10⁴ and a polystyrene-reduced weight average molecular weight of 5.2×10⁴. The fluorescence intensity was 4.9, and the glass transition temperature was 125° C.

The compound (J7) was synthesized by a method described in International Publication WO 2005/049546, p. 12.

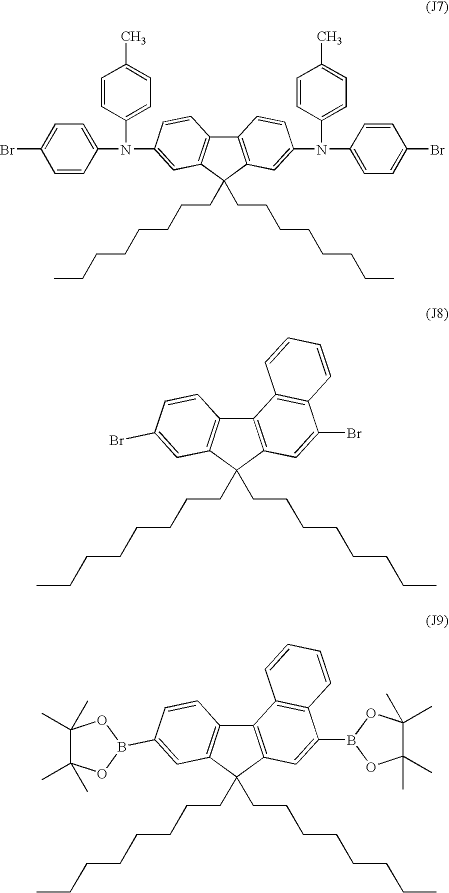

### Example 8

### Manufacturing of Light Emitting Device by Polymer Compound 6

A 1.8 wt % xylene solution of the polymer compound 6 was prepared, and an EL device was manufactured in the same manner as in Example 3. A light emitting layer was formed by spin coat at a rotational speed of 900 rpm. The film thickness was about 90 nm. By applying voltage on the resulting device, blue EL light emission (peak wavelength: 460 nm) was obtained.

### Example 9

### Synthesis of Polymer Compound 7

Into a 100 mL two-necked flask was added 0.0312 g (0.044 mmol) of the following compound (J4), 1.524 g (2.20 mmol) of the following compound (J9), 1.254 g (1.92 mmol) of the following compound (J11), 0.103 g (0.22 mmol) of the following compound (J12) and 0.34 g of Aliquat™ as a phase transfer catalyst, and an atmosphere in the flask was purged with an argon gas. Then, 19 mL of toluene was added, Ar bubbling was carried out for 30 minutes while stirring. Then, 1.9 mg of dichlorobis(triphenylphosphine)palladium and 4.5 mL of a 2 M sodium carbonate aqueous solution were added, and the mixture was stirred at 100° C. for 2.5 hours, then, 2.9 mg of dichlorobis(triphenylphosphine)palladium was additionally added, and the mixture was further stirred at 100° C. for 3 hours. Then, 0.20 g of 4-t-butylphenylboric acid and 15 mL of toluene were added and the mixture was stirred at 100° C. for 1.5 hours. After cooling down to room temperature, 80 mL of toluene and 50 mL of water were added and the mixture was stirred, then, the organic layer was separated from the aqueous layer. To the organic layer was added water and stirred, then, the organic layer separated from the aqueous layer was dropped into 500 mL of methanol, and the resultant precipitate was filtrated and dried. The precipitate was dissolved in 100 mL of toluene, and passed through a silica gel column and an alumina column, and dropped into 800 mL of methanol, and the resultant precipitate was filtrated and dried to obtain 1.7 g of polymer compound 7. The polystyrene-reduced number average molecular weight and polystyrene-reduced weight average molecular weight were Mn=1.0×10⁵ and Mw=2.3×10⁵, respectively.

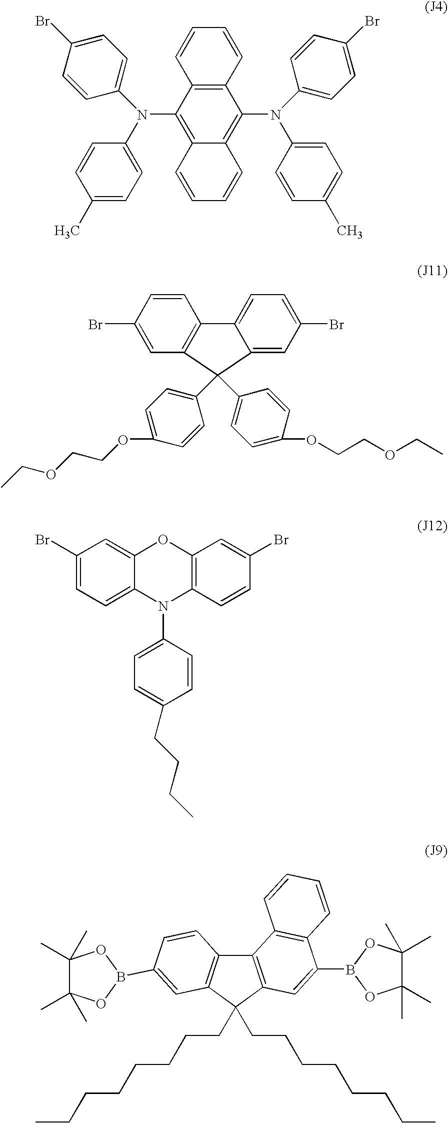

### Example 10

### Manufacturing of Light Emitting Device by Polymer Compound 7

On a glass substrate carrying an ITO film formed by a sputtering method, a suspension of poly(3,4)ethylenedioxythiophene/polystyrenesulfonic acid (manufactured by Bayer, Baytron P CH 8000) was spin-coated to form a film having a thickness of 80 nm, and dried on a hot plate at 200® C. for 15 minutes. Next, an INTERLAYER layer was formed. Then, the polymer compound 7 obtained in Example 9 was dissolved in xylene. In this procedure, the solution was prepared so as to give a solid concentration of about 1.5 wt %. This xylene solution was spin-coated to form a film with a thickness of 90 nm. Thereafter, the film was dried at 130° C. for 1 hour under a nitrogen atmosphere, then, as a cathode, barium was vapor-deposited, then, aluminum was vapor-deposited, to manufacture an organic EL device. By applying voltage on the resulting device, green light emission with a peak wavelength of 525 nm originated from the polymer compound 7 was shown. When a voltage of 7.4 V was applied, this device showed a maximum light emission efficiency of 11.5 cd/A, and the chromaticity coordinate C.I.E.1931 (x,y) was (0.291, 0.585) in this operation.

### Example 11

### Synthesis of Polymer Compound 8

3.2 g of polymer compound 8 was obtained in the same procedure as in Example 9 excepting that 0.080 mmol of the compound (J14), 4.04 mmol of the compound (J9), 0.40 mmol of the compound (J12) and 3.52 mmol of the following compound (J16) were used as a monomer. The polystyrene-reduced number average molecular weight and polystyrene-reduced weight average molecular weight were Mn=1.4×10⁵ and Mw=2.9×10⁵, respectively.

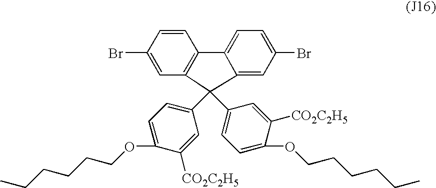

### Example 12

### Manufacturing of Light Emitting Device by Polymer Compound 8

On a glass substrate carrying an ITO film formed by a sputtering method, a suspension of poly(3,4)ethylenedioxythiophene/polystyrenesulfonic acid (manufactured by Bayer, Baytron P CH 8000) was spin-coated to form a film having a thickness of 80 nm, and dried on a hot plate at 200° C. for 15 minutes, then, an INTERLAYER layer was formed. Next, the polymer compound 8 was dissolved in xylene. In this procedure, the solution was prepared so as to give a solid concentration of about 1.5 wt %. This xylene solution was spin-coated to form a film with a thickness of 85 nm. Thereafter, the film was dried at 130° C. for 1 hour under a nitrogen atmosphere, then, as a cathode, barium was vapor-deposited, then, aluminum was vapor-deposited, to manufacture an organic EL device. By applying voltage on the resulting device, green light emission with a peak wavelength of 525 nm originated from the polymer compound 8 was shown. When a voltage of 7.4 V was applied, this device showed a maximum light emission efficiency of 12.2 cd/A, and the chromaticity coordinate C.I.E.1931 (x,y) was (0.271, 0.565) in this operation.

### Comparative Example 5

On a glass substrate carrying an ITO film formed by a sputtering method, a suspension of poly(3,4)ethylenedioxythiophene/polystyrenesulfonic acid (manufactured by Bayer, Baytron P CH 8000) was spin-coated to form a film having a thickness of 80 nm, and dried on a hot plate at 200° C. for 15 minutes, then, an INTERLAYER layer was formed. Next, polymer compound 9 obtained by condensation polymerization of 0.60 mmol of the following compound (J4), 6.12 mmol of the compound (J14) and 5.40 mmol of the compound (J15) in the same manner as for a procedure in patent document 1 (International Publication WO 2005/49546, pamphlet), p. 21, Example 8, was dissolved in xylene. This xylene solution was spin-coated to form a film with a thickness of 90 nm. Thereafter, the film was dried at 130° C. for 1 hour under a nitrogen atmosphere, then, as a cathode, barium was vapor-deposited, then, aluminum was vapor-deposited, to manufacture an organic EL device. By applying voltage on the resulting device, green light emission with a peak wavelength of 535 nm originated from the polymer compound 9 was shown. When a voltage of 4.8 V was applied, this device showed a maximum light emission efficiency of 8.5 cd/A, and the chromaticity coordinate C.I.E.1931 (x,y) was (0.354, 0.604) in this operation.

As described above, the polymer compound 7 and the polymer compound 8 used in Example 10 and Example 12, respectively, showed higher efficiency as compared with the polymer compound 9 containing no repeating unit of the formula (2), thus, the polymer compounds of the present invention have an excellent nature as materials to be used in polymer light emitting devices.

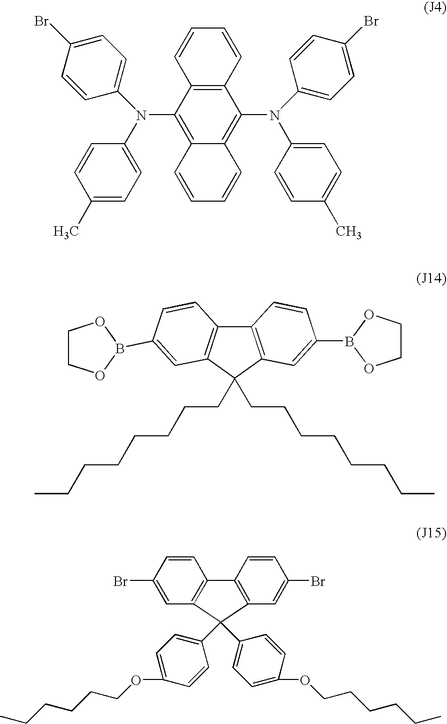

### INDUSTRIAL APPLICABILITY

The polymer compound of the present invention is useful as a light emitting material and a charge transporting material, excellent in heat resistance, fluorescence intensity and the like, and a light emitting device using this polymer compound is excellent in performances such as life of a device, light emission efficiency and the like. Therefore, a polymer LED containing a polymer compound of the present invention can be used for back light of liquid crystal displays, curved of flat light sources for illumination, segment type displays, dot matrix flat panel displays and the like.

1. A polymer compound comprising at least one of repeating units of the following formula (1) and at least one of repeating units selected from the following formulae (2) and (3) 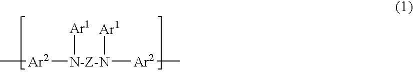
wherein, Ar¹ represents an aryl group or monovalent aromatic heterocyclic group optionally having a substituent, and Ar² represents an arylene group or divalent aromatic heterocyclic group optionally having a substituent; Z represents a divalent aromatic group having a condensed ring structure, and this group optionally has a substituent; two Ar¹s may be the same or different, and two Ar²s may be the same or different; 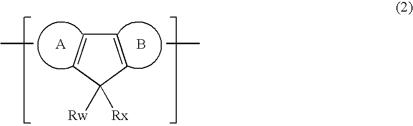
wherein, a ring A and a ring B represent each independently an aromatic hydrocarbon ring optionally having a substituent, and at least one of the ring A and the ring B is an aromatic hydrocarbon ring having two or more benzene rings condensed, two bonds are present on the ring A or the ring B, and Rw and Rx represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group, and Rw and Rx may be mutually connected with each other to form a ring; 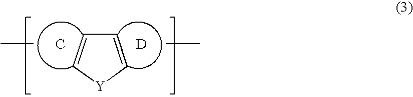
wherein, a ring C and a ring D represent each independently an aromatic ring optionally having a substituent, and two bonds are present on the ring C or the ring D; Y represents an oxygen atom, sulfur atom or —O—C(R^{K})₂; R^{K} represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, nitro group or cyano group; and two R^{K} s may be the same or different.

2. The polymer compound according to claim 1, further comprising at least one repeating unit of the following formula (4) or (5):
—Ar³— (4)
wherein, Ar³ represents a divalent aromatic group optionally having a substituent 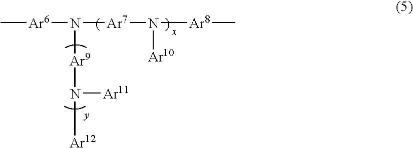
wherein, Ar⁶, Ar⁷, Ar⁸ and Ar⁹ represent each independently a 1,4-phenylene group or 4,4′-biphenylene group. Ar¹⁰, Ar¹¹ and Ar¹² represent each independently an aryl group; Ar⁶, Ar⁷, Ar⁸, Ar⁹, Ar¹⁰, Ar¹¹ and Ar¹² optionally have a substituent; x and y represent each independently 0 or a positive integer.

3. The polymer compound according to claim 1, wherein Z in the formula (1) is an atomic group obtained by removing two hydrogen atoms from a substituted or unsubstituted aromatic hydrocarbon compound having a condensed ring.

4. The polymer compound according to claim 1, wherein Z in the formula (1) is an anthracenediyl group optionally having a substituent or a fluorenediyl group optionally having a substituent.

5. The polymer compound according to claim 1, wherein Ar¹ in the formula (1) is a phenyl group optionally having a substituent.

6. The polymer compound according to claim 1, wherein the repeating unit of the formula (1) is a divalent group of the following formula (S-52): 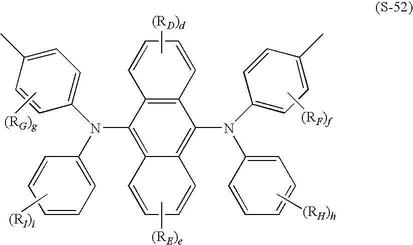
wherein, R_{D}, R_{E}, R_{F}, R_{G}, R_{H} and R_{I} represent each independently and alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group; when there are two or more R_{D}s, R_{E}s, R_{F}s, R_{G}s, R_{H}s or R_{I}s, respectively, they may be mutually the same or different; d, e, f and g represent each independently an integer of 0 to 4, and h and i represent each independently an integer of 0 to 5.

7. The polymer compound according to claim 1, wherein the repeating unit of the formula (1) is a divalent group of the following formula (S-53): 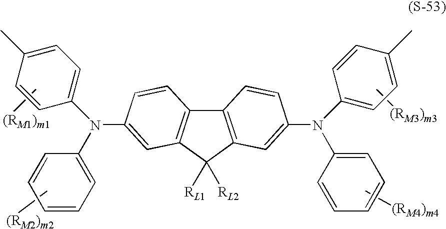
wherein, R_{M1}, R_{M2}, R_{M3} and R_{M4} represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group; when there are two or more R_{M1}s, R_{M2} s, R_{M3} s or R_{M4} s, respectively, they may be mutually the same or different; m1 and m3 represent each independently an integer of 0 to 4, and m2 and m4 represent each independently an integer of 0 to 5; R_{L1} and R_{L2} represent each independently an alkyl group, aryl group, arylalkyl group or monovalent heterocyclic group.

8. The polymer compound according to claim 1, wherein the repeating unit of the formula (2) is a divalent group of the following formula (1-1), (1-2), (1-3) or (1-4): 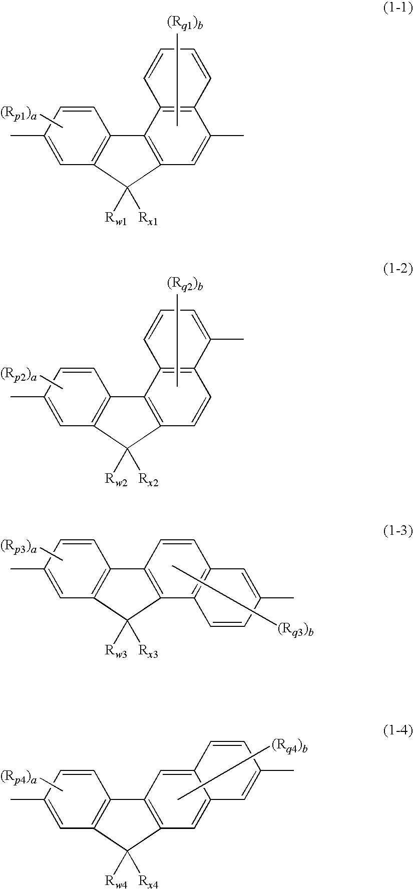
wherein, Rₚ₁, R_{q1}, Rₚ₂, R_{q2}, Rₚ₃, R_{q3}, Rₚ₄ and R_{q4} represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. a represents an integer of 0 to 3, and b represents an integer of 0 to 5; when there are two or more Rₚ₁s, R_{q1} s, Rₚ₂ s, R_{q2}s, Rₚ₃ s, R_{q3}S, Rₚ₄s or R_{q4} s, they may be the same or different; R_{w1}, Rₓ₁, R_{w2}, Rₓ₂, R_{w3}, Rₓ₃, R_{w4} and Rₓ₄ represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group, and, R_{w1} and Rₓ₁, R_{w2} and Rₓ₂, R_{w3} and Rₓ₃, and R_{w4} and Rₓ₄ each may be mutually connected to form a ring.

9. The polymer compound according to claim 1, wherein the repeating unit of the formula (3) is a divalent group of the following formula (G-27): 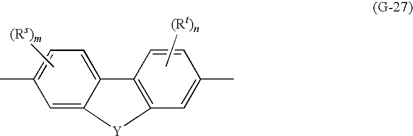
wherein, Y represents the same meaning as for Y in the formula (3), and R^{s} and R^{t} represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, nitro group or cyano group; when there are two or more R^{s} s or R^{t} s, they may be the same or different; m and n represent each independently an integer of 0 to 3.11.

10. The polymer compound according to claim 2, wherein the repeating unit of the formula (4) is a 2,7-fluorenediyl group having a substituent or a 3,7-phenoxazinediyl group having a substituent.

11. The polymer compound according to claim 2, comprising a repeating unit of the formula (S-52), a repeating unit of the formula (1-1), a 2,7-fluorenediyl group having a substituent and a 3,7-phenoxazinediyl group having a substituent.

12. A polymer composition comprising at least one material selected from the group consisting of hole transporting materials, electron transporting materials and light emitting materials, and the polymer compound as described in claim 1.

13. A solution comprising the polymer compound according to claim 1.

14. A solution comprising the polymer composition according to claim 12.

15. The solution according to claim 13, comprising two or more organic solvents.

16. The solution according to claim 13, having a viscosity of 1 to 20 mPa·s at 25° C.

17. A light emitting thin film comprising the polymer compound as described in claim 1, or a polymer composition comprising at least one material selected from the group consisting of hole transporting materials, electron transporting materials and light emitting materials, and the polymer compound as described in claim 1.

18. The light emitting thin film according to claim 17, showing a fluorescence quantum yield of 50% or more.

19. An electric conductive thin film comprising the polymer compound as described in claim 1, or a polymer composition comprising at least one material selected from the group consisting of hole transporting materials, electron transporting materials and light emitting materials, and the polymer compound as described in claim 1.

20. An organic semiconductor thin film comprising the polymer compound as described in claim 1, or a polymer composition comprising at least one material selected from the group consisting of hole transporting materials, electron transporting materials and light emitting materials, and the polymer compound as described in claim 1.

21. An organic transistor having the organic semiconductor thin film according to claim 20.

22. A method for forming the thin film as described in claim 17, using an inkjet method.

23. A polymer light emitting device having an organic layer between electrodes composed of an anode and a cathode, and comprising the polymer compound as described in claim 1, or a polymer composition comprising at least one material selected from the group consisting of hole transporting materials, electron transporting materials and light emitting materials, and the polymer compound as described in claim 1.

24. The polymer light emitting device according to claim 23, wherein said organic layer is a light emitting layer.

25. The polymer light emitting device according to claim 24, wherein said light emitting layer comprises further a hole transporting material, electron transporting material or light emitting material.

26. The polymer light emitting device according to claim 23, having a light emitting layer and a charge transporting layer between electrodes composed of an anode and a cathode, wherein the charge transporting layer comprises the polymer compound as described in claim 1, or a polymer composition comprising at least one material selected from the group consisting of hole transporting materials, electron transporting materials and light emitting materials, and the polymer compound as described in claim 1.

27. The polymer light emitting device according to claim 23, having a light emitting layer and a charge transporting layer between electrodes composed of an anode and a cathode, and having a charge injection layer between the charge transporting layer and the electrode, wherein the charge injection layer comprises the polymer compound as described in claim 1, or a polymer composition comprising at least one material selected from the group consisting of hole transporting materials, electron transporting materials and light emitting materials, and the polymer compound as described in claim 1.

28. A sheet light source using the polymer light emitting device as described in claim 23.

29. A segment display using the polymer light emitting device as described in claim 23.

30. A dot matrix display using the polymer light emitting device as described in claim 23.

31. A liquid crystal display using the polymer light emitting device as described in claim 23 as back light.
